(19) United States
(12) Patent Application Publication
(10) Pub. No.: US 2023/0119201 A1
(43) Pub. Date: Apr. 20, 2023

(54) COMPOSITION FOR ORGANIC OPTOELECTRONIC ELEMENT, ORGANIC OPTOELECTRONIC ELEMENT, AND DISPLAY DEVICE

(71) Applicant: SAMSUNG SDI CO., LTD., Yongin-si, Gyeonggi-do (KR)

(72) Inventors: Jonghoon KIM, Suwon-si, Gyeonggi-do (KR); Youngmook LIM, Suwon-si, Gyeonggi-do (KR); Changwoo KIM, Suwon-si, Gyeonggi-do (KR); Hansol SEO, Suwon-si, Gyeonggi-do (KR); Hyung Sun KIM, Suwon-si, Gyeonggi-do (KR); Mijin LEE, Suwon-si, Gyeonggi-do (KR); Sung-Hyun JUNG, Suwon-si, Gyeonggi-do (KR); Ho Kuk JUNG, Suwon-si, Gyeonggi-do (KR); Youngkyoung JO, Suwon-si, Gyeonggi-do (KR); Dalho HUH, Suwon-si, Gyeonggi-do (KR)

(21) Appl. No.: 17/793,234

(22) PCT Filed: Mar. 5, 2021
(86) PCT No.: PCT/KR2021/002723

§ 371 Date: Jul. 15, 2022

(30) Foreign Application Priority Data
Mar. 6, 2020 (KR) 10-2020-0028483
Mar. 20, 2020 (KR) 10-2020-0034165

(51) Int. Cl. H01L 51/00

(52) U.S. Cl. CPC H01L 51/0067; H01L 51/0058; H01L 51/0072; H01L 51/0073; H01L 51/0071; H01L 51/0054; H01L 51/0074; H01L 51/5012

(57) ABSTRACT

The present invention relates to a composition for an organic optoelectronic element, and an organic optoelectronic element and a display device including same, the composition comprising a first compound, a second compound, and a third compound, wherein the first compound is represented by Chemical Formula I, the second compound is represented by Chemical Formula II, and the third compound is represented by Chemical Formula IIIA or Chemical Formula IIIB.

The details of Chemical Formula I, Chemical Formula II, Chemical Formula IIIA and Chemical Formula IIIB are the same as those described in the specification.

### TECHNICAL FIELD

A composition for an organic optoelectronic element, an organic optoelectronic element, and a display device are disclosed.

### BACKGROUND ART

An organic optoelectronic element (organic optoelectronic diode) is a device capable of converting electrical energy and optical energy to each other.

An organic optoelectronic element may be classified as follows in accordance with its driving principles. One is a photoelectric element that generates electrical energy by separating excitons formed by light energy into electrons and holes, and transferring the electrons and holes to different electrodes, respectively and the other is light emitting element that generates light energy from electrical energy by supplying voltage or current to the electrodes.

Examples of the organic optoelectronic element include an organic photoelectric element, an organic light emitting diode, an organic solar cell, and an organic photo conductor drum.

Of these, an organic light emitting diode (OLED) has recently drawn attention due to an increase in demand for flat panel displays. The organic light emitting diode is a device that converts electrical energy into light, and the performance of the organic light emitting diode is greatly influenced by an organic material between electrodes.

### DISCLOSURE

### Technical Problem

An embodiment provides a composition for an organic optoelectronic element capable of implementing a high efficiency and long life-span organic optoelectronic element.

Another embodiment provides an organic optoelectronic element including the composition for an organic optoelectronic element.

Another embodiment provides a display device including the organic optoelectronic element.

### Technical Solution

According to an embodiment, a composition for an organic optoelectronic element includes a first compound, a second compound, and a third compound, wherein the first compound is represented by Chemical Formula I, the second compound is represented by Chemical Formula II, and the third compound is represented by Chemical Formula IIIA or Chemical Formula IIIB.

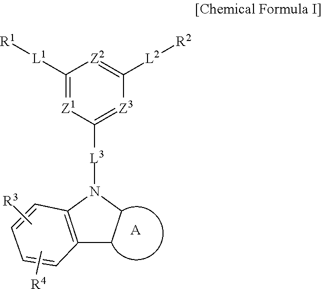

In Chemical Formula I,

Z¹ to Z³ are N or C-L^{a}-R^{a},

at least two of Z¹ to Z³ are N,

L^{a} and L¹ to L³ are each independently a single bond, a substituted or unsubstituted C6 to C20 arylene group, a substituted or unsubstituted C2 to C20 heterocyclic group, or a combination thereof,

R¹ and R² are each independently a substituted or unsubstituted C6 to C30 aryl group, a substituted or unsubstituted C2 to C30 heterocyclic group, or a combination thereof,

R^{a}, R³, and R⁴ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and

a ring A is represented by Chemical Formula I-1 to Chemical Formula I-7:

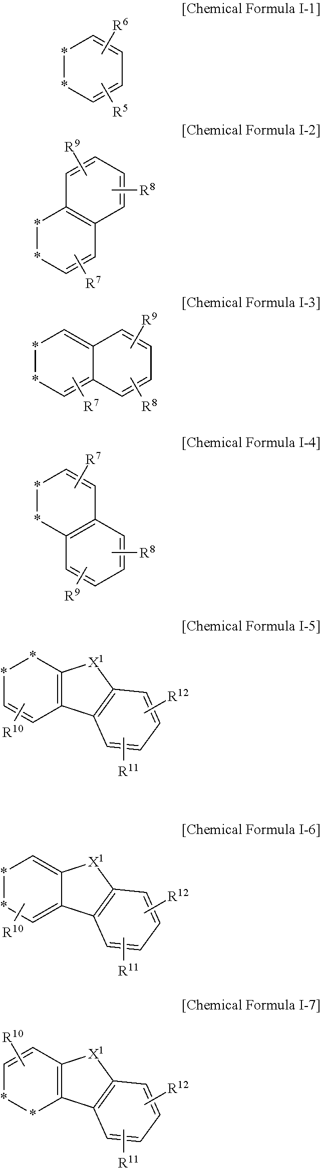

wherein, in Chemical Formula I-1 to Chemical Formula I-7,

X¹ is O, S, or NR^{b},

R^{b} and R⁵ to R¹² are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and

* is a linking point;

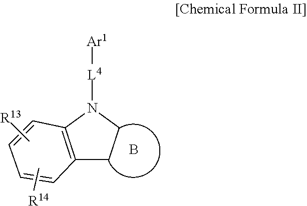

wherein, in Chemical Formula II,

L⁴ is a single bond, a substituted or unsubstituted C6 to C20 arylene group, a substituted or unsubstituted C2 to C20 heterocyclic group, or a combination thereof,

Ar¹ is a substituted or unsubstituted C6 to C30 aryl group, a substituted or unsubstituted dibenzofuranyl group, a substituted or unsubstituted dibenzothiophenyl group, or a combination thereof,

R¹³ and R¹⁴ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and

a ring B is represented by any one of Chemical Formula II-1 to Chemical Formula II-4:

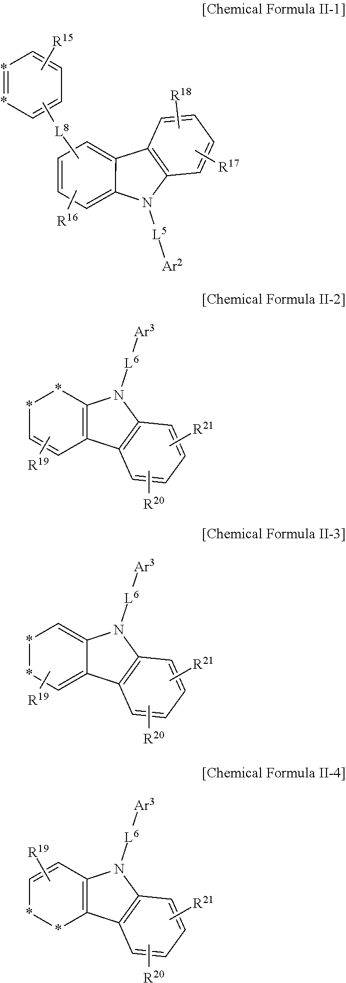

wherein, in Chemical Formula II-1 to Chemical Formula II-4,

L⁵ and L⁶ are each independently a single bond, a substituted or unsubstituted C6 to C20 arylene group, a substituted or unsubstituted C2 to C20 heterocyclic group, or a combination thereof,

L⁸ is a single bond, or a substituted or unsubstituted C6 to C20 arylene group,

Ar² and Ar³ are a substituted or unsubstituted C6 to C30 aryl group, a substituted or unsubstituted dibenzofuranyl group, a substituted or unsubstituted dibenzothiophenyl group, or a combination thereof,

R¹⁵ to R²¹ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and

* is a linking point;

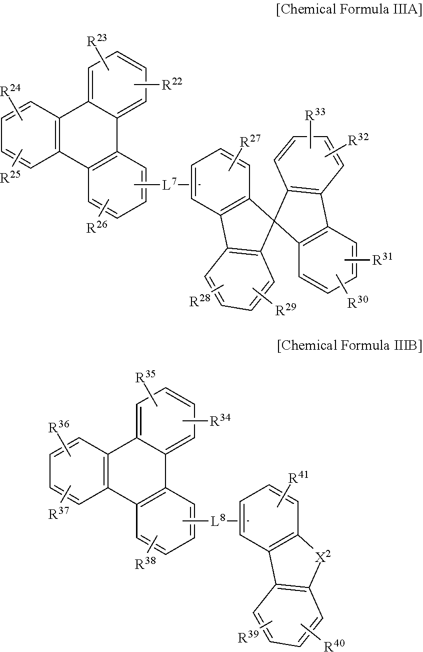

wherein, in Chemical Formula IIIA and Chemical Formula IIIB,

L⁷ and L⁸ are each independently a single bond, a substituted or unsubstituted C6 to C20 arylene group, a substituted or unsubstituted C2 to C20 heterocyclic group, or a combination thereof, and

R²² to R⁴¹ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group or a combination thereof.

According to another embodiment, an organic optoelectronic element includes an anode and a cathode facing each other, and at least one organic layer between the anode and the cathode, and the organic layer includes the composition for an organic optoelectronic element.

According to another embodiment, a display device including the organic optoelectronic element is provided.

### Advantageous Effects

An organic optoelectronic element having high efficiency and a long life-span may be realized.

### DESCRIPTION OF THE DRAWINGS

FIGS. 1 and 2 are cross-sectional views each illustrating an organic light emitting diode according to embodiments.

### DESCRIPTION OF SYMBOLS

100, 200: organic light emitting diode
105: organic layer
110: cathode
120: anode
130: light emitting layer
140: hole auxiliary layer

### MODE FOR INVENTION

Hereinafter, embodiments of the present invention are described in detail. However, these embodiments are exemplary, the present invention is not limited thereto and the present invention is defined by the scope of claims.

In the present specification, when a definition is not otherwise provided, “substituted” refers to replacement of at least one hydrogen of a substituent or a compound by deuterium, a halogen, a hydroxyl group, an amino group, a substituted or unsubstituted C1 to C30 amine group, a nitro group, a substituted or unsubstituted C1 to C40 silyl group, a C1 to C30 alkyl group, a C1 to C10 alkylsilyl group, a C6 to C30 arylsilyl group, a C3 to C30 cycloalkyl group, a C3 to C30 heterocycloalkyl group, a C6 to C30 aryl group, a C2 to C30 heteroaryl group, a C1 to C20 alkoxy group, a C1 to C10 trifluoroalkyl group, a cyano group, or a combination thereof.

In one example of the present invention, “substituted” refers to replacement of at least one hydrogen of a substituent or a compound by deuterium, a cyano group, a C1 to C30 alkyl group, a C1 to C10 alkylsilyl group, a C6 to C30 arylamine group, a C6 to C30 arylsilyl group, a C3 to C30 cycloalkyl group, a C3 to C30 heterocycloalkyl group, a C6 to C30 aryl group, or a C2 to C30 heteroaryl group. In addition, in specific examples of the present invention, “substituted” refers to replacement of at least one hydrogen of a substituent or a compound by deuterium, a cyano group, a C1 to C20 alkyl group, a C6 to C30 arylamine group, a C6 to C30 aryl group, or a C2 to C30 heteroaryl group. In addition, in specific examples of the present invention, “substituted” refers to replacement of at least one hydrogen of a substituent or a compound by deuterium, a cyano group, a C1 to C5 alkyl group, a C6 to C20 arylamine group, a C6 to C18 aryl group, a dibenzofuranyl group, a dibenzothiophenyl group, a carbazolyl group, or a pyridinyl group. In addition, in specific examples of the present invention, “substituted” refers to replacement of at least one hydrogen of a substituent or a compound by deuterium, a cyano group, a methyl group, an ethyl group, a propyl group, butyl group, a C6 to C20 arylamine group, a phenyl group, a biphenyl group, a terphenyl group, a naphthyl group, a triphenyl group, a fluorenyl group, a dibenzofuranyl group, a dibenzothiophenyl group, a carbazolyl group, or a pyridinyl group.

In the present specification, when a definition is not otherwise provided, “hetero” refers to one including one to three heteroatoms selected from N, O, S, P, and Si, and remaining carbons in one functional group.

In the present specification, “aryl group” refers to a group including at least one hydrocarbon aromatic moiety, and may include a group in which all elements of the hydrocarbon aromatic moiety have p-orbitals which form conjugation, for example a phenyl group, a naphthyl group, and the like, a group in which two or more hydrocarbon aromatic moieties may be linked by a sigma bond, for example a biphenyl group, a terphenyl group, a quarterphenyl group, and the like, and a group in which two or more hydrocarbon aromatic moieties are fused directly or indirectly to provide a non-aromatic fused ring, for example, a fluorenyl group, and the like.

The aryl group may include a monocyclic, polycyclic or fused ring polycyclic (i.e., rings sharing adjacent pairs of carbon atoms) functional group.

In the present specification, “heterocyclic group” is a generic concept of a heteroaryl group, and may include at least one heteroatom selected from N, O, S, P, and Si instead of carbon (C) in a cyclic compound such as an aryl group, a cycloalkyl group, a fused ring thereof, or a combination thereof. When the heterocyclic group is a fused ring, the entire ring or each ring of the heterocyclic group may include one or more heteroatoms.

For example, “heteroaryl group” refers to an aryl group including at least one heteroatom selected from N, O, S, P, and Si. Two or more heteroaryl groups are linked by a sigma bond directly, or when the heteroaryl group includes two or more rings, the two or more rings may be fused. When the heteroaryl group is a fused ring, each ring may include one to three heteroatoms.

More specifically, the substituted or unsubstituted C6 to C30 aryl group may be a substituted or unsubstituted phenyl group, a substituted or unsubstituted naphthyl group, a substituted or unsubstituted anthracenyl group, a substituted or unsubstituted phenanthrenyl group, a substituted or unsubstituted naphthacenyl group, a substituted or unsubstituted pyrenyl group, a substituted or unsubstituted biphenyl group, a substituted or unsubstituted p-terphenyl group, a substituted or unsubstituted m-terphenyl group, a substituted or unsubstituted o-terphenyl group, a substituted or unsubstituted chrysenyl group, a substituted or unsubstituted triphenylene group, a substituted or unsubstituted perylenyl group, a substituted or unsubstituted fluorenyl group, a substituted or unsubstituted indenyl group, or a combination thereof, but is not limited thereto.

More specifically, the substituted or unsubstituted C2 to C30 heterocyclic group may be a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzthiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted dibenzofuranyl group, or a substituted or unsubstituted dibenzothiophenyl group, or combination thereof, but is not limited thereto.

In the present specification, hole characteristics refer to an ability to donate an electron to form a hole when an electric field is applied and that a hole formed in the anode may be easily injected into the light emitting layer and transported in the light emitting layer due to conductive characteristics according to the highest occupied molecular orbital (HOMO) level.

In addition, electron characteristics refer to an ability to accept an electron when an electric field is applied and that electron formed in the cathode may be easily injected into the light emitting layer and transported in the light emitting layer due to conductive characteristics according to the lowest unoccupied molecular orbital (LUMO) level.

Hereinafter, a composition for an organic optoelectronic element according to an embodiment is described.

The composition for an organic optoelectronic element according to an embodiment is a mixture including three types of compounds, specifically, a first compound having electronic characteristics, a second compound having hole characteristics, and a third compound having buffer characteristics.

The third compound is a compound having a wide HOMO-LUMO band gap including both the HOMO-LUMO band gaps of the first compound and the second compound, and has a lower hole mobility than the hole mobility of the second compound having the hole characteristics, which slows down the hole injection characteristic and can bring about an effect of reducing hole traps.

In addition, as the third compound has lower electron mobility than the electron mobility of the first compound, and the light emitting layer region relatively shifts toward the hole transport auxiliary layer, exciton quenching at the interface with the electron transport auxiliary layer and deterioration thereby may be reduced, and thus makes it possible to increase the life-span.

The first compound having the above electronic characteristics has a structure in which carbazole or a carbazole derivative is substituted with a nitrogen-containing 6-membered ring and is represented by Chemical Formula I.

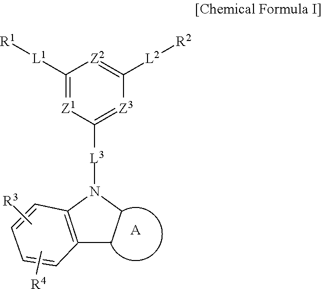

In Chemical Formula I,

Z¹ to Z³ are N or C-L^{a}-R^{a},

at least two of Z¹ to Z³ are N,

L^{a} and L¹ to L³ are each independently a single bond, a substituted or unsubstituted C6 to C20 arylene group, a substituted or unsubstituted C2 to C20 heterocyclic group, or a combination thereof,

R¹ and R² are each independently a substituted or unsubstituted C6 to C30 aryl group, a substituted or unsubstituted C2 to C30 heterocyclic group, or a combination thereof,

R^{a}, R³, and R⁴ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and

ring A is represented by Chemical Formula I-1 to Chemical Formula I-7:

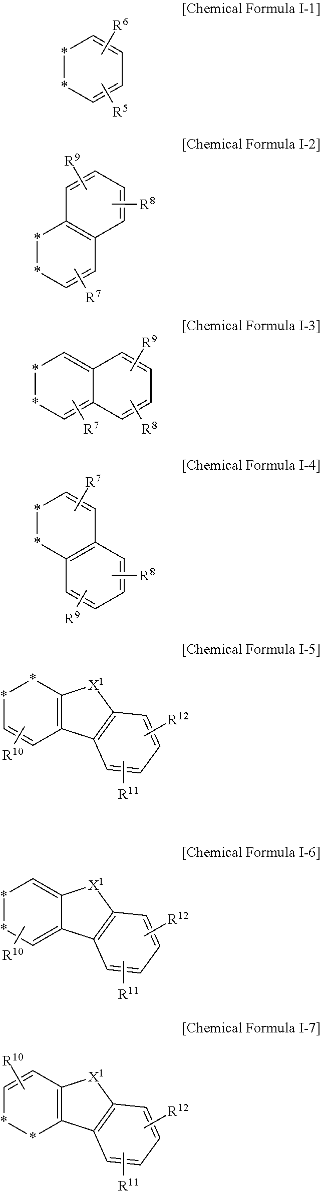

wherein, in Chemical Formula I-1 to Chemical Formula I-7,

X¹ is O, S, or NR,

R^{b} and R⁵ to R¹² are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and

* is a linking point.

Specifically, in Chemical Formula I, Z¹ to Z³ are each independently N or CH, at least two of Z¹ to Z³ are N.

For example, Z¹ to Z³ may each be N.

For example, Z¹ and Z³ may be N and Z² may be CH.

For example, in Chemical Formula I, L¹ to L³ may each independently be a single bond, a substituted or unsubstituted phenylene group, a substituted or unsubstituted biphenylene group, a substituted or unsubstituted naphthylene group, a substituted or unsubstituted carbazolylene group, a substituted or unsubstituted dibenzofuranylene group, a substituted or unsubstituted dibenzothiophenylene group, or a substituted or unsubstituted pyridinylene group.

As a specific example, In Chemical Formula I, L¹ to L³ may each independently be a single bond, a phenylene group, a biphenylene group, a carbazolylene group, a dibenzofuranylene group, a dibenzothiophenylene group, or a pyridinylene group.

For example, in Chemical Formula I, L¹ to L³ may each independently be a single bond, a m-phenylene group, or a p-phenylene group.

For example, in Chemical Formula I, R¹ and R² may each independently be a substituted or unsubstituted phenyl group, a substituted or unsubstituted biphenyl group, a substituted or unsubstituted terphenyl group, a substituted or unsubstituted naphthyl group, a substituted or unsubstituted carbazolyl group, a substituted or unsubstituted indolocarbazolyl group, a substituted or unsubstituted dibenzofuranyl group, a substituted or unsubstituted dibenzothiophenyl group, a substituted or unsubstituted fused carbazolyl group, a substituted or unsubstituted fused dibenzofuranyl group, a substituted or unsubstituted fused dibenzothiophenyl group, a substituted or unsubstituted fused indolocarbazolyl group, a substituted or unsubstituted pyridinyl group, a substituted or unsubstituted pyrimidinyl group, a substituted or unsubstituted triazinyl group, a substituted or unsubstituted quinolinyl group, a substituted or unsubstituted isoquinolinyl group, a substituted or unsubstituted quinoxalinyl group, a substituted or unsubstituted quinazolinyl group, or a substituted or unsubstituted benzoquinazolinyl group.

As a specific example, in Chemical Formula I, R¹ and R² may each independently be a substituted or unsubstituted phenyl group, a substituted or unsubstituted biphenyl group, a substituted or unsubstituted terphenyl group, a substituted or unsubstituted naphthyl group, a substituted or unsubstituted fluorenyl group, a substituted or unsubstituted carbazolyl group, a substituted or unsubstituted indolocarbazolyl group, a substituted or unsubstituted dibenzofuranyl group, or a substituted or unsubstituted dibenzothiophenyl group.

For example, in Chemical Formula I, R¹ and R² may each independently be a substituted or unsubstituted phenyl group, a substituted or unsubstituted biphenyl group, a substituted or unsubstituted carbazolyl group, a substituted or unsubstituted dibenzofuranyl group, or a substituted or unsubstituted dibenzothiophenyl group.

According to the specific structure of the carbazole and carbazole derivative, Chemical Formula I may be represented by, for example, any one of Chemical Formula IA to Chemical Formula IJ.

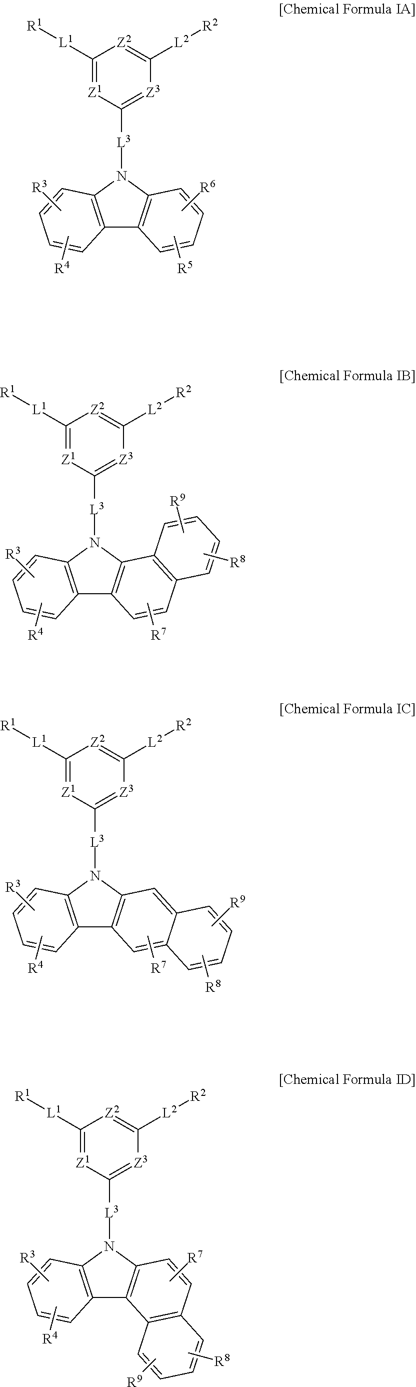

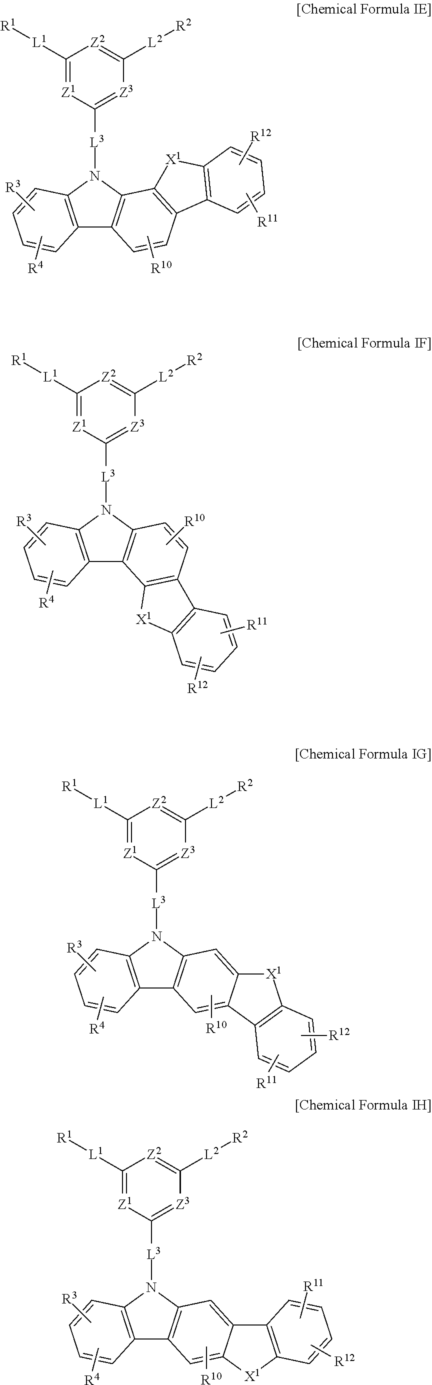

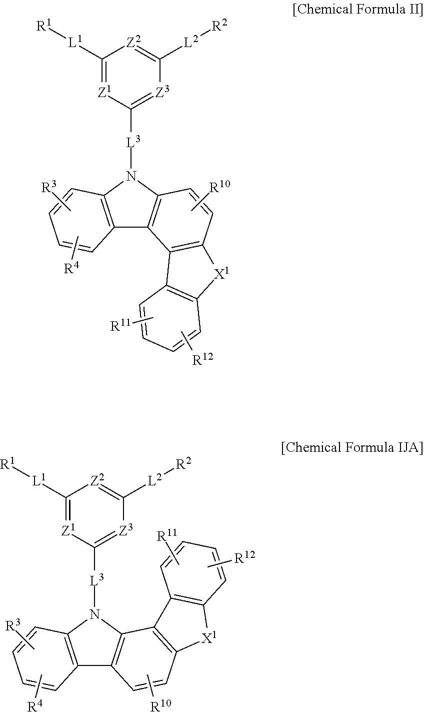

In Chemical Formula IA to Chemical Formula IJ, the definitions of Z¹ to Z³, L¹ to L³, R¹ to R¹², and X¹ are the same as described above.

Specifically, in Chemical Formula IA, R³ to R⁶ may each independently be hydrogen, deuterium, a substituted or unsubstituted phenyl group, a substituted or unsubstituted biphenyl group, a substituted or unsubstituted terphenyl group, a substituted or unsubstituted carbazolyl group, a substituted or unsubstituted indolocarbazolyl group, a substituted or unsubstituted dibenzofuranyl group, or a substituted or unsubstituted dibenzothiophenyl group.

For example, in Chemical Formula IA, R³ to R⁶ may each independently be hydrogen, a phenyl group, a biphenyl group, a carbazolyl group, a dibenzofuranyl group, or a dibenzothiophenyl group.

Specifically, in Chemical Formula IB to Chemical Formula ID, R³, R⁴, and R⁷ to R⁹ may each independently be hydrogen, deuterium, a substituted or unsubstituted phenyl group, a substituted or unsubstituted biphenyl group, a substituted or unsubstituted terphenyl group, a substituted or unsubstituted carbazolyl group, a substituted or unsubstituted indolocarbazolyl group, a substituted or unsubstituted dibenzofuranyl group, or a substituted or unsubstituted dibenzothiophenyl group.

For example, in Chemical Formula IB to Chemical Formula ID, R³, R⁴, and R⁷ to R⁹ may each independently be hydrogen or a phenyl group.

Specifically, in Chemical Formula IE to Chemical Formula IJ, R³, R⁴, and R¹⁰ to R¹² may each independently be hydrogen, deuterium, a substituted or unsubstituted phenyl group, a substituted or unsubstituted biphenyl group, a substituted or unsubstituted terphenyl group, a substituted or unsubstituted carbazolyl group, a substituted or unsubstituted indolocarbazolyl group, a substituted or unsubstituted dibenzofuranyl group, or a substituted or unsubstituted dibenzothiophenyl group.

For example, in Chemical Formula IE to Chemical Formula IJ, R³, R⁴, and R¹⁰ to R¹² may each independently be hydrogen or a phenyl group. For example, Chemical Formula IA may be represented by any one of Chemical Formula IA-1 to Chemical Formula IA-7.

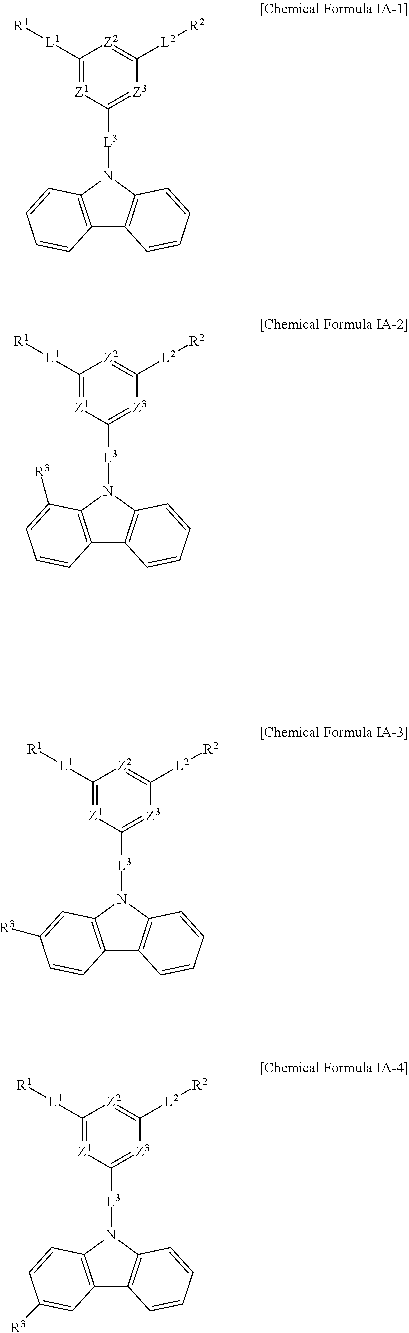

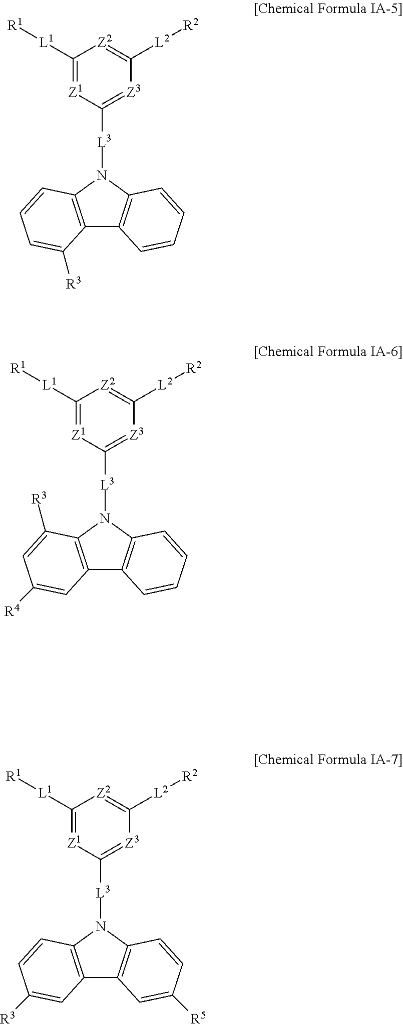

In Chemical Formula IA-1 to Chemical Formula IA-7, the definitions of Z¹ to Z³, L¹ to L³, R¹, and R² are the same as described above, and R³ to R⁵ may each independently be a substituted or unsubstituted phenyl group, a substituted or unsubstituted biphenyl group, a substituted or unsubstituted terphenyl group, a substituted or unsubstituted carbazolyl group, a substituted or unsubstituted indolocarbazolyl group, a substituted or unsubstituted dibenzofuranyl group, or a substituted or unsubstituted dibenzothiophenyl group.

For example, Chemical Formula IB may be represented by Chemical Formula IB-1 or Chemical Formula IB-2.

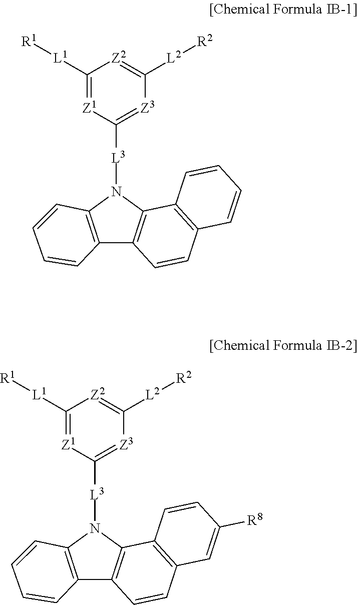

In Chemical Formula IB-1 and Chemical Formula IB-2, the definitions of Z¹ to Z³, L¹ to L³, R¹, and R² are the same as described above, and R⁸ may be a substituted or unsubstituted phenyl group, or a substituted or unsubstituted biphenyl group.

For example, Chemical Formula IC may be represented by Chemical Formula IC-1 or Chemical Formula IC-2.

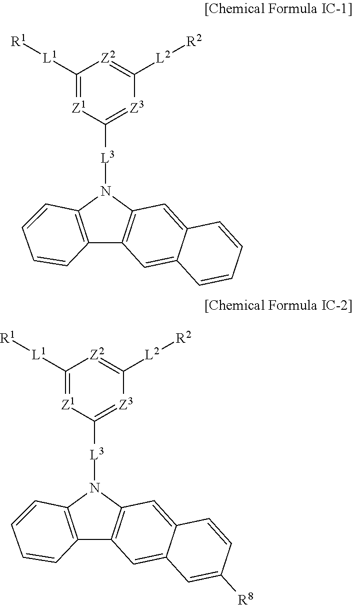

In Chemical Formula IC-1 and Chemical Formula IC-2, the definitions of Z¹ to Z³, L¹ to L³, R¹, and R² are the same as described above, and R⁸ may be a substituted or unsubstituted phenyl group, or a substituted or unsubstituted biphenyl group.

For example, Chemical Formula ID may be represented by Chemical Formula ID-1.

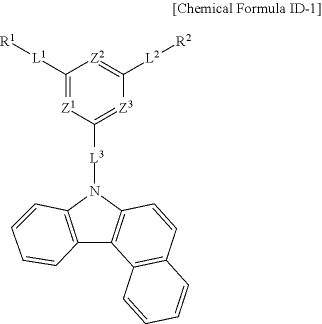

In Chemical Formula ID-1, the definitions of Z¹ to Z³, L¹ to L³, R¹, and R² are the same as described above.

For example, Chemical Formula IE may be represented by any one of Chemical Formula IE-1 to Chemical Formula IE-5.

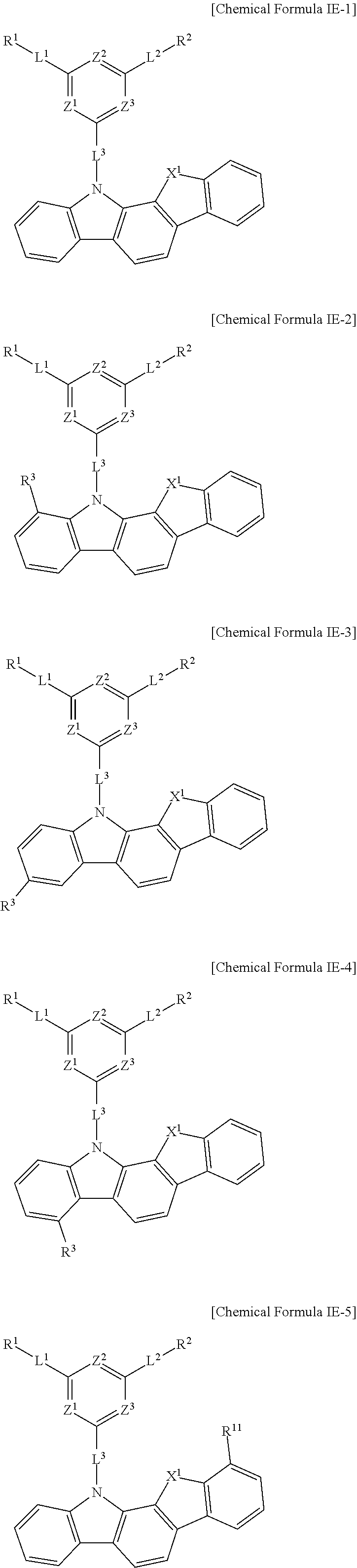

In Chemical Formula IE-1 to Chemical Formula IE-5, the definitions of Z¹ to Z³, L¹ to L³, R¹, R², and X¹ are the same as described above, and R³ to R¹¹ may each independently be a substituted or unsubstituted phenyl group, or a substituted or unsubstituted biphenyl group.

For example, Chemical Formula IF may be represented by Chemical Formula IF-1 or Chemical Formula IF-2.

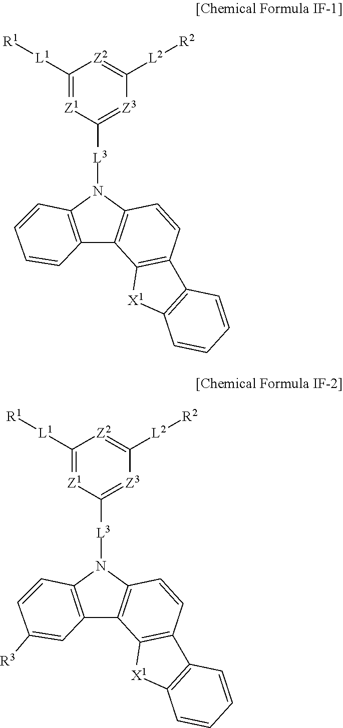

In Chemical Formula IF-1 and Chemical Formula IF-2, the definitions of Z¹ to Z³, L¹ to L³, R¹, R², and X¹ are the same as described above, and R³ may be a substituted or unsubstituted phenyl group, or a substituted or unsubstituted biphenyl group.

For example, Chemical Formula IG may be represented by Chemical Formula IG-1 or Chemical Formula IG-2.

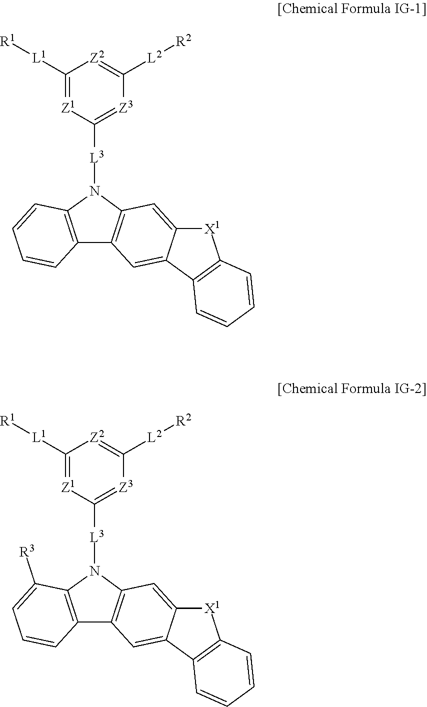

In Chemical Formula IG-1 and Chemical Formula IG-2, the definitions of Z¹ to Z³, L¹ to L³, R¹, R², and X¹ are the same as described above, and R³ may be a substituted or unsubstituted phenyl group, or a substituted or unsubstituted biphenyl group.

For example, Chemical Formula IH may be represented by Chemical Formula IH-1.

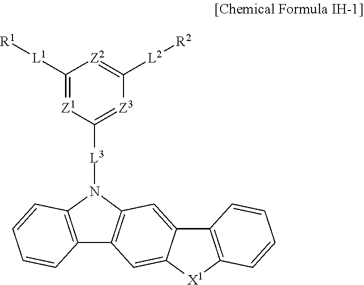

In Chemical Formula IH-1, the definitions of Z¹ to Z³, L¹ to L³, R¹, R², and X¹ are the same as described above.

For example, Chemical Formula II may be represented by Chemical Formula II-1 or Chemical Formula II-2.

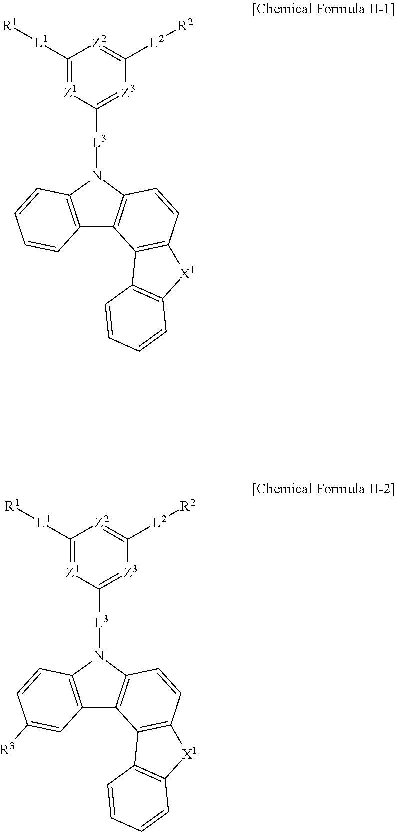

In Chemical Formula II-1 and Chemical Formula II-2, the definitions of Z¹ to Z³, L¹ to L³, R¹, R², and X¹ are the same as described above, and R³ may be a substituted or unsubstituted phenyl group, or a substituted or unsubstituted biphenyl group.

The second compound having the hole characteristics has a structure in which a carbazole or carbazole derivative is substituted with a substituted or unsubstituted C6 to C30 aryl group, a substituted or unsubstituted dibenzofuranyl group, or a substituted or unsubstituted dibenzothiophenyl group and is represented by Chemical Formula II.

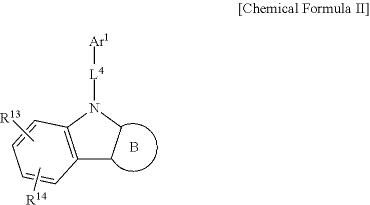

In Chemical Formula II,

L⁴ is a single bond, a substituted or unsubstituted C6 to C20 arylene group, a substituted or unsubstituted C2 to C20 heterocyclic group, or a combination thereof,

Ar¹ is a substituted or unsubstituted C6 to C30 aryl group, a substituted or unsubstituted dibenzofuranyl group, a substituted or unsubstituted dibenzothiophenyl group, or a combination thereof,

R¹³ and R¹⁴ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and

ring B is represented by any one of Chemical Formula II-1 to Chemical Formula II-4:

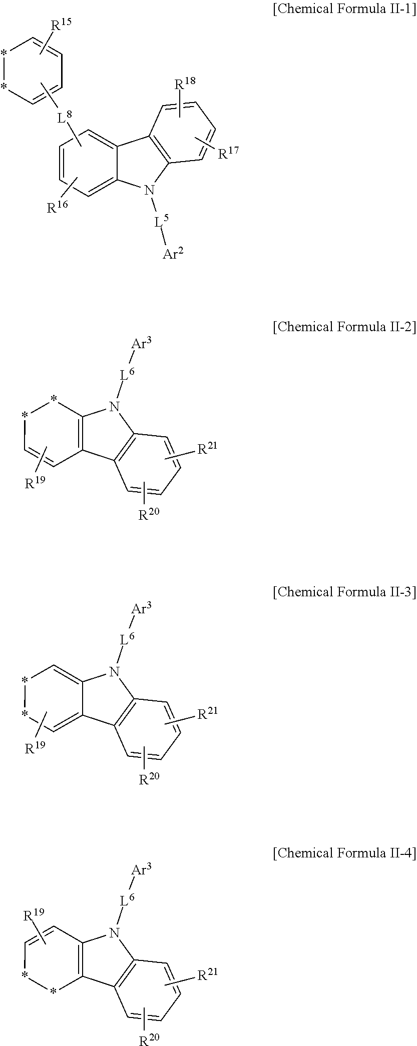

wherein, in Chemical Formula II-1 to Chemical Formula II-4,

L⁵ and L⁶ are each independently a single bond, a substituted or unsubstituted C6 to C20 arylene group, a substituted or unsubstituted C2 to C20 heterocyclic group, or a combination thereof,

L⁸ is a single bond, or a substituted or unsubstituted C6 to C20 arylene group,

Ar² and Ar³ are a substituted or unsubstituted C6 to C30 aryl group, a substituted or unsubstituted dibenzofuranyl group, a substituted or unsubstituted dibenzothiophenyl group, or a combination thereof,

R¹⁵ to R²¹ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and

* is a linking point.

Specifically, in Chemical Formula II, L⁴ may be a single bond or a C6 to C12 arylene group.

For example, in Chemical Formula II, L⁴ may be a single bond or a substituted or unsubstituted phenyl group.

In Chemical Formula II, Ar¹ may be a substituted or unsubstituted phenyl group, a substituted or unsubstituted biphenyl group, a substituted or unsubstituted terphenyl group, a substituted or unsubstituted fluorenyl group, a substituted or unsubstituted dibenzofuranyl group, or a substituted or unsubstituted dibenzothiophenyl group.

For example, in Chemical Formula II, Ar¹ may be a substituted or unsubstituted meta-biphenyl group or a substituted or unsubstituted para-biphenyl group.

According to the specific structure of the carbazole and carbazole derivative, Chemical Formula II may be represented, for example, by any one of Chemical Formula IIA to Chemical Formula IIF.

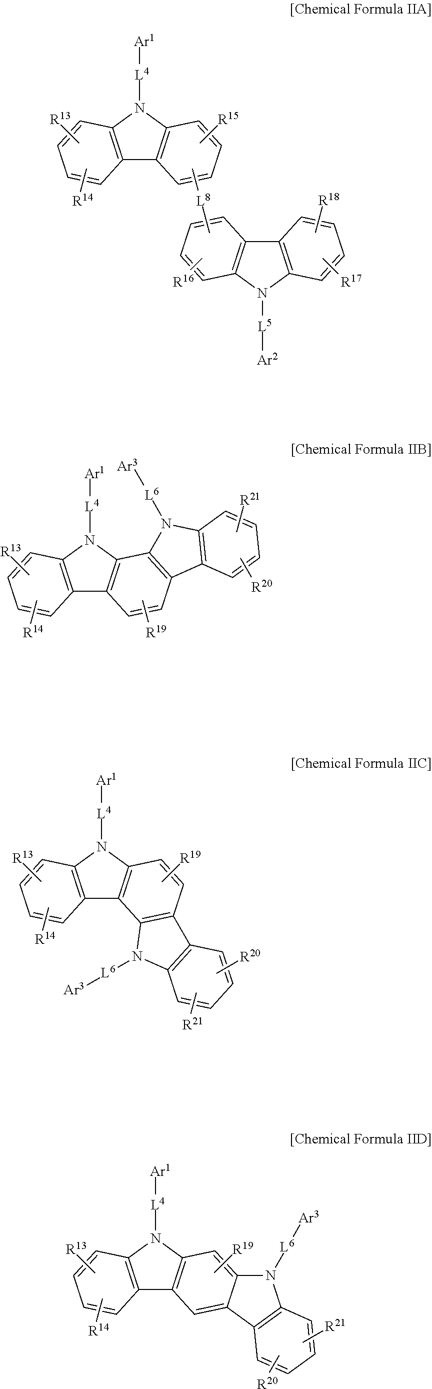

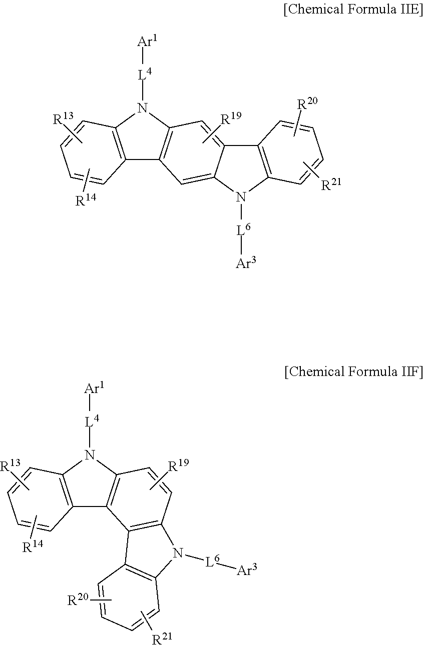

In Chemical Formula IIA to Chemical Formula IIF, the definitions of L⁴ to L⁶, L⁸, Ar¹ to Ar³, and R¹³ to R²¹ are the same as described above.

Specifically, in Chemical Formula IIA, R¹³ to R¹⁸ may each independently be hydrogen, a substituted or unsubstituted phenyl group, or a substituted or unsubstituted carbazolyl group.

For example, in Chemical Formula IIA, R¹³ to R¹⁸ may each independently be hydrogen or a substituted or unsubstituted phenyl group.

Specifically, in Chemical Formula IIA, L⁵ may be a single bond or a substituted or unsubstituted C6 to C12 arylene group.

For example, in Chemical Formula IIA, L⁵ may be a single bond or a substituted or unsubstituted phenylene group.

Specifically, in Chemical Formula IIA, L⁸ may be a single bond or a substituted or unsubstituted C6 to C12 arylene group.

For example, in Chemical Formula IIA, L⁸ may be a single bond or a substituted or unsubstituted phenylene group.

Specifically, in Chemical Formula IIA, Ar² may be a substituted or unsubstituted phenyl group or a substituted or unsubstituted biphenyl group, a substituted or unsubstituted terphenyl group, a substituted or unsubstituted naphthyl group, a substituted or unsubstituted anthracenyl group, a substituted or unsubstituted phenanthrenyl group, a substituted or unsubstituted triphenylene group, a substituted or unsubstituted fluorenyl group, a substituted or unsubstituted dibenzofuranyl group, or a substituted or unsubstituted dibenzothiphenyl group.

For example, in Chemical Formula IIA, Ar² may be a substituted or unsubstituted phenyl group or a substituted or unsubstituted biphenyl group.

Specifically, in Chemical Formula IIB to Chemical Formula IIF, R¹³, R¹⁴, and R¹⁹ to R²¹ may each independently be hydrogen, a substituted or unsubstituted phenyl group, a substituted or unsubstituted triphenylene group, a substituted or unsubstituted carbazolyl group.

For example, in Chemical Formula IIB to Chemical Formula IIF, R¹³, R¹⁴, and R¹⁹ to R²¹ may each independently be hydrogen or a substituted or unsubstituted phenyl group.

Specifically, in Chemical Formula IIB to Chemical Formula IIF, L⁶ may be a single bond or a substituted or unsubstituted phenylene group.

For example, in Chemical Formula IIB to Chemical Formula IIF, L⁶ may be a single bond or a substituted or unsubstituted phenylene group.

Specifically, in Chemical Formula IIB to Chemical Formula IIF, Ar³ may be a substituted or unsubstituted phenyl group, a substituted or unsubstituted biphenyl group, a substituted or unsubstituted terphenyl group, a substituted or unsubstituted triphenylene group, a substituted or unsubstituted carbazolyl group, a substituted or unsubstituted dibenzofuranyl group, or a substituted or unsubstituted dibenzothiophenyl group.

For example, Chemical Formula IIB to Chemical Formula IIF, Ar³ may be a substituted or unsubstituted phenyl group or a substituted or unsubstituted biphenyl group.

For example, Chemical Formula IIA may be represented by any one of Chemical Formula IIA-1 to Chemical Formula IIA-3.

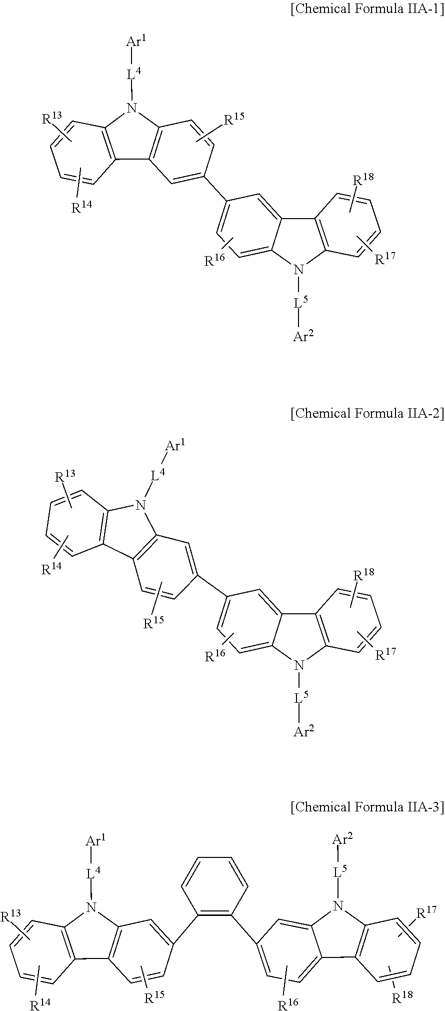

In Chemical Formula IIA-1 to Chemical Formula IIA-3, the definitions of L⁴, L⁵, Ar¹, Ar², and R¹³ to R¹⁸ are the same as described above.

The third compound having the buffer characteristics may be represented by Chemical Formula IIIA in which triphenylene is substituted with spirofluorene or may be represented by Chemical Formula IIIB in which triphenylene is substituted with a dibenzofuranyl group (or dibenzothiophenyl group).

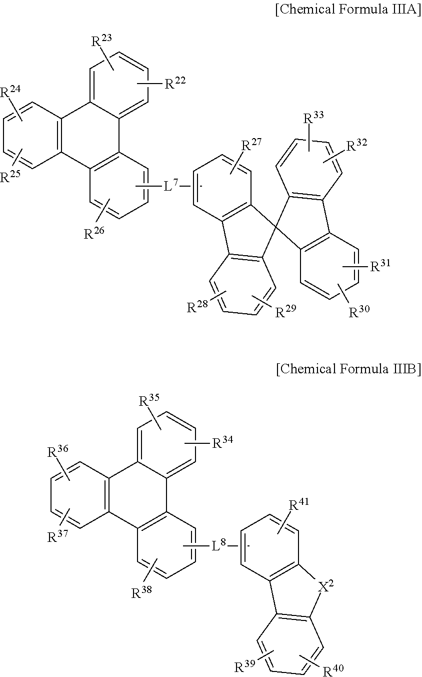

In Chemical Formula IIIA and Chemical Formula IIIB,

L⁷ and L⁸ are each independently a single bond, a substituted or unsubstituted C6 to C20 arylene group, a substituted or unsubstituted C2 to C20 heterocyclic group, or a combination thereof,

R²² to R⁴¹ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and

X² is O or S.

According to the first embodiment of the present invention, the third compound may be represented by Chemical Formula IIIA.

In the first embodiment, the first compound may be represented by Chemical Formula IA or Chemical Formula IE.

For example, the first compound according to the first embodiment may be represented by Chemical Formula IA.

In the first embodiment, the second compound may be represented by Chemical Formula IIA or Chemical Formula IIF.

For example, the second compound according to the first embodiment may be represented by Chemical Formula IIA-I or Chemical Formula IIA-2.

As a specific example, the second compound according to the first embodiment may be represented by any one of Chemical Formula IIA-1, Chemical Formula IIA-2, and Chemical Formula IIF.

For example, the third compound according to the first embodiment may be represented by any one of Chemical Formula IIIA-1 to Chemical Formula IIIA-4.

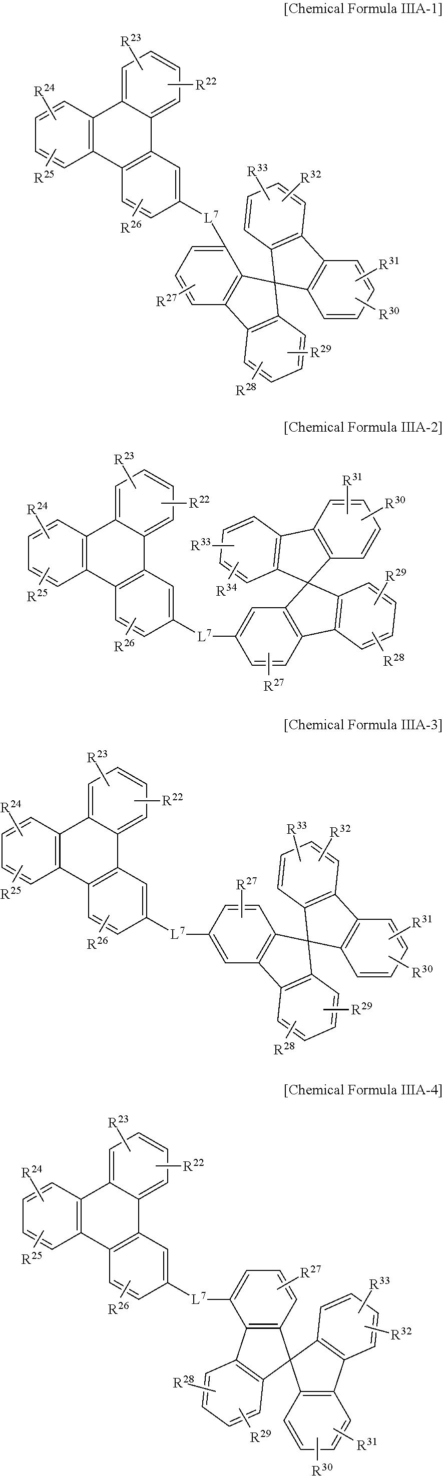

In Chemical Formula IIIA-1 to Chemical Formula IIIA-4, the definitions of L⁷ and R²² to R³³ are the same as described above.

As a specific example, the third compound according to the first embodiment may be represented by Chemical Formula IIIA-4, and in Chemical Formula IIIA-4, L⁷ may be a single bond or a substituted or unsubstituted phenylene group, and R²² to R³³ may be hydrogen, a substituted or unsubstituted phenyl group, or a substituted or unsubstituted carbazolyl group.

According to the most specific first embodiment, the first compound may be represented by Chemical Formula IA-1 or Chemical Formula IA-4, the second compound is represented by any one of Chemical Formula IIA-1, Chemical Formula IIA-2 and Chemical Formula IIF, and the third compound may be represented by Chemical Formula IIIA-4.

In Chemical Formula IA-1 and Chemical Formula IA-4, the definitions of Z¹ to Z³, L¹ to L³, R¹, and R² are the same as described above, and R³ may be a substituted or unsubstituted phenyl group, a substituted or unsubstituted biphenyl group, a substituted or unsubstituted terphenyl group, a substituted or unsubstituted carbazolyl group, a substituted or unsubstituted indolocarbazolyl group, a substituted or unsubstituted dibenzofuranyl group, or a substituted or unsubstituted dibenzothiophenyl group.

In Chemical Formula IIA-1, Chemical Formula IIA-2, and Chemical Formula IIF, L⁴ and L⁵ may each independently be a single bond or a substituted or unsubstituted phenylene group, Ar¹ and Ar² may each independently be a substituted or unsubstituted phenyl group or a substituted or unsubstituted biphenyl group, and R¹³ to R¹⁸ may each be hydrogen or a substituted or unsubstituted phenyl group.

In Chemical Formula IIIA-4, L⁷ may be a meta-phenylene group or a para-phenylene group, and R²² to R³³ may each be hydrogen.

According to the second embodiment of the present invention, the third compound may be represented by Chemical Formula IIIB.

In the second embodiment, the first compound may be represented by any one of the aforementioned Chemical Formula IA, and Chemical Formula ID to Chemical Formula IJ.

For example, the first compound according to the second embodiment may be represented by Chemical Formula IA or Chemical Formula IE.

In the second embodiment, the second compound may be represented by the aforementioned Chemical Formula IIA or Chemical Formula IIF.

For example, the second compound according to the second embodiment may be represented by any one of Chemical Formula IIA-1 to Chemical Formula IIA-3.

As a specific example, the second compound according to the second embodiment may be represented by any one of Chemical Formula IIA-1, Chemical Formula IIA-2 and Chemical Formula IIF.

In Chemical Formula IIA-1, Chemical Formula IIA-2, and Chemical Formula IIF, R¹³ to R²¹ may each be hydrogen, L⁴ to L⁶ may each independently be a single bond or a substituted or unsubstituted phenylene group, and Ar¹ to Ar³ may each independently be a substituted or unsubstituted phenyl group, or a substituted or unsubstituted biphenyl group.

For example, the third compound according to the second embodiment may be represented by Chemical Formula IIIB-1 to Chemical Formula IIIB-4.

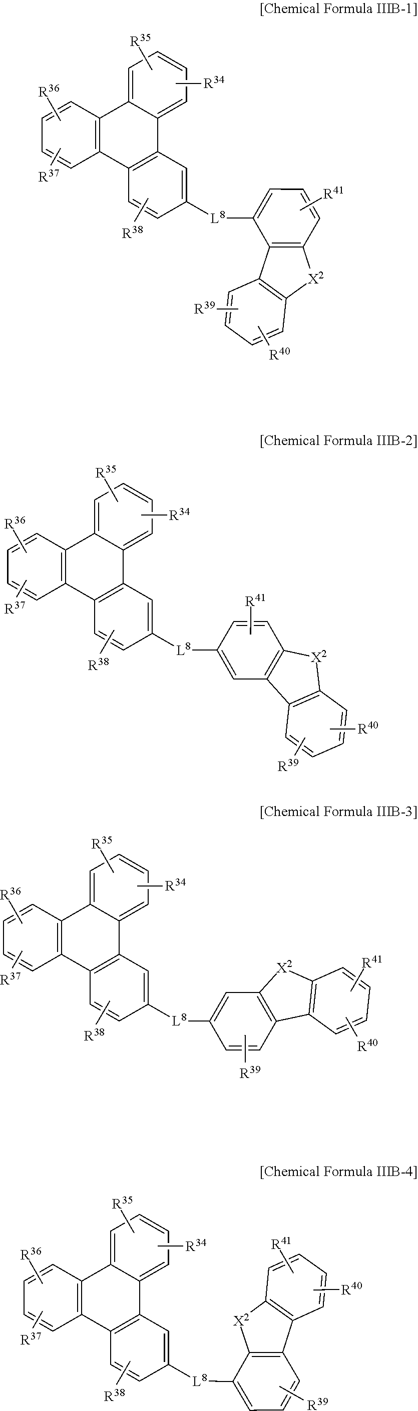

In Chemical Formula IIIB-1 to Chemical Formula IIIB-4, the definitions of X², L⁸, and R³⁴ to R⁴¹ are the same as described above.

As a specific example, the third compound according to the second embodiment may be represented by Chemical Formula IIIB-1 or Chemical Formula IIIB-4.

According to the second most specific embodiment, the first compound may be represented by Chemical Formula IA-1, the second compound may be represented by Chemical Formula IIA-1, and the third compound may be represented by Chemical Formula IIIA-4.

In Chemical Formula IA-1, Z¹ to Z³ may each be N, L¹ to L³ may each independently be a single bond or an unsubstituted phenylene group, and R¹ and R² may each independently be a substituted or unsubstituted phenyl group, a substituted or unsubstituted a biphenyl group, a substituted or unsubstituted carbazolyl group, a substituted or unsubstituted dibenzofuranyl group, or a substituted or unsubstituted dibenzothiophenyl group, in Chemical Formula IIA-1, R¹³ to R¹⁸ may each independently be hydrogen, a substituted or unsubstituted phenyl group, a substituted or unsubstituted carbazolyl group, a substituted or unsubstituted dibenzofuranyl group, or a substituted or unsubstituted dibenzothiophenyl group, L⁴ and L⁵ may each independently be a single bond, or a substituted or unsubstituted phenylene group, a substituted or unsubstituted biphenylene group, a substituted or unsubstituted naphthylene group, a substituted or unsubstituted dibenzofuranylene group, or a substituted or unsubstituted dibenzothiophenylene group, and Ar¹ and Ar² may each independently be a substituted or unsubstituted phenyl group, a substituted or unsubstituted biphenyl group, a substituted or unsubstituted terphenyl group, a substituted or unsubstituted naphthyl group, a substituted or unsubstituted phenanthrene group, a substituted or unsubstituted triphenylene group, a substituted or unsubstituted fluorenyl group, a substituted or unsubstituted dibenzofuranyl group, or a substituted or unsubstituted dibenzothiophenyl group, and

in Chemical Formula III-4, X² may be O or S, R²² to R²⁹ may each independently be hydrogen or a substituted or unsubstituted phenyl group, and L⁷ may be selected from linking groups of Group I.

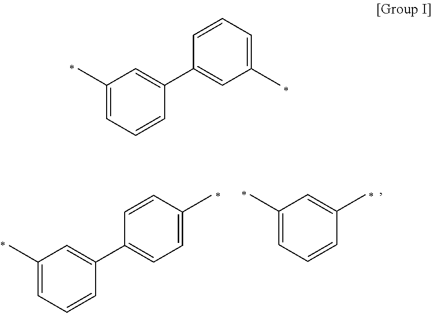

According to another most specific second embodiment, the first compound may be represented by Chemical Formula IE-1, the second compound may be represented by Chemical Formula IIA-1, and the third compound may be represented by Chemical Formula IIIA-1 or Chemical Formula IIIA-4.

In Chemical Formula IE-1, X¹ may be NR^{b} or O, R^{b} may be a substituted or unsubstituted phenyl group, a substituted or unsubstituted biphenyl group, or a substituted or unsubstituted terphenyl group, Z¹ to Z³ are may each be N, L¹ to L³ may each independently be a single bond, or a substituted or unsubstituted phenylene group, and R¹ and R² may each independently be a substituted or unsubstituted phenyl group, or a substituted or unsubstituted biphenyl group,

in Chemical Formula IIA-1, R¹³ to R¹⁸ may each independently be hydrogen, a substituted or unsubstituted phenyl group, a substituted or unsubstituted carbazolyl group, a substituted or unsubstituted dibenzofuranyl group, or a substituted or unsubstituted dibenzothiophenyl group, L⁴ and L⁵ may each independently be a single bond, or a substituted or unsubstituted phenylene group, a substituted or unsubstituted biphenylene group, a substituted or unsubstituted naphthylene group, a substituted or unsubstituted dibenzofuranylene group, or a substituted or unsubstituted dibenzothiophenylene group, and Ar¹ and Ar² may each independently be a substituted or unsubstituted phenyl group, a substituted or unsubstituted biphenyl group, a substituted or unsubstituted terphenyl group, a substituted or unsubstituted naphthyl group, a substituted or unsubstituted phenanthrene group, a substituted or unsubstituted triphenylene group, a substituted or unsubstituted fluorenyl group, a substituted or unsubstituted dibenzofuranyl group, or a substituted or unsubstituted dibenzothiophenyl group, and

in Chemical Formula III-1 and Chemical Formula III-4, X² may be O or S, R²² to R²⁹ may each independently be hydrogen or a substituted or unsubstituted phenyl group, and L⁷ may be selected from linking groups of Group I.

On the other hand, the aforementioned composition for an organic optoelectronic element is a composition in which the first compound, the second compound, and the third compound are mixed, wherein the first compound may be included in an amount of 20 wt % to 50 wt % based on the total weight of the first compound, the second compound, and the third compound, the second compound may be included in an amount of 40 wt % to 60 wt % based on the total weight of the first compound, the second compound, and the third compound, and the third compound may be included in an amount of 10 wt % to 30 wt % based on the total weight of the first compound, the second compound, and the third compound.

Within the above range, for example, the first compound for an organic optoelectronic element may be included in an amount of about 25 wt % to 45 wt % based on the total weight of the first compound for an organic optoelectronic element, the second compound for an organic optoelectronic element, and the third compound for an organic optoelectronic element included in weight, the second compound for an organic optoelectronic element may be included in an amount of about 45 wt % to 60 wt % based on the total weight of the first compound for an organic optoelectronic element, the second compound for an organic optoelectronic element, and the third compound for an organic optoelectronic element, and the third compound for an organic optoelectronic element may be included in an amount of about about 10 wt % to 25 wt % based on the total weight of the first compound for an organic optoelectronic element, the second compound for an organic optoelectronic element, and the third compound for an organic optoelectronic element.

In addition, as a specific example, the first compound may be included in an amount of about 30 wt % to 40 wt % based on the total weight of the first compound, the second compound, and the third compound, the second compound may be included in an amount of about 45 wt % to 55 wt % based on the total weight of the first compound, the second compound, and the third compound, and the third compound may be included in an amount of about 10 wt % to 20 wt % based on the total weight of the first compound, the second compound, and the third compound.

As a more specific example, the composition for an organic optoelectronic element includes the first compound: the second compound: the third compound in a weight ratio of about 40:50:10, about 35:55:10, or a weight ratio of about 32:48:20.

Within the above range, the electron transport capability of the first compound, the hole transport capability of the second compound, and the buffering capability of the third compound are properly harmonized to improve efficiency and life-span of the device.

The first compound may be, for example, one selected from the compounds of Group 1.

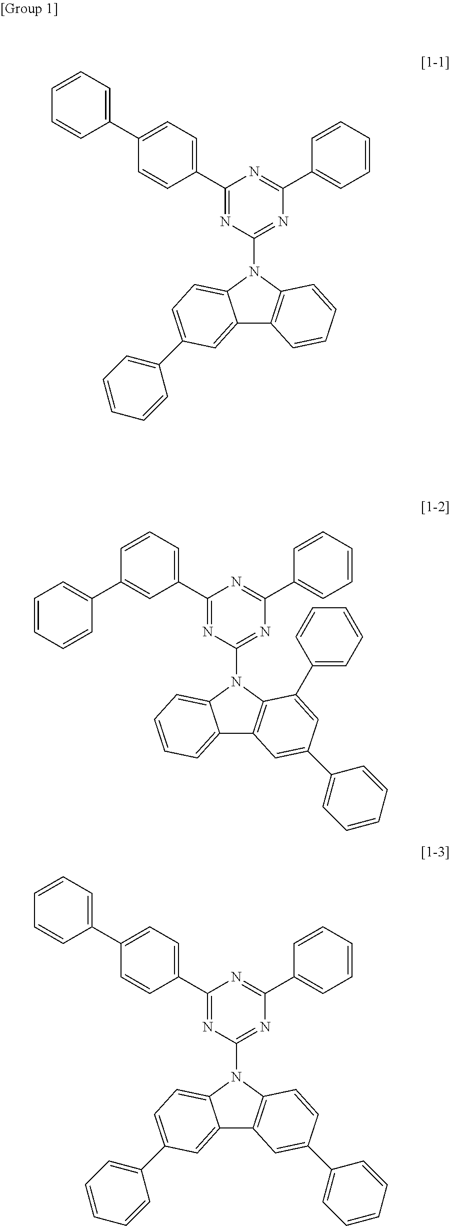 [SMILES: c1ccc(-c2ccc(-c3nc(-c4ccccc4)nc(-n4c5ccccc5c5cc(-c6ccccc6)ccc54)n3)cc2)cc1 ; c1ccc(-c2cccc(-c3nc(-c4ccccc4)nc(-n4c5ccccc5c5cc(-c6ccccc6)cc(-c6ccccc6)c54)n3)c2)cc1 ; c1ccc(-c2ccc(-c3nc(-c4ccccc4)nc(-n4c5ccc(-c6ccccc6)cc5c5cc(-c6ccccc6)ccc54)n3)cc2)cc1]

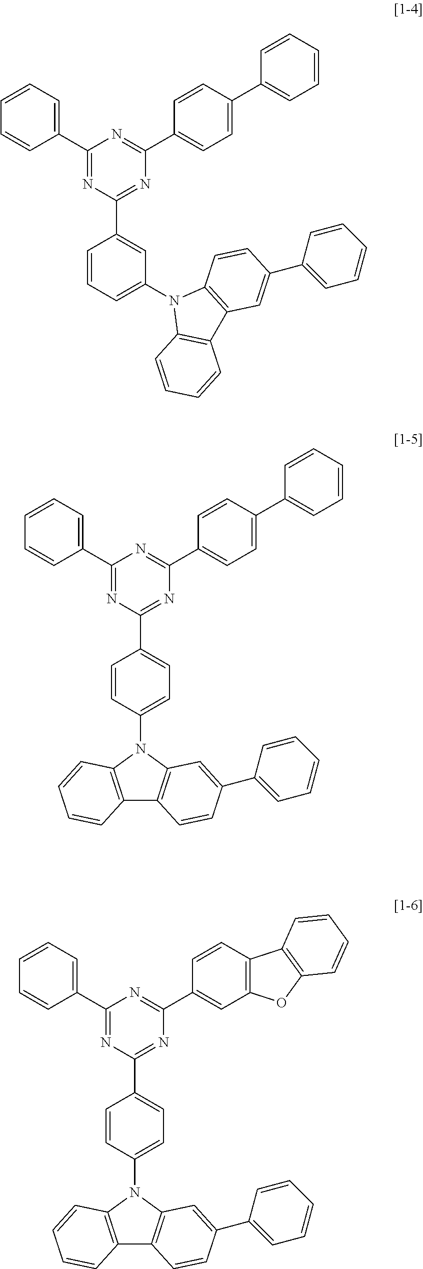 [SMILES: c1ccc(-c2ccc(-c3nc(-c4ccccc4)nc(-c4cccc(-n5c6ccccc6c6cc(-c7ccccc7)ccc65)c4)n3)cc2)cc1 ; c1ccc(-c2ccc(-c3nc(-c4ccccc4)nc(-c4ccc(-n5c6ccccc6c6ccc(-c7ccccc7)cc65)cc4)n3)cc2)cc1 ; c1ccc(-c2ccc3c4ccccc4n(-c4ccc(-c5nc(-c6ccccc6)nc(-c6ccc7c(c6)oc6ccccc67)n5)cc4)c3c2)cc1]

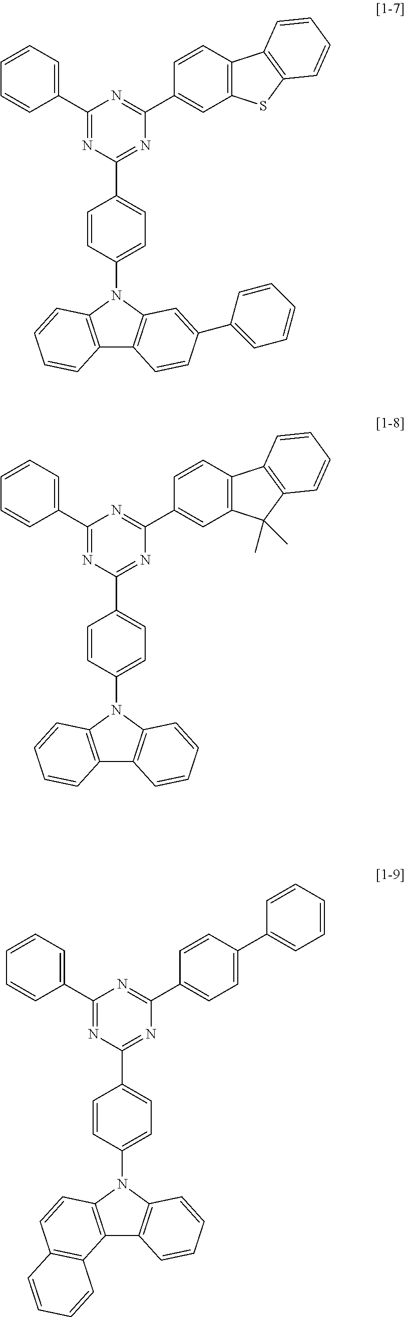 [SMILES: c1ccc(-c2ccc3c4ccccc4n(-c4ccc(-c5nc(-c6ccccc6)nc(-c6ccc7c(c6)sc6ccccc67)n5)cc4)c3c2)cc1 ; CC1(C)c2ccccc2-c2ccc(-c3nc(-c4ccccc4)nc(-c4ccc(-n5c6ccccc6c6ccccc65)cc4)n3)cc21 ; c1ccc(-c2ccc(-c3nc(-c4ccccc4)nc(-c4ccc(-n5c6ccccc6c6c7ccccc7ccc65)cc4)n3)cc2)cc1]

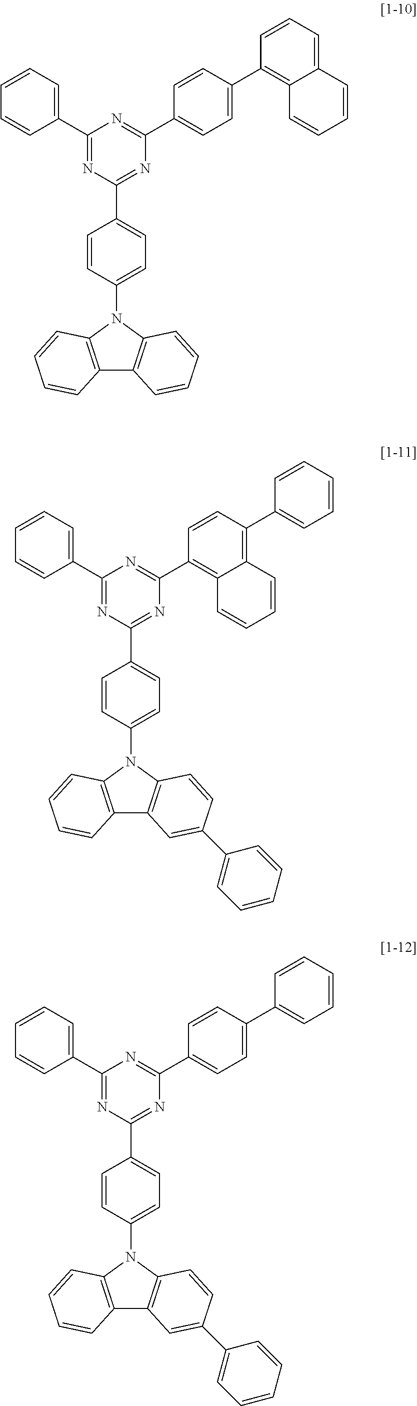 [SMILES: c1ccc(-c2nc(-c3ccc(-c4cccc5ccccc45)cc3)nc(-c3ccc(-n4c5ccccc5c5ccccc54)cc3)n2)cc1 ; c1ccc(-c2ccc3c(c2)c2ccccc2n3-c2ccc(-c3nc(-c4ccccc4)nc(-c4ccc(-c5ccccc5)c5ccccc45)n3)cc2)cc1 ; c1ccc(-c2ccc(-c3nc(-c4ccccc4)nc(-c4ccc(-n5c6ccccc6c6cc(-c7ccccc7)ccc65)cc4)n3)cc2)cc1]

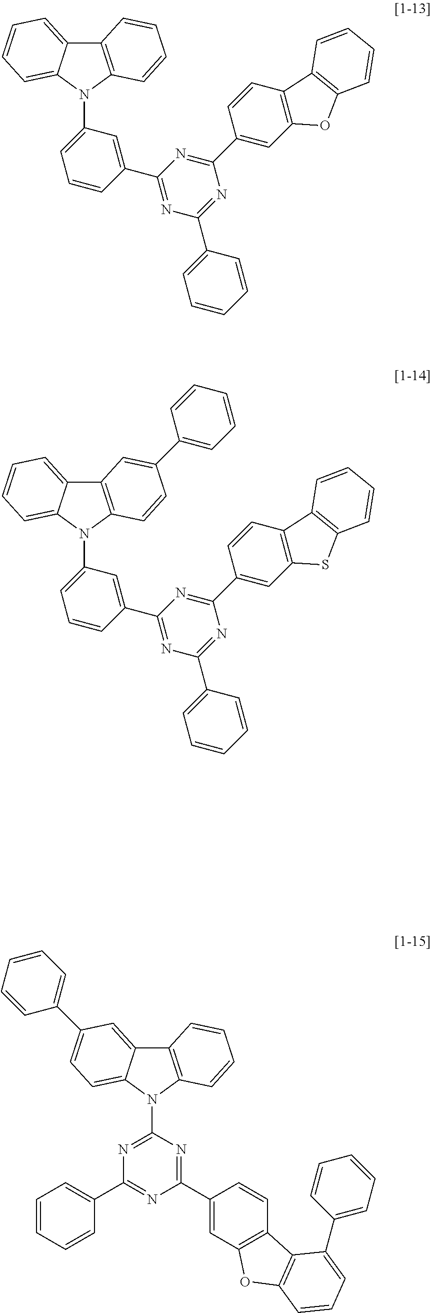 [SMILES: c1ccc(-c2nc(-c3cccc(-n4c5ccccc5c5ccccc54)c3)nc(-c3ccc4c(c3)oc3ccccc34)n2)cc1 ; c1ccc(-c2ccc3c(c2)c2ccccc2n3-c2cccc(-c3nc(-c4ccccc4)nc(-c4ccc5c(c4)sc4ccccc45)n3)c2)cc1 ; c1ccc(-c2ccc3c(c2)c2ccccc2n3-c2nc(-c3ccccc3)nc(-c3ccc4c(c3)oc3cccc(-c5ccccc5)c34)n2)cc1]

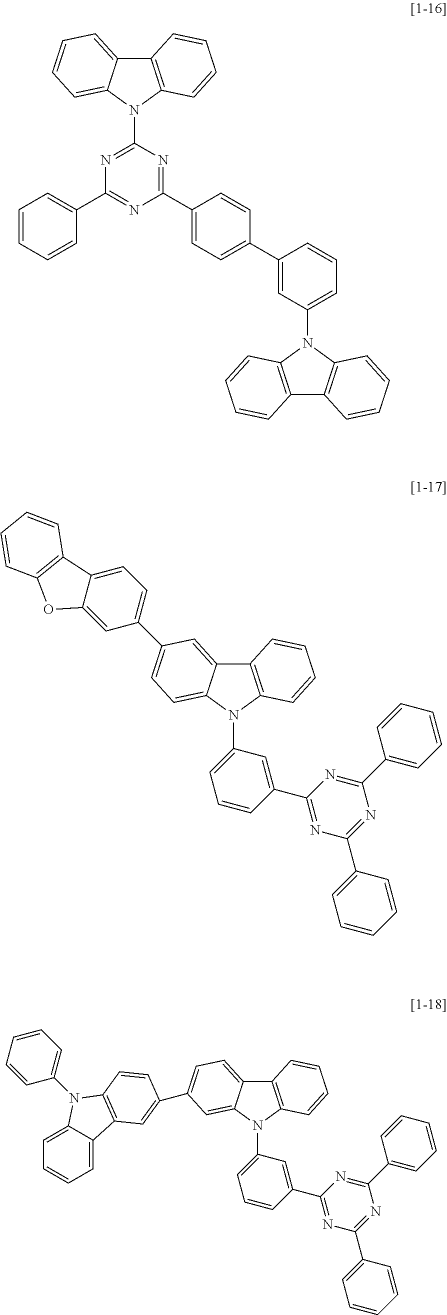 [SMILES: c1ccc(-c2nc(-c3ccc(-c4cccc(-n5c6ccccc6c6ccccc65)c4)cc3)nc(-n3c4ccccc4c4ccccc43)n2)cc1 ; c1ccc(-c2nc(-c3ccccc3)nc(-c3cccc(-n4c5ccccc5c5cc(-c6ccc7c(c6)oc6ccccc67)ccc54)c3)n2)cc1 ; c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1]

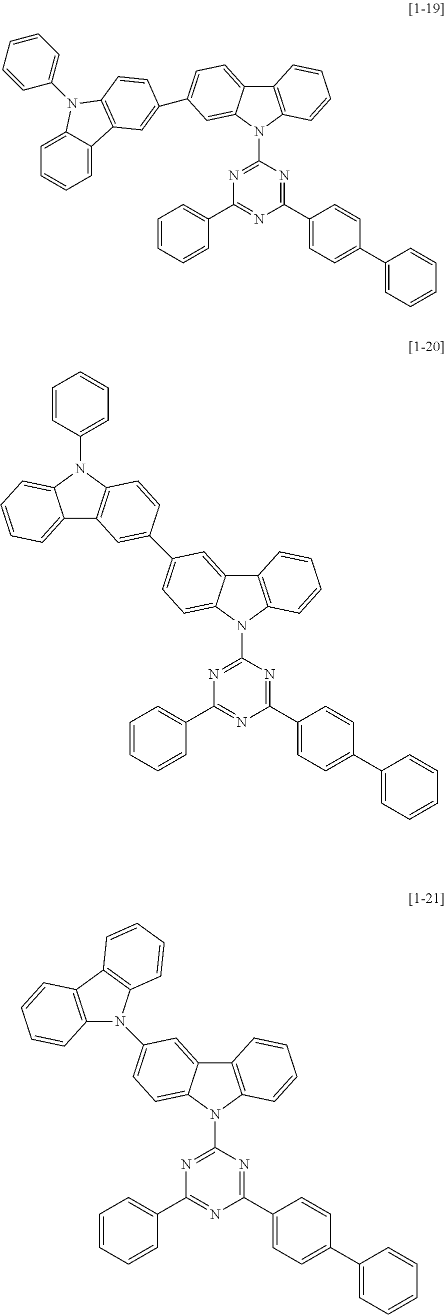 [SMILES: c1ccc(-c2ccc(-c3nc(-c4ccccc4)nc(-n4c5ccccc5c5ccc(-c6ccc7c(c6)c6ccccc6n7-c6ccccc6)cc54)n3)cc2)cc1 ; c1ccc(-c2ccc(-c3nc(-c4ccccc4)nc(-n4c5ccccc5c5cc(-c6ccc7c(c6)c6ccccc6n7-c6ccccc6)ccc54)n3)cc2)cc1 ; c1ccc(-c2ccc(-c3nc(-c4ccccc4)nc(-n4c5ccccc5c5cc(-n6c7ccccc7c7ccccc76)ccc54)n3)cc2)cc1]

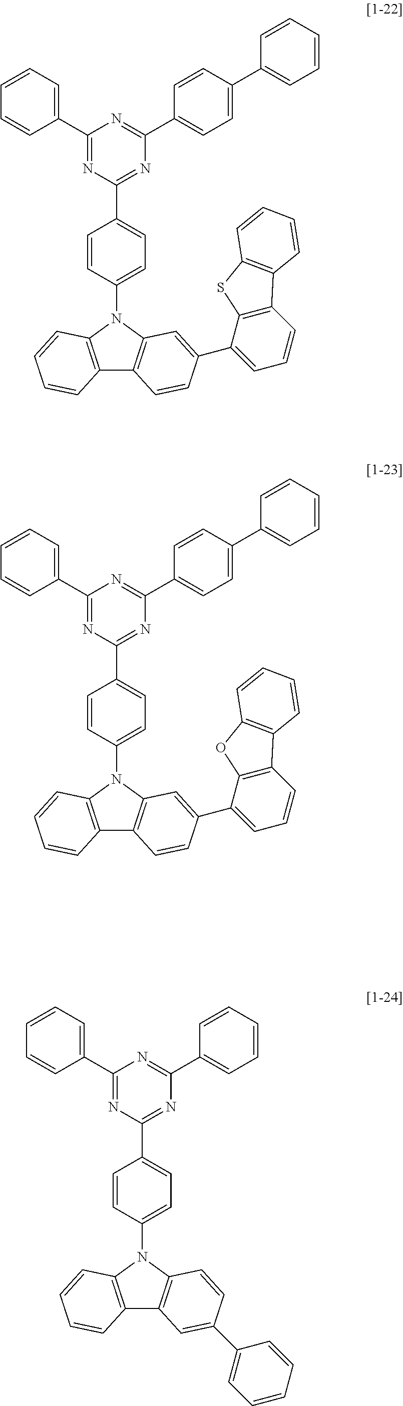 [SMILES: c1ccc(-c2ccc(-c3nc(-c4ccccc4)nc(-c4ccc(-n5c6ccccc6c6ccc(-c7cccc8c7sc7ccccc78)cc65)cc4)n3)cc2)cc1 ; c1ccc(-c2ccc(-c3nc(-c4ccccc4)nc(-c4ccc(-n5c6ccccc6c6ccc(-c7cccc8c7oc7ccccc78)cc65)cc4)n3)cc2)cc1 ; c1ccc(-c2ccc3c(c2)c2ccccc2n3-c2ccc(-c3nc(-c4ccccc4)nc(-c4ccccc4)n3)cc2)cc1]

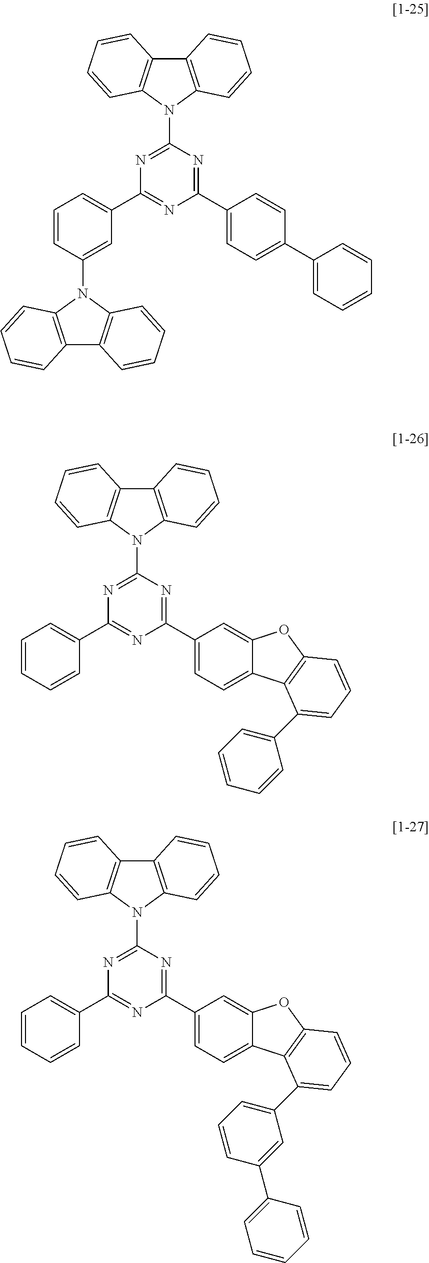 [SMILES: c1ccc(-c2ccc(-c3nc(-c4cccc(-n5c6ccccc6c6ccccc65)c4)nc(-n4c5ccccc5c5ccccc54)n3)cc2)cc1 ; c1ccc(-c2nc(-c3ccc4c(c3)oc3cccc(-c5ccccc5)c34)nc(-n3c4ccccc4c4ccccc43)n2)cc1 ; c1ccc(-c2cccc(-c3cccc4oc5cc(-c6nc(-c7ccccc7)nc(-n7c8ccccc8c8ccccc87)n6)ccc5c34)c2)cc1]

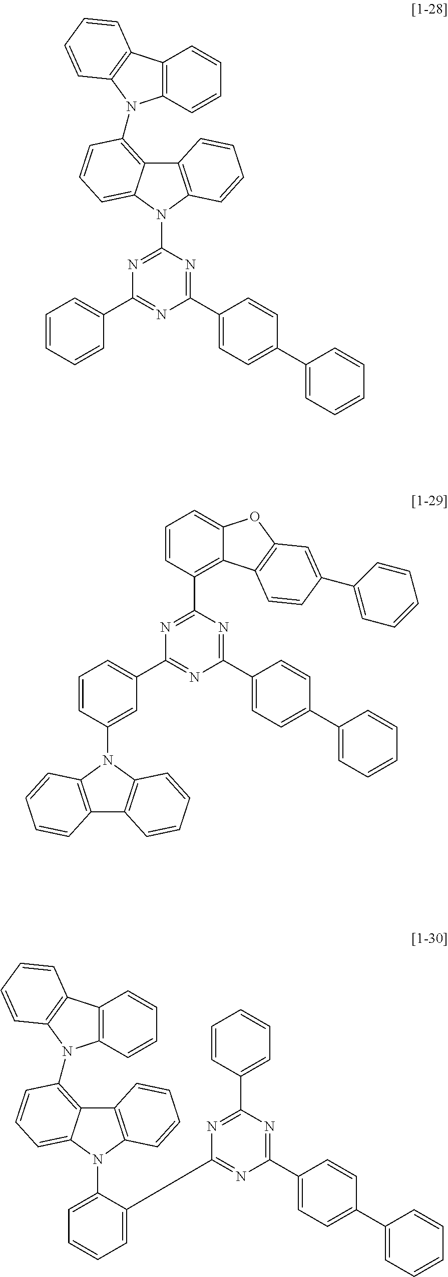 [SMILES: c1ccc(-c2ccc(-c3nc(-c4ccccc4)nc(-n4c5ccccc5c5c(-n6c7ccccc7c7ccccc76)cccc54)n3)cc2)cc1 ; c1ccc(-c2ccc(-c3nc(-c4cccc(-n5c6ccccc6c6ccccc65)c4)nc(-c4cccc5oc6cc(-c7ccccc7)ccc6c45)n3)cc2)cc1 ; c1ccc(-c2ccc(-c3nc(-c4ccccc4)nc(-c4ccccc4-n4c5ccccc5c5c(-n6c7ccccc7c7ccccc76)cccc54)n3)cc2)cc1]

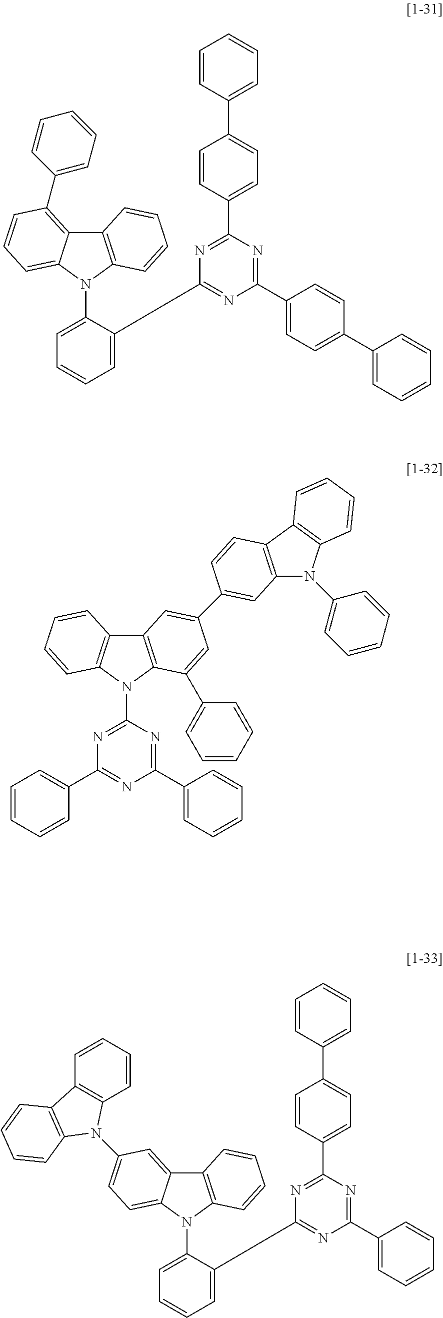 [SMILES: c1ccc(-c2ccc(-c3nc(-c4ccc(-c5ccccc5)cc4)nc(-c4ccccc4-n4c5ccccc5c5c(-c6ccccc6)cccc54)n3)cc2)cc1 ; c1ccc(-c2nc(-c3ccccc3)nc(-n3c4ccccc4c4cc(-c5ccc6c7ccccc7n(-c7ccccc7)c6c5)cc(-c5ccccc5)c43)n2)cc1 ; c1ccc(-c2ccc(-c3nc(-c4ccccc4)nc(-c4ccccc4-n4c5ccccc5c5cc(-n6c7ccccc7c7ccccc76)ccc54)n3)cc2)cc1]

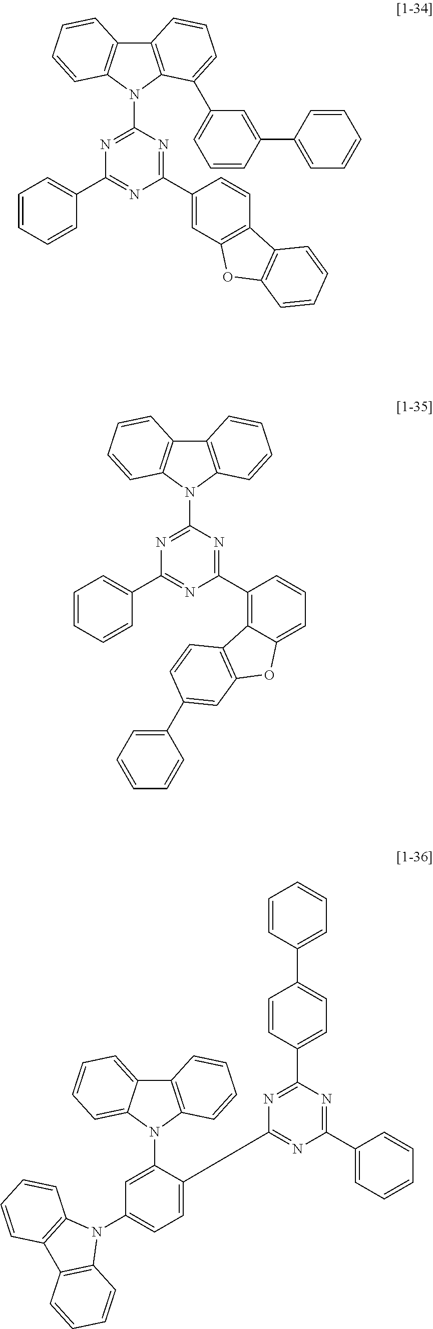 [SMILES: c1ccc(-c2cccc(-c3cccc4c5ccccc5n(-c5nc(-c6ccccc6)nc(-c6ccc7c(c6)oc6ccccc67)n5)c34)c2)cc1 ; c1ccc(-c2ccc3c(c2)oc2cccc(-c4nc(-c5ccccc5)nc(-n5c6ccccc6c6ccccc65)n4)c23)cc1 ; c1ccc(-c2ccc(-c3nc(-c4ccccc4)nc(-c4ccc(-n5c6ccccc6c6ccccc65)cc4-n4c5ccccc5c5ccccc54)n3)cc2)cc1]

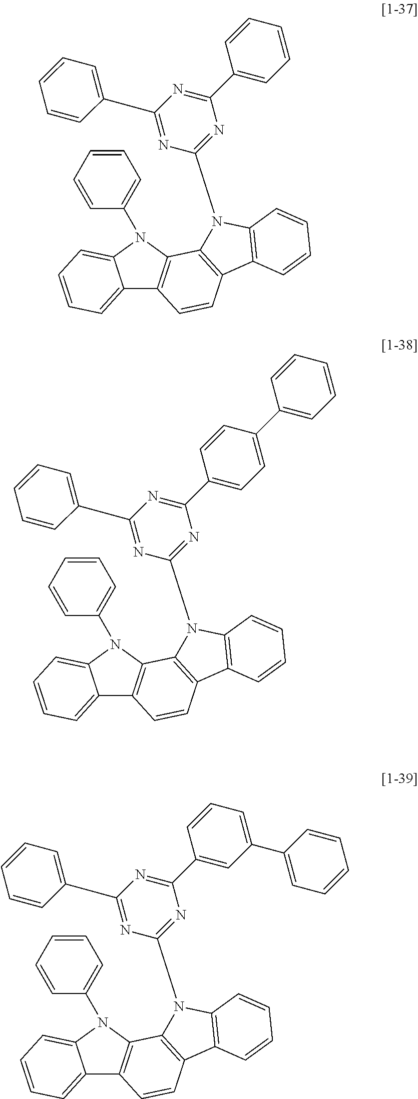 [SMILES: c1ccc(-c2nc(-c3ccccc3)nc(-n3c4ccccc4c4ccc5c6ccccc6n(-c6ccccc6)c5c43)n2)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-c2cccc(-c3nc(-c4ccccc4)nc(-n4c5ccccc5c5ccc6c7ccccc7n(-c7ccccc7)c6c54)n3)c2)cc1]

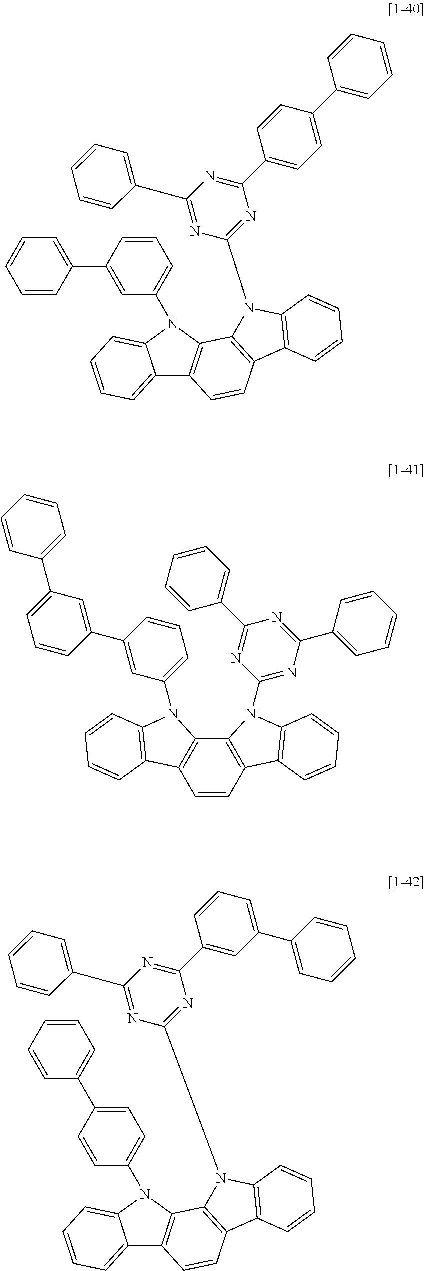 [SMILES: c1ccc(-c2ccc(-c3nc(-c4ccccc4)nc(-n4c5ccccc5c5ccc6c7ccccc7n(-c7cccc(-c8ccccc8)c7)c6c54)n3)cc2)cc1 ; c1ccc(-c2cccc(-c3cccc(-n4c5ccccc5c5ccc6c7ccccc7n(-c7nc(-c8ccccc8)nc(-c8ccccc8)n7)c6c54)c3)c2)cc1 ; c1ccc(-c2ccc(-n3c4ccccc4c4ccc5c6ccccc6n(-c6nc(-c7ccccc7)nc(-c7cccc(-c8ccccc8)c7)n6)c5c43)cc2)cc1]

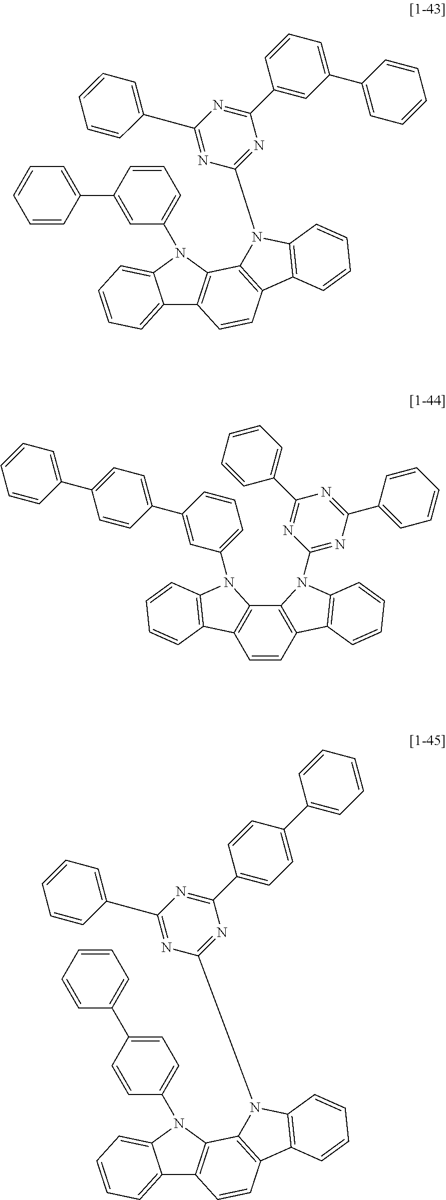 [SMILES: c1ccc(-c2cccc(-c3nc(-c4ccccc4)nc(-n4c5ccccc5c5ccc6c7ccccc7n(-c7cccc(-c8ccccc8)c7)c6c54)n3)c2)cc1 ; c1ccc(-c2ccc(-c3cccc(-n4c5ccccc5c5ccc6c7ccccc7n(-c7nc(-c8ccccc8)nc(-c8ccccc8)n7)c6c54)c3)cc2)cc1 ; c1ccc(-c2ccc(-c3nc(-c4ccccc4)nc(-n4c5ccccc5c5ccc6c7ccccc7n(-c7ccc(-c8ccccc8)cc7)c6c54)n3)cc2)cc1]

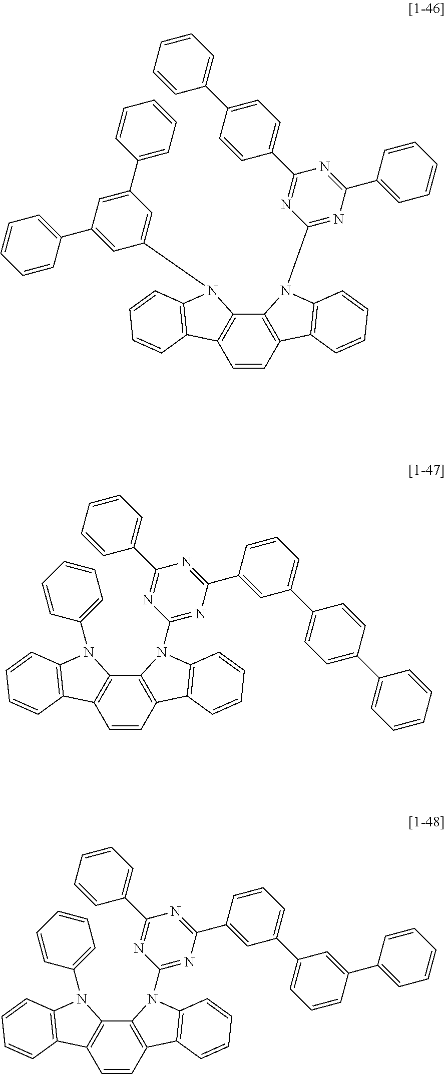 [SMILES: c1ccc(-c2ccc(-c3nc(-c4ccccc4)nc(-n4c5ccccc5c5ccc6c7ccccc7n(-c7cc(-c8ccccc8)cc(-c8ccccc8)c7)c6c54)n3)cc2)cc1 ; c1ccc(-c2ccc(-c3cccc(-c4nc(-c5ccccc5)nc(-n5c6ccccc6c6ccc7c8ccccc8n(-c8ccccc8)c7c65)n4)c3)cc2)cc1 ; c1ccc(-c2cccc(-c3cccc(-c4nc(-c5ccccc5)nc(-n5c6ccccc6c6ccc7c8ccccc8n(-c8ccccc8)c7c65)n4)c3)c2)cc1]

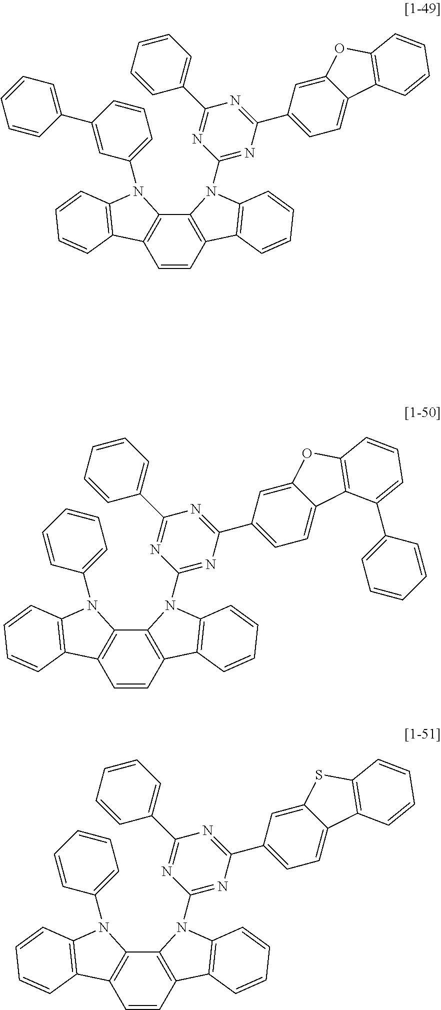 [SMILES: c1ccc(-c2cccc(-n3c4ccccc4c4ccc5c6ccccc6n(-c6nc(-c7ccccc7)nc(-c7ccc8c(c7)oc7ccccc78)n6)c5c43)c2)cc1 ; c1ccc(-c2nc(-c3ccc4c(c3)oc3cccc(-c5ccccc5)c34)nc(-n3c4ccccc4c4ccc5c6ccccc6n(-c6ccccc6)c5c43)n2)cc1 ; c1ccc(-c2nc(-c3ccc4c(c3)sc3ccccc34)nc(-n3c4ccccc4c4ccc5c6ccccc6n(-c6ccccc6)c5c43)n2)cc1]

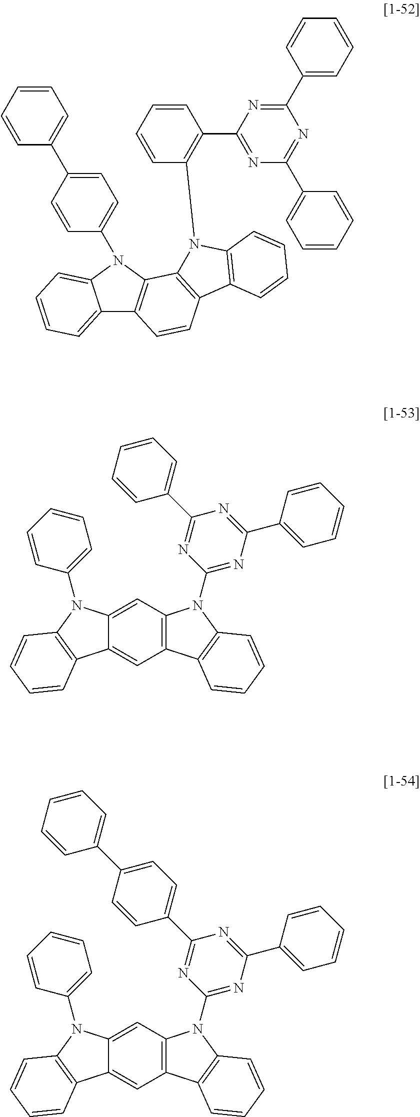 [SMILES: c1ccc(-c2ccc(-n3c4ccccc4c4ccc5c6ccccc6n(-c6ccccc6-c6nc(-c7ccccc7)nc(-c7ccccc7)n6)c5c43)cc2)cc1 ; c1ccc(-c2nc(-c3ccccc3)nc(-n3c4ccccc4c4cc5c6ccccc6n(-c6ccccc6)c5cc43)n2)cc1 ; c1ccc(-c2ccc(-c3nc(-c4ccccc4)nc(-n4c5ccccc5c5cc6c7ccccc7n(-c7ccccc7)c6cc54)n3)cc2)cc1]

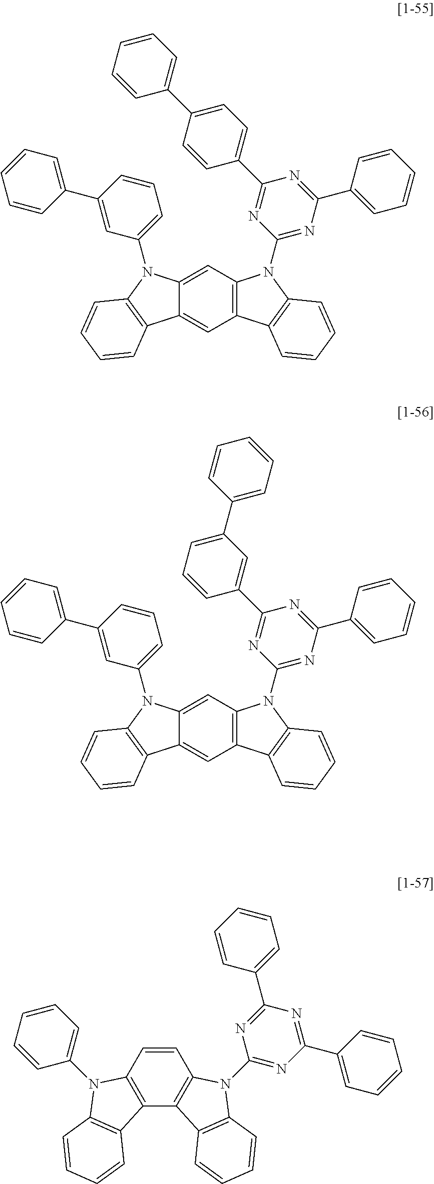 [SMILES: c1ccc(-c2ccc(-c3nc(-c4ccccc4)nc(-n4c5ccccc5c5cc6c7ccccc7n(-c7cccc(-c8ccccc8)c7)c6cc54)n3)cc2)cc1 ; c1ccc(-c2cccc(-c3nc(-c4ccccc4)nc(-n4c5ccccc5c5cc6c7ccccc7n(-c7cccc(-c8ccccc8)c7)c6cc54)n3)c2)cc1 ; c1ccc(-c2nc(-c3ccccc3)nc(-n3c4ccccc4c4c5c6ccccc6n(-c6ccccc6)c5ccc43)n2)cc1]

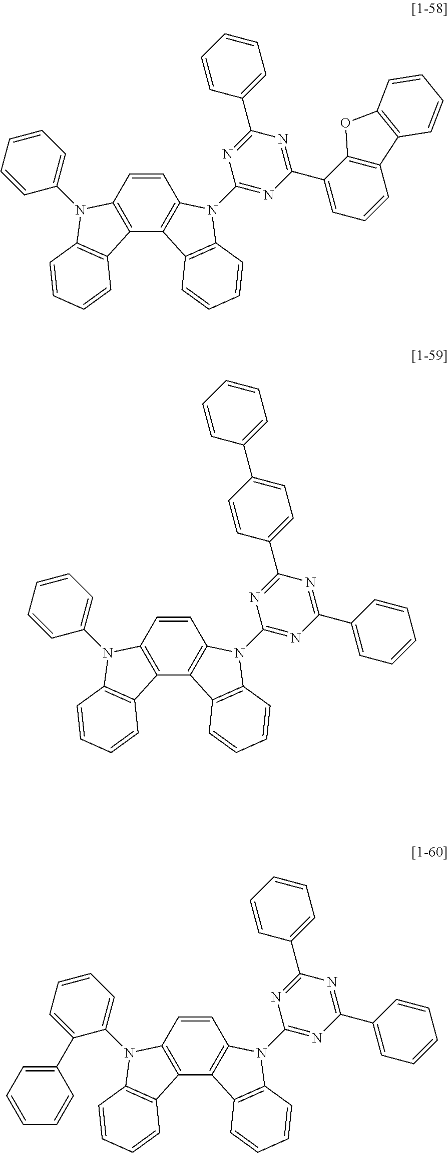 [SMILES: c1ccc(-c2nc(-c3cccc4c3oc3ccccc34)nc(-n3c4ccccc4c4c5c6ccccc6n(-c6ccccc6)c5ccc43)n2)cc1 ; c1ccc(-c2ccc(-c3nc(-c4ccccc4)nc(-n4c5ccccc5c5c6c7ccccc7n(-c7ccccc7)c6ccc54)n3)cc2)cc1 ; c1ccc(-c2nc(-c3ccccc3)nc(-n3c4ccccc4c4c5c6ccccc6n(-c6ccccc6-c6ccccc6)c5ccc43)n2)cc1]

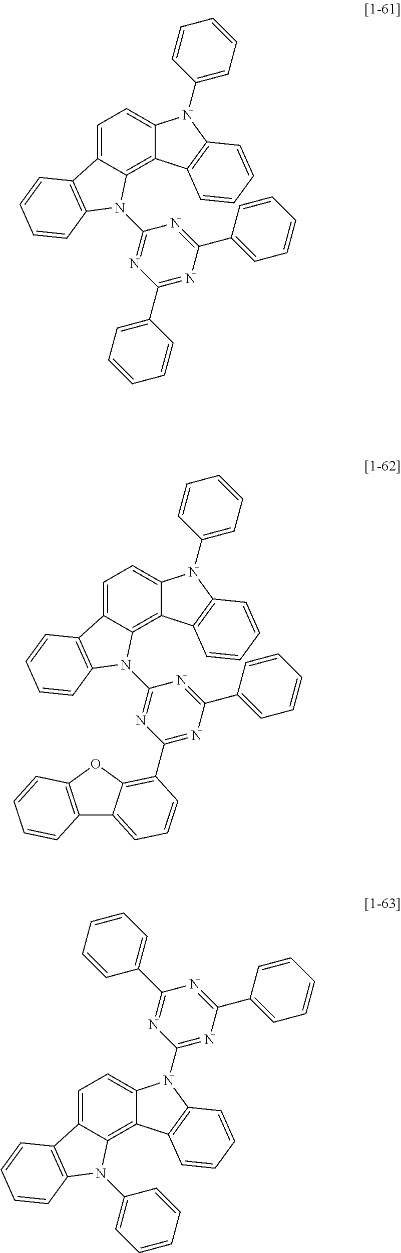 [SMILES: c1ccc(-c2nc(-c3ccccc3)nc(-n3c4ccccc4c4ccc5c(c6ccccc6n5-c5ccccc5)c43)n2)cc1 ; c1ccc(-c2nc(-c3cccc4c3oc3ccccc34)nc(-n3c4ccccc4c4ccc5c(c6ccccc6n5-c5ccccc5)c43)n2)cc1 ; c1ccc(-c2nc(-c3ccccc3)nc(-n3c4ccccc4c4c3ccc3c5ccccc5n(-c5ccccc5)c34)n2)cc1]

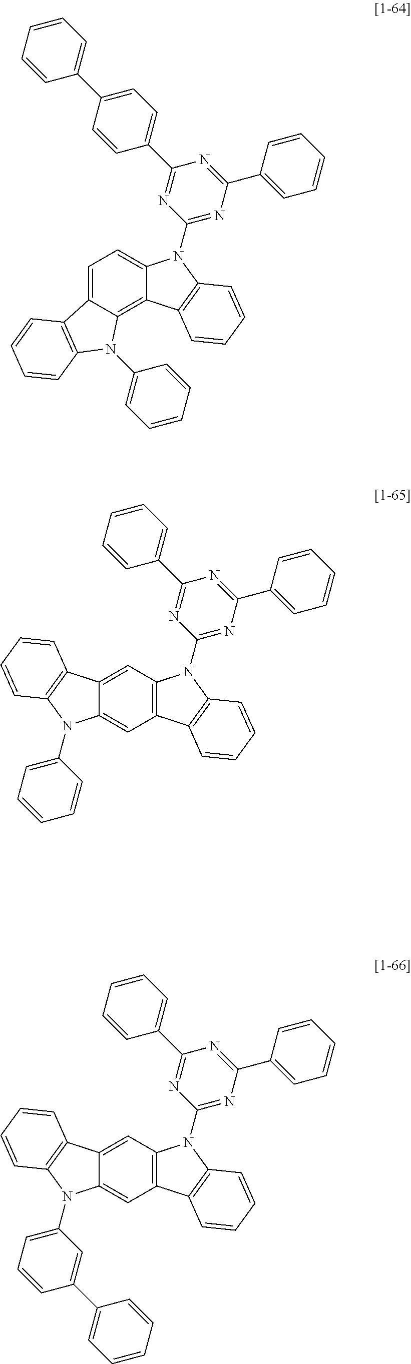 [SMILES: c1ccc(-c2ccc(-c3nc(-c4ccccc4)nc(-n4c5ccccc5c5c4ccc4c6ccccc6n(-c6ccccc6)c45)n3)cc2)cc1 ; c1ccc(-c2nc(-c3ccccc3)nc(-n3c4ccccc4c4cc5c(cc43)c3ccccc3n5-c3ccccc3)n2)cc1 ; c1ccc(-c2cccc(-n3c4ccccc4c4cc5c(cc43)c3ccccc3n5-c3nc(-c4ccccc4)nc(-c4ccccc4)n3)c2)cc1]

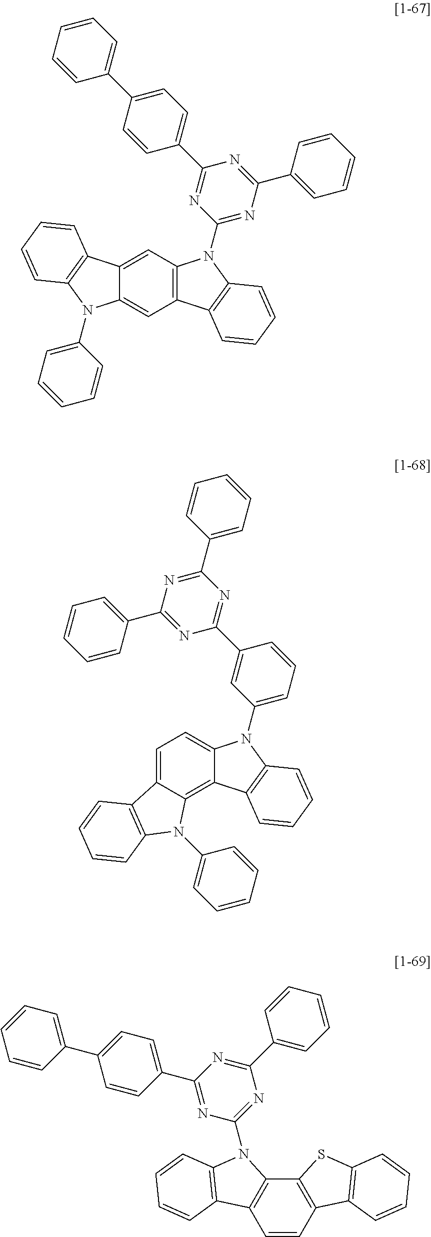 [SMILES: c1ccc(-c2ccc(-c3nc(-c4ccccc4)nc(-n4c5ccccc5c5cc6c(cc54)c4ccccc4n6-c4ccccc4)n3)cc2)cc1 ; c1ccc(-c2nc(-c3ccccc3)nc(-c3cccc(-n4c5ccccc5c5c4ccc4c6ccccc6n(-c6ccccc6)c45)c3)n2)cc1 ; c1ccc(-c2ccc(-c3nc(-c4ccccc4)nc(-n4c5ccccc5c5ccc6c7ccccc7sc6c54)n3)cc2)cc1]

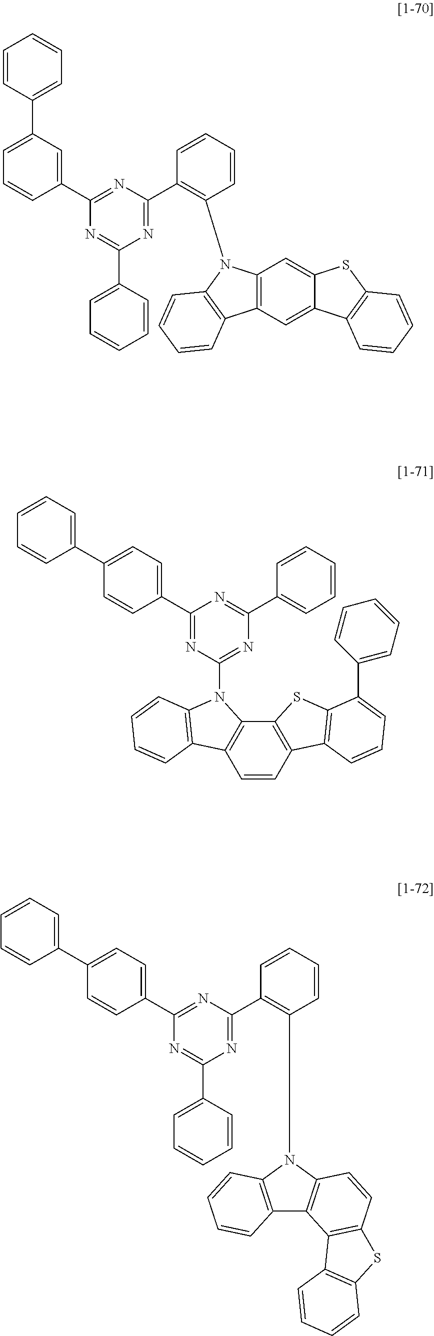 [SMILES: c1ccc(-c2cccc(-c3nc(-c4ccccc4)nc(-c4ccccc4-n4c5ccccc5c5cc6c(cc54)sc4ccccc46)n3)c2)cc1 ; c1ccc(-c2ccc(-c3nc(-c4ccccc4)nc(-n4c5ccccc5c5ccc6c7cccc(-c8ccccc8)c7sc6c54)n3)cc2)cc1 ; c1ccc(-c2ccc(-c3nc(-c4ccccc4)nc(-c4ccccc4-n4c5ccccc5c5c6c(ccc54)sc4ccccc46)n3)cc2)cc1]

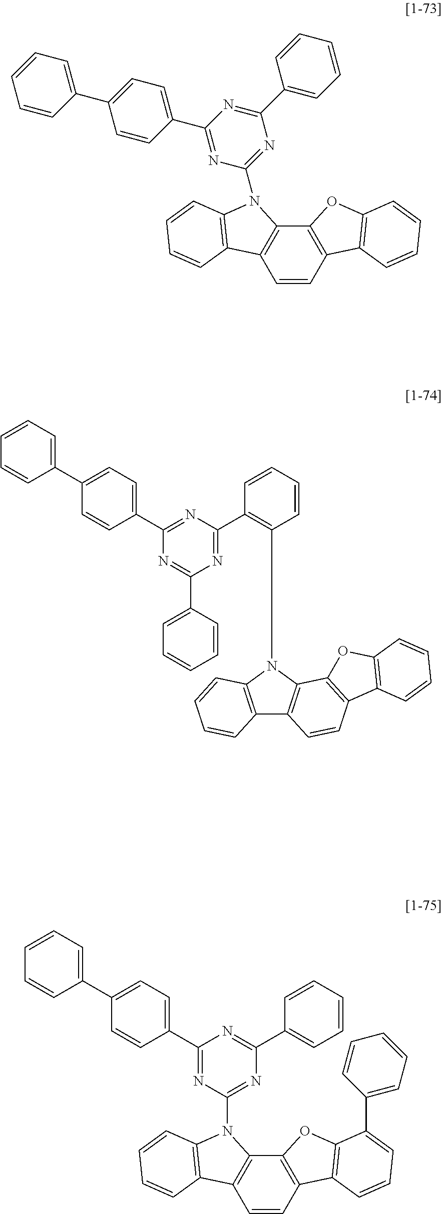 [SMILES: c1ccc(-c2ccc(-c3nc(-c4ccccc4)nc(-n4c5ccccc5c5ccc6c7ccccc7oc6c54)n3)cc2)cc1 ; c1ccc(-c2ccc(-c3nc(-c4ccccc4)nc(-c4ccccc4-n4c5ccccc5c5ccc6c7ccccc7oc6c54)n3)cc2)cc1 ; c1ccc(-c2ccc(-c3nc(-c4ccccc4)nc(-n4c5ccccc5c5ccc6c7cccc(-c8ccccc8)c7oc6c54)n3)cc2)cc1]

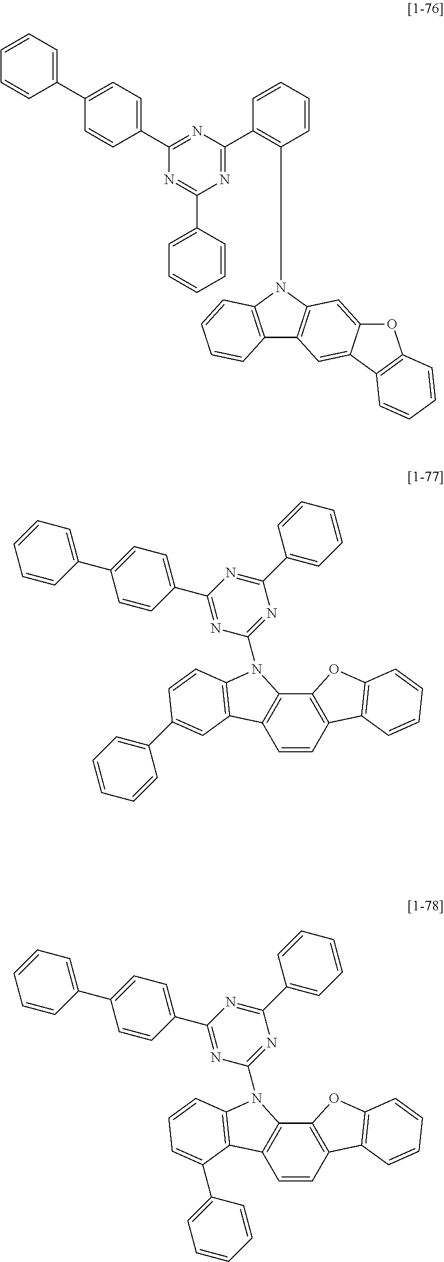 [SMILES: c1ccc(-c2ccc(-c3nc(-c4ccccc4)nc(-c4ccccc4-n4c5ccccc5c5cc6c(cc54)oc4ccccc46)n3)cc2)cc1 ; c1ccc(-c2ccc(-c3nc(-c4ccccc4)nc(-n4c5ccc(-c6ccccc6)cc5c5ccc6c7ccccc7oc6c54)n3)cc2)cc1 ; c1ccc(-c2ccc(-c3nc(-c4ccccc4)nc(-n4c5cccc(-c6ccccc6)c5c5ccc6c7ccccc7oc6c54)n3)cc2)cc1]

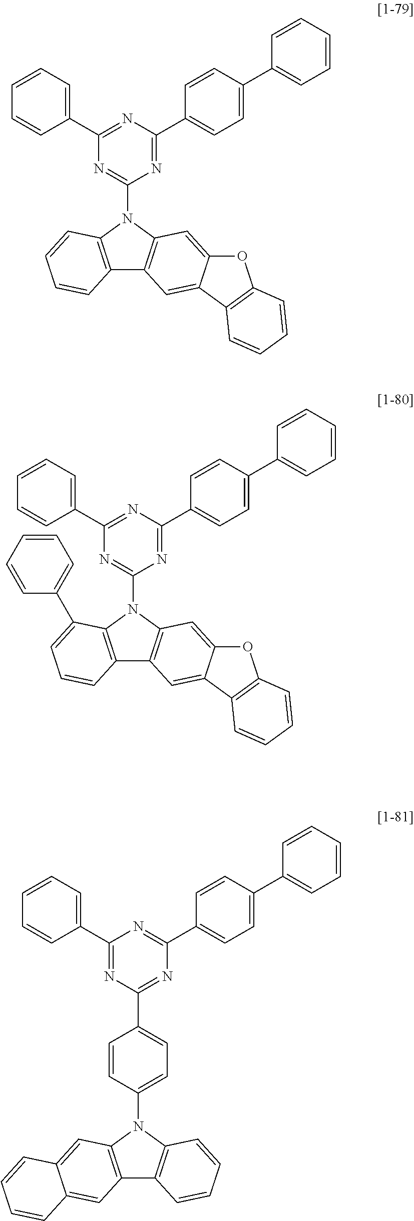 [SMILES: c1ccc(-c2ccc(-c3nc(-c4ccccc4)nc(-n4c5ccccc5c5cc6c(cc54)oc4ccccc46)n3)cc2)cc1 ; c1ccc(-c2ccc(-c3nc(-c4ccccc4)nc(-n4c5cc6oc7ccccc7c6cc5c5cccc(-c6ccccc6)c54)n3)cc2)cc1 ; c1ccc(-c2ccc(-c3nc(-c4ccccc4)nc(-c4ccc(-n5c6ccccc6c6cc7ccccc7cc65)cc4)n3)cc2)cc1]

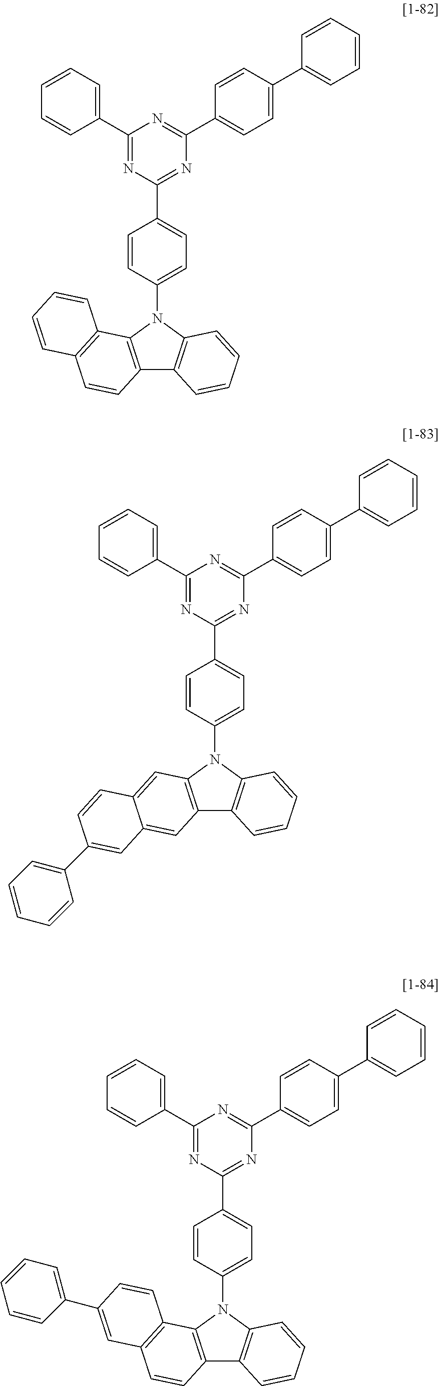 [SMILES: c1ccc(-c2ccc(-c3nc(-c4ccccc4)nc(-c4ccc(-n5c6ccccc6c6ccc7ccccc7c65)cc4)n3)cc2)cc1 ; c1ccc(-c2ccc(-c3nc(-c4ccccc4)nc(-c4ccc(-n5c6ccccc6c6cc7cc(-c8ccccc8)ccc7cc65)cc4)n3)cc2)cc1 ; c1ccc(-c2ccc(-c3nc(-c4ccccc4)nc(-c4ccc(-n5c6ccccc6c6ccc7cc(-c8ccccc8)ccc7c65)cc4)n3)cc2)cc1]

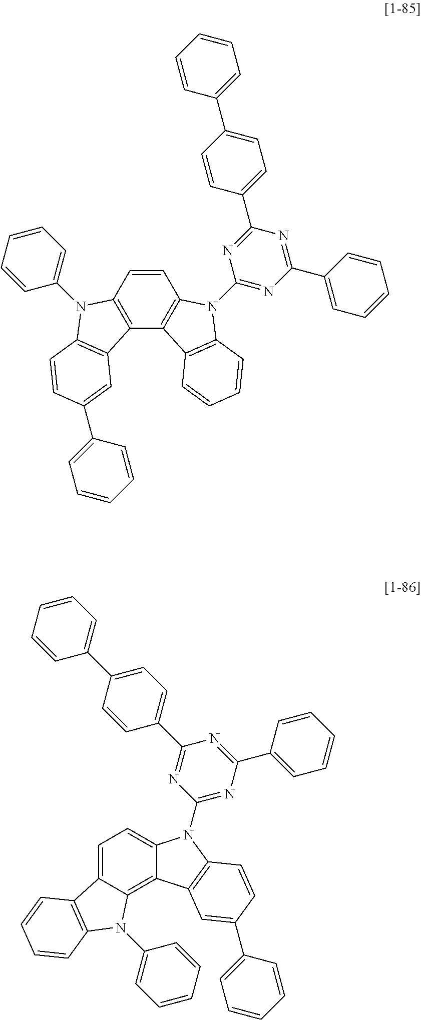 [SMILES: c1ccc(-c2ccc(-c3nc(-c4ccccc4)nc(-n4c5ccccc5c5c6c7cc(-c8ccccc8)ccc7n(-c7ccccc7)c6ccc54)n3)cc2)cc1 ; c1ccc(-c2ccc(-c3nc(-c4ccccc4)nc(-n4c5ccc(-c6ccccc6)cc5c5c4ccc4c6ccccc6n(-c6ccccc6)c45)n3)cc2)cc1]

The second compound may be, for example, one selected from the compounds of Group 2.

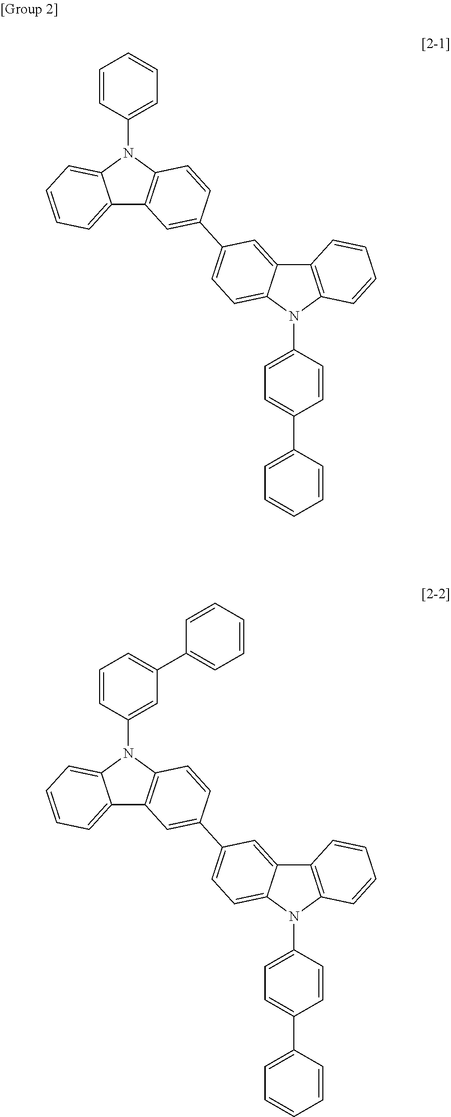 [SMILES: c1ccc(-c2ccc(-n3c4ccccc4c4cc(-c5ccc6c(c5)c5ccccc5n6-c5ccccc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1]

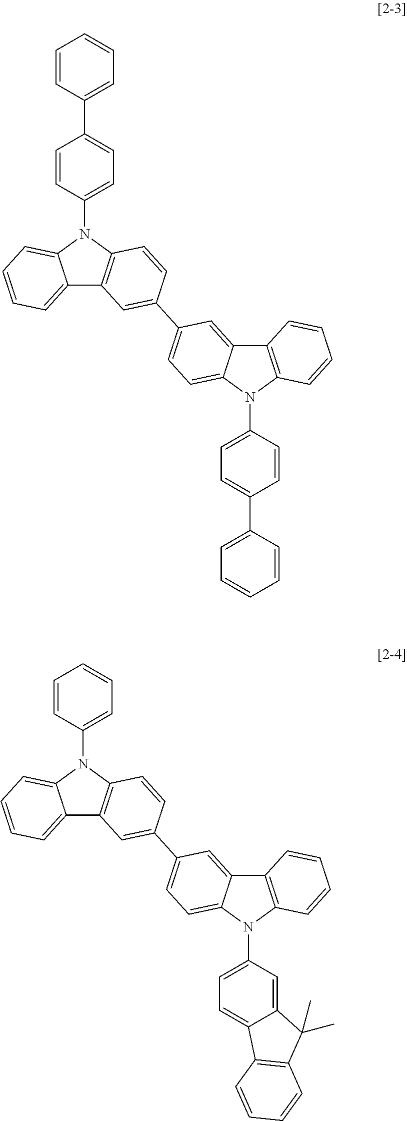 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; CC1(C)c2ccccc2-c2ccc(-n3c4ccccc4c4cc(-c5ccc6c(c5)c5ccccc5n6-c5ccccc5)ccc43)cc21]

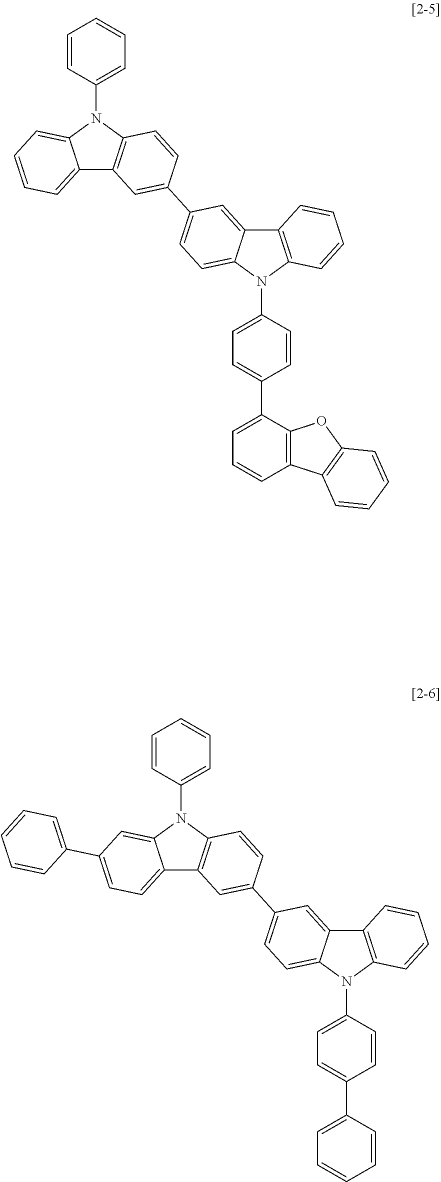 [SMILES: c1ccc(-n2c3ccccc3c3cc(-c4ccc5c(c4)c4ccccc4n5-c4ccc(-c5cccc6c5oc5ccccc56)cc4)ccc32)cc1 ; c1ccc(-c2ccc(-n3c4ccccc4c4cc(-c5ccc6c(c5)c5ccc(-c7ccccc7)cc5n6-c5ccccc5)ccc43)cc2)cc1]

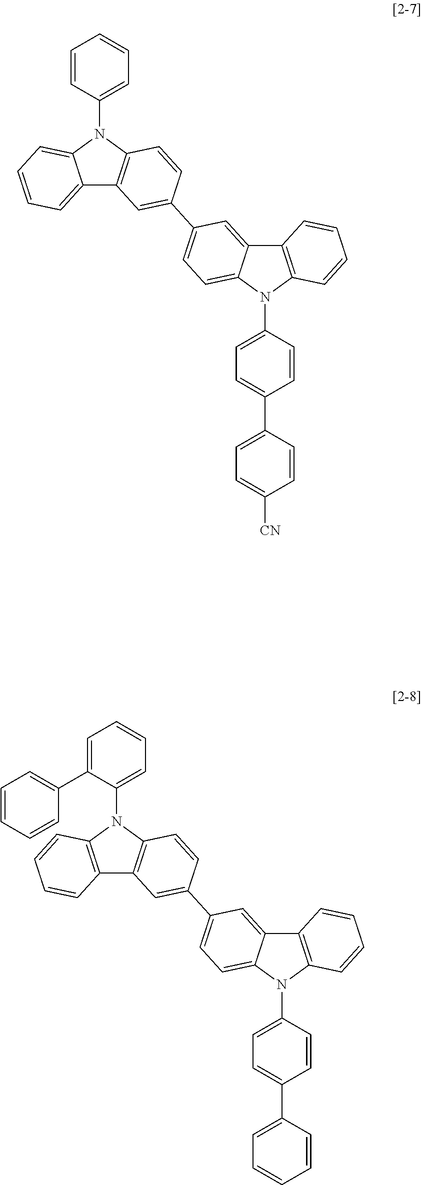 [SMILES: N#Cc1ccc(-c2ccc(-n3c4ccccc4c4cc(-c5ccc6c(c5)c5ccccc5n6-c5ccccc5)ccc43)cc2)cc1 ; c1ccc(-c2ccc(-n3c4ccccc4c4cc(-c5ccc6c(c5)c5ccccc5n6-c5ccccc5-c5ccccc5)ccc43)cc2)cc1]

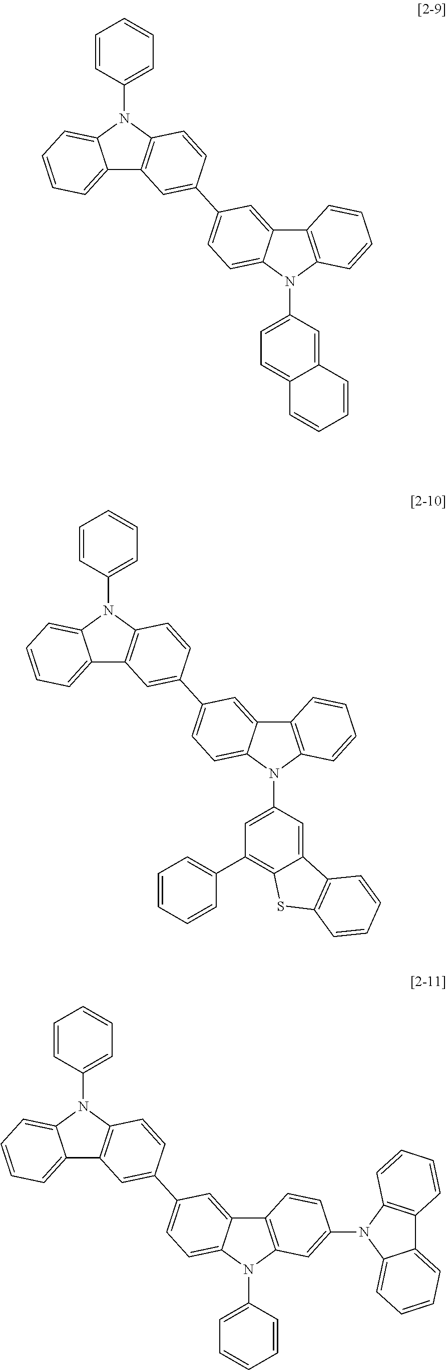 [SMILES: c1ccc(-n2c3ccccc3c3cc(-c4ccc5c(c4)c4ccccc4n5-c4ccc5ccccc5c4)ccc32)cc1 ; c1ccc(-c2cc(-n3c4ccccc4c4cc(-c5ccc6c(c5)c5ccccc5n6-c5ccccc5)ccc43)cc3c2sc2ccccc23)cc1 ; c1ccc(-n2c3ccccc3c3cc(-c4ccc5c(c4)c4ccc(-n6c7ccccc7c7ccccc76)cc4n5-c4ccccc4)ccc32)cc1]

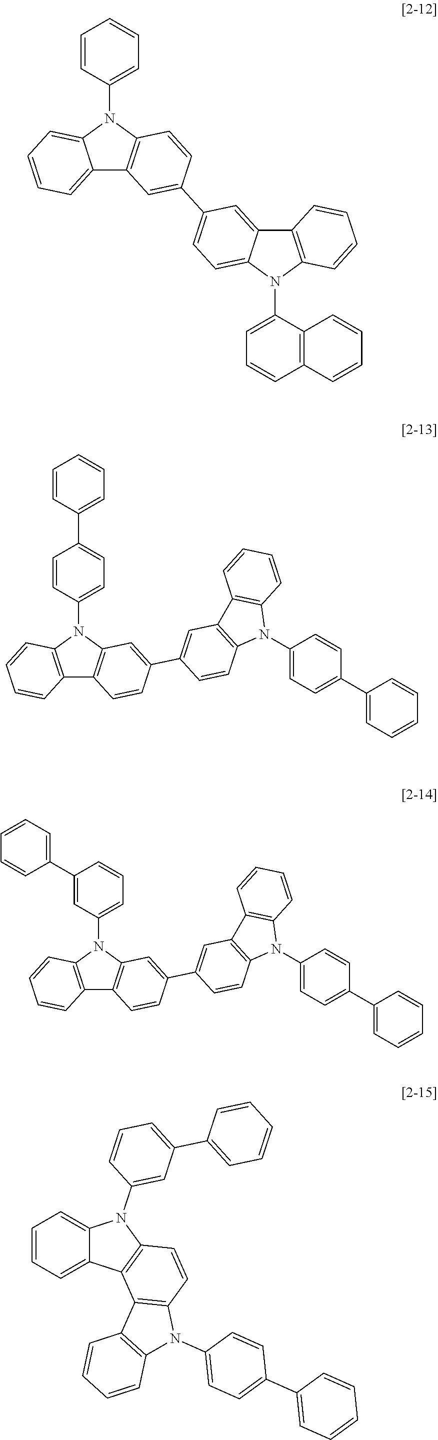 [SMILES: c1ccc(-n2c3ccccc3c3cc(-c4ccc5c(c4)c4ccccc4n5-c4cccc5ccccc45)ccc32)cc1 ; c1ccc(-c2ccc(-n3c4ccccc4c4cc(-c5ccc6c7ccccc7n(-c7ccc(-c8ccccc8)cc7)c6c5)ccc43)cc2)cc1 ; c1ccc(-c2ccc(-n3c4ccccc4c4cc(-c5ccc6c7ccccc7n(-c7cccc(-c8ccccc8)c7)c6c5)ccc43)cc2)cc1 ; c1ccc(-c2ccc(-n3c4ccccc4c4c5c6ccccc6n(-c6cccc(-c7ccccc7)c6)c5ccc43)cc2)cc1]

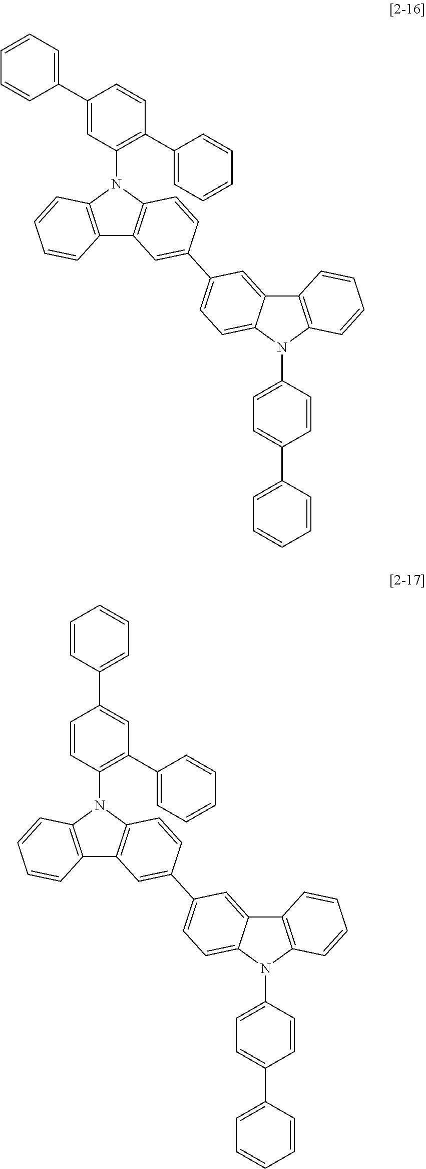 [SMILES: c1ccc(-c2ccc(-n3c4ccccc4c4cc(-c5ccc6c(c5)c5ccccc5n6-c5cc(-c6ccccc6)ccc5-c5ccccc5)ccc43)cc2)cc1 ; c1ccc(-c2ccc(-n3c4ccccc4c4cc(-c5ccc6c(c5)c5ccccc5n6-c5ccc(-c6ccccc6)cc5-c5ccccc5)ccc43)cc2)cc1]

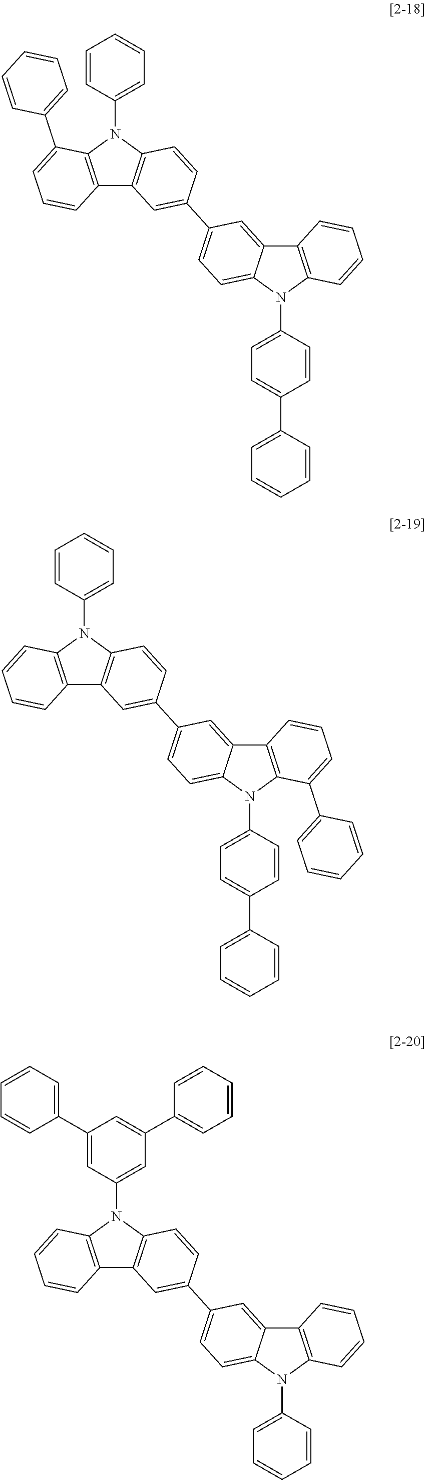 [SMILES: c1ccc(-c2ccc(-n3c4ccccc4c4cc(-c5ccc6c(c5)c5cccc(-c7ccccc7)c5n6-c5ccccc5)ccc43)cc2)cc1 ; c1ccc(-c2ccc(-n3c4ccc(-c5ccc6c(c5)c5ccccc5n6-c5ccccc5)cc4c4cccc(-c5ccccc5)c43)cc2)cc1 ; c1ccc(-c2cc(-c3ccccc3)cc(-n3c4ccccc4c4cc(-c5ccc6c(c5)c5ccccc5n6-c5ccccc5)ccc43)c2)cc1]

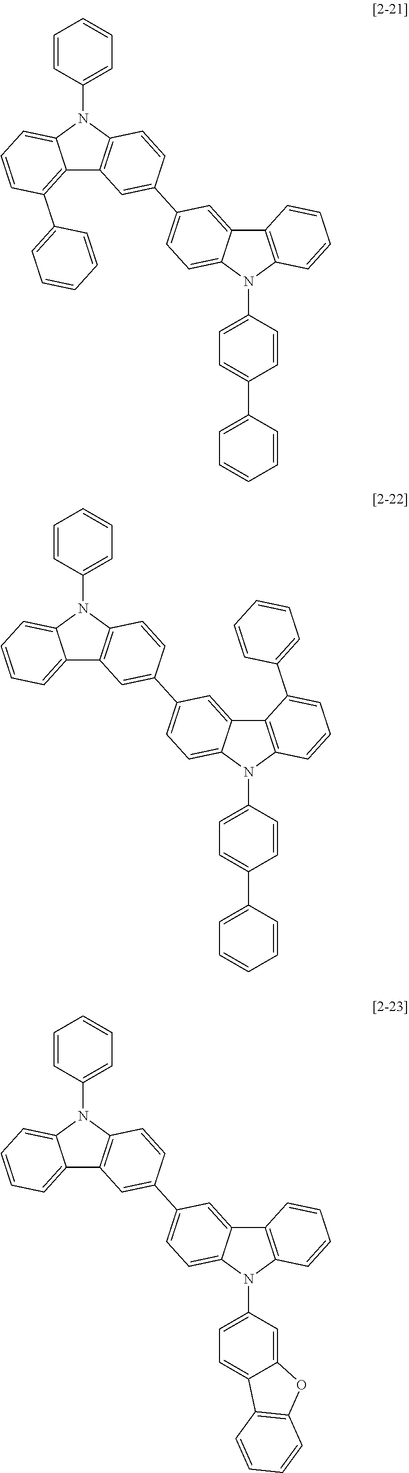 [SMILES: c1ccc(-c2ccc(-n3c4ccccc4c4cc(-c5ccc6c(c5)c5c(-c7ccccc7)cccc5n6-c5ccccc5)ccc43)cc2)cc1 ; c1ccc(-c2ccc(-n3c4ccc(-c5ccc6c(c5)c5ccccc5n6-c5ccccc5)cc4c4c(-c5ccccc5)cccc43)cc2)cc1 ; c1ccc(-n2c3ccccc3c3cc(-c4ccc5c(c4)c4ccccc4n5-c4ccc5c(c4)oc4ccccc45)ccc32)cc1]

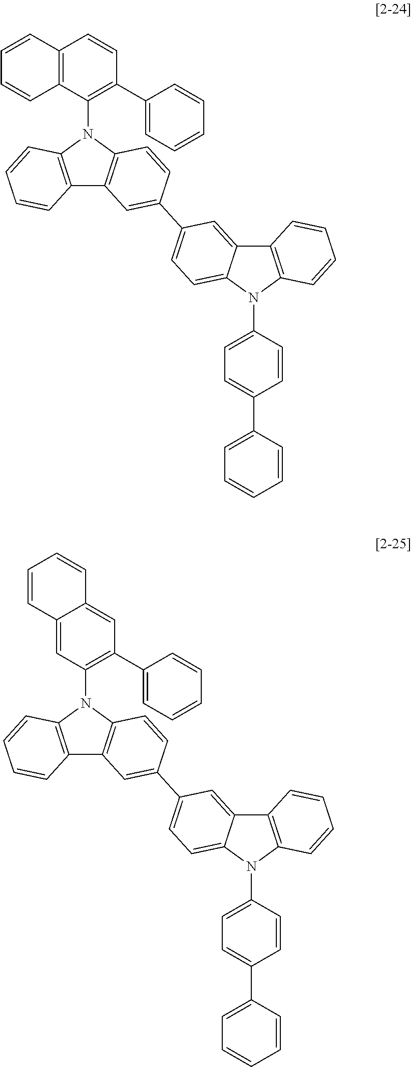 [SMILES: c1ccc(-c2ccc(-n3c4ccccc4c4cc(-c5ccc6c(c5)c5ccccc5n6-c5c(-c6ccccc6)ccc6ccccc56)ccc43)cc2)cc1 ; c1ccc(-c2ccc(-n3c4ccccc4c4cc(-c5ccc6c(c5)c5ccccc5n6-c5cc6ccccc6cc5-c5ccccc5)ccc43)cc2)cc1]

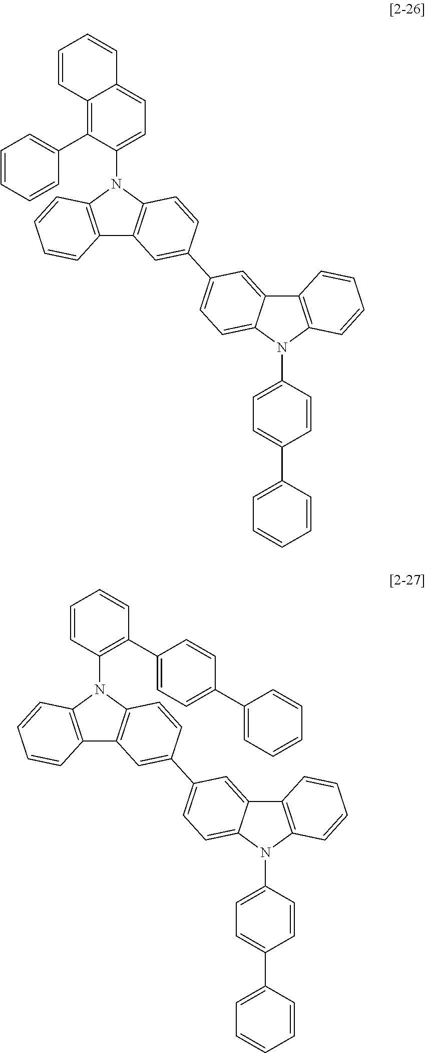 [SMILES: c1ccc(-c2ccc(-n3c4ccccc4c4cc(-c5ccc6c(c5)c5ccccc5n6-c5ccc6ccccc6c5-c5ccccc5)ccc43)cc2)cc1 ; c1ccc(-c2ccc(-c3ccccc3-n3c4ccccc4c4cc(-c5ccc6c(c5)c5ccccc5n6-c5ccc(-c6ccccc6)cc5)ccc43)cc2)cc1]

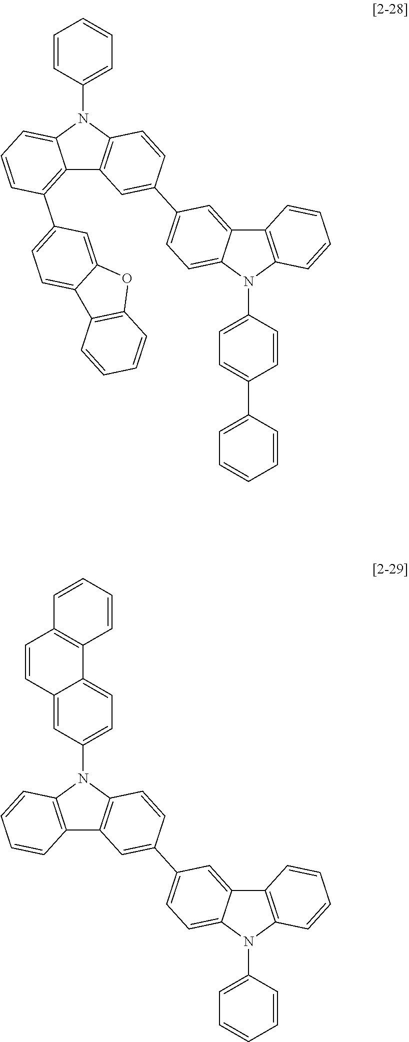 [SMILES: c1ccc(-c2ccc(-n3c4ccccc4c4cc(-c5ccc6c(c5)c5c(-c7ccc8c(c7)oc7ccccc78)cccc5n6-c5ccccc5)ccc43)cc2)cc1 ; c1ccc(-n2c3ccccc3c3cc(-c4ccc5c(c4)c4ccccc4n5-c4ccc5c(ccc6ccccc65)c4)ccc32)cc1]

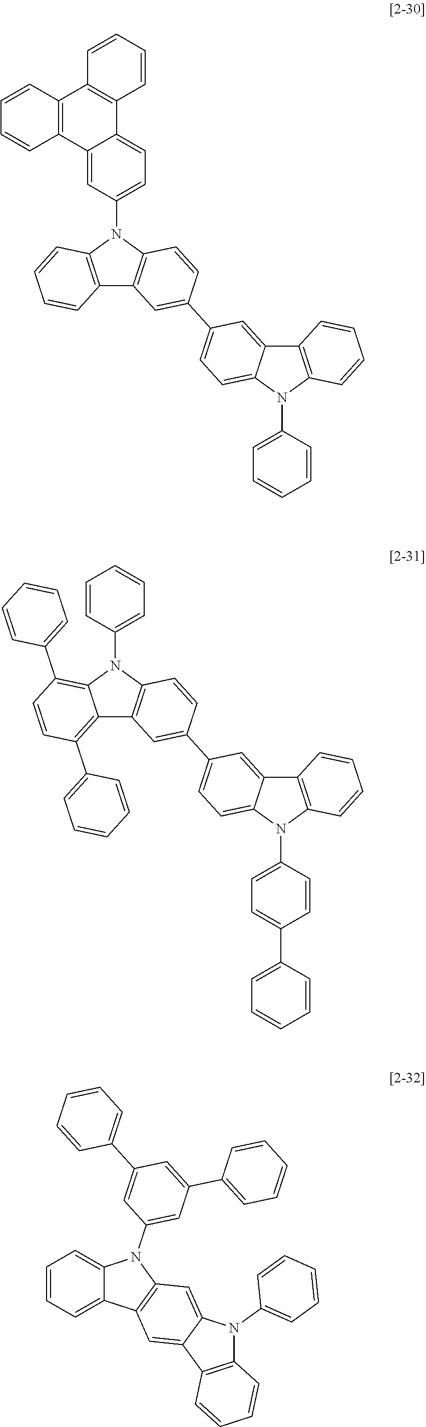 [SMILES: c1ccc(-n2c3ccccc3c3cc(-c4ccc5c(c4)c4ccccc4n5-c4ccc5c6ccccc6c6ccccc6c5c4)ccc32)cc1 ; c1ccc(-c2ccc(-n3c4ccccc4c4cc(-c5ccc6c(c5)c5c(-c7ccccc7)ccc(-c7ccccc7)c5n6-c5ccccc5)ccc43)cc2)cc1 ; c1ccc(-c2cc(-c3ccccc3)cc(-n3c4ccccc4c4cc5c6ccccc6n(-c6ccccc6)c5cc43)c2)cc1]

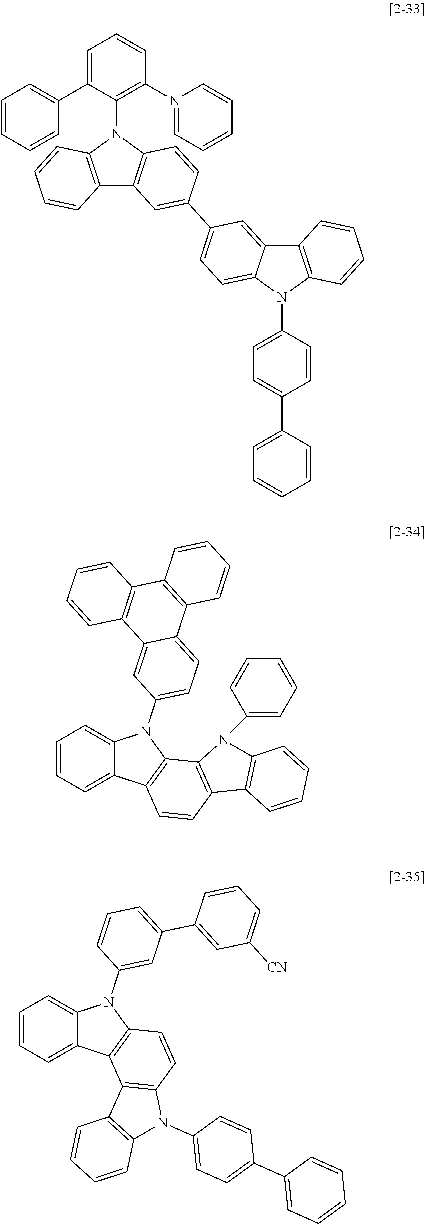

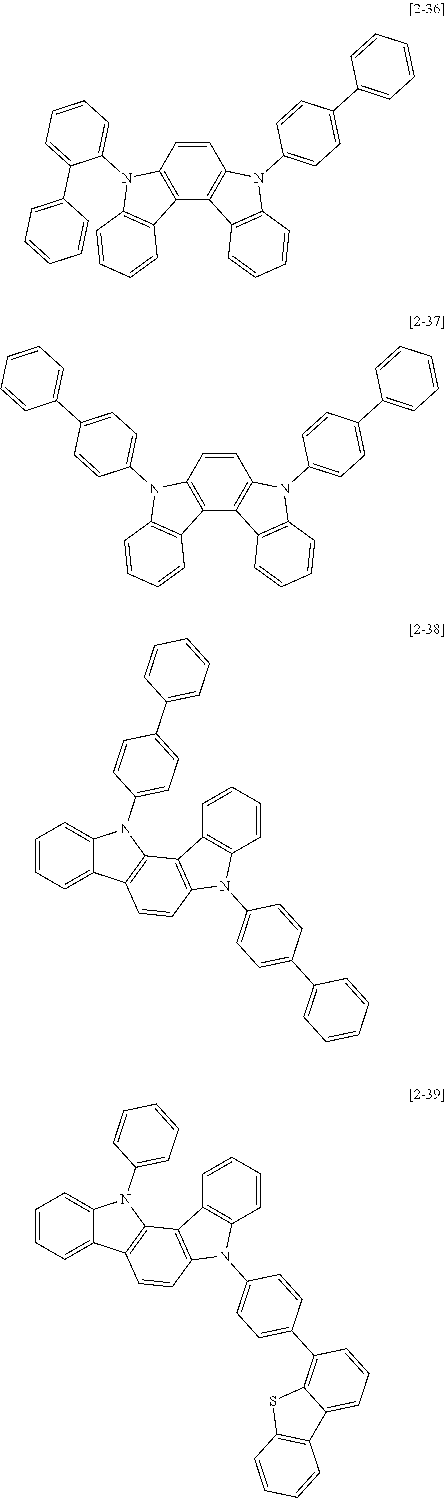 [SMILES: c1ccc(-c2ccc(-n3c4ccccc4c4c5c6ccccc6n(-c6ccccc6-c6ccccc6)c5ccc43)cc2)cc1 ; c1ccc(-c2ccc(-n3c4ccccc4c4c5c6ccccc6n(-c6ccc(-c7ccccc7)cc6)c5ccc43)cc2)cc1 ; c1ccc(-c2ccc(-n3c4ccccc4c4c3ccc3c5ccccc5n(-c5ccc(-c6ccccc6)cc5)c34)cc2)cc1 ; c1ccc(-n2c3ccccc3c3ccc4c(c5ccccc5n4-c4ccc(-c5cccc6c5sc5ccccc56)cc4)c32)cc1]

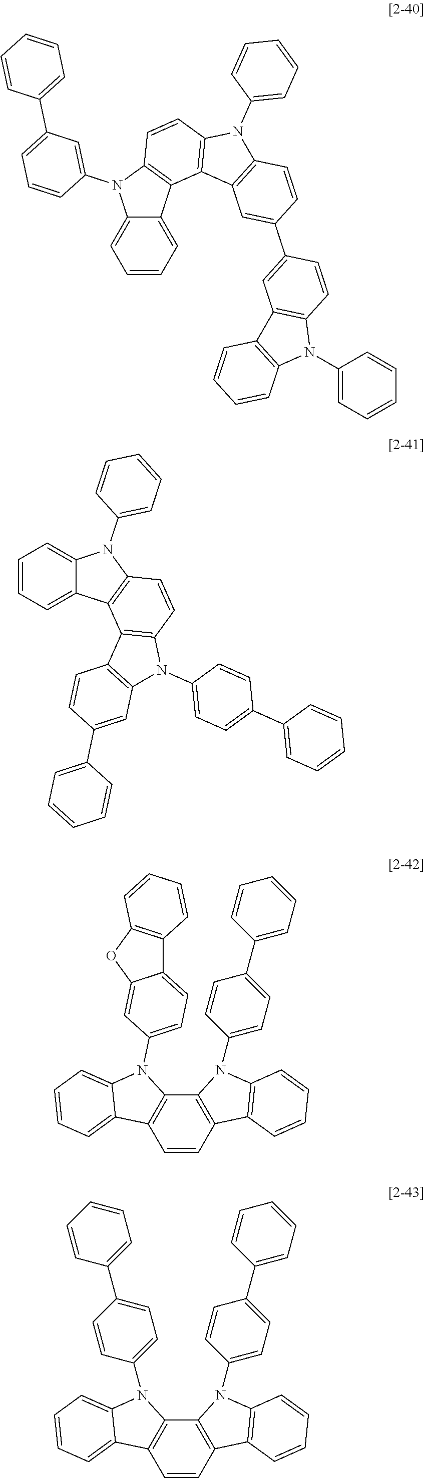 [SMILES: c1ccc(-c2cccc(-n3c4ccccc4c4c5c6cc(-c7ccc8c(c7)c7ccccc7n8-c7ccccc7)ccc6n(-c6ccccc6)c5ccc43)c2)cc1 ; c1ccc(-c2ccc(-n3c4cc(-c5ccccc5)ccc4c4c5c6ccccc6n(-c6ccccc6)c5ccc43)cc2)cc1 ; c1ccc(-c2ccc(-n3c4ccccc4c4ccc5c6ccccc6n(-c6ccc7c(c6)oc6ccccc67)c5c43)cc2)cc1 ; c1ccc(-c2ccc(-n3c4ccccc4c4ccc5c6ccccc6n(-c6ccc(-c7ccccc7)cc6)c5c43)cc2)cc1]

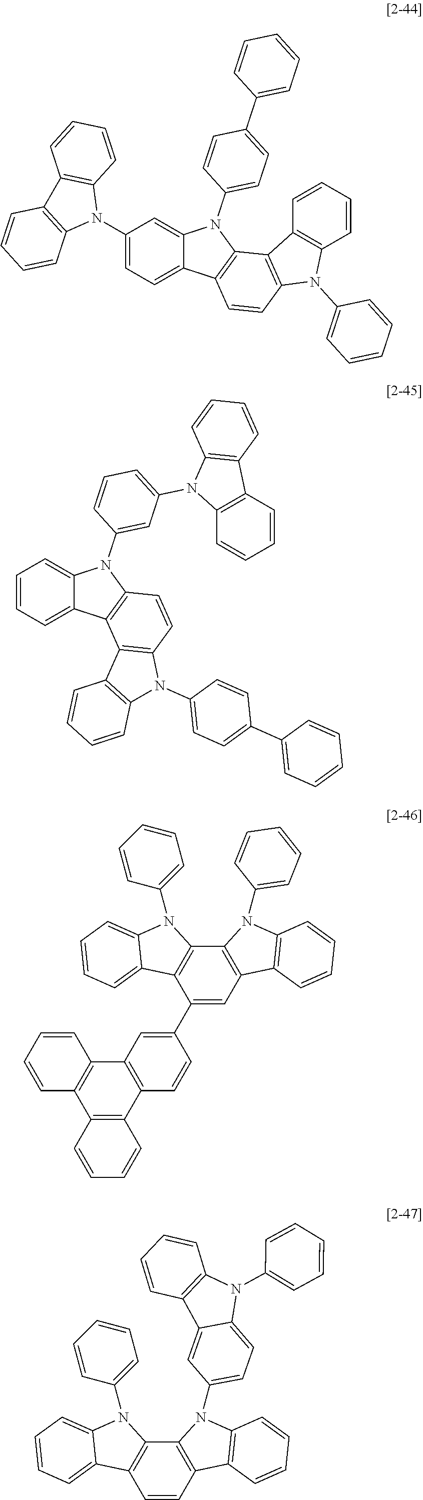 [SMILES: c1ccc(-c2ccc(-n3c4cc(-n5c6ccccc6c6ccccc65)ccc4c4ccc5c(c6ccccc6n5-c5ccccc5)c43)cc2)cc1 ; c1ccc(-c2ccc(-n3c4ccccc4c4c5c6ccccc6n(-c6cccc(-n7c8ccccc8c8ccccc87)c6)c5ccc43)cc2)cc1 ; c1ccc(-n2c3ccccc3c3cc(-c4ccc5c6ccccc6c6ccccc6c5c4)c4c5ccccc5n(-c5ccccc5)c4c32)cc1 ; c1ccc(-n2c3ccccc3c3cc(-n4c5ccccc5c5ccc6c7ccccc7n(-c7ccccc7)c6c54)ccc32)cc1]

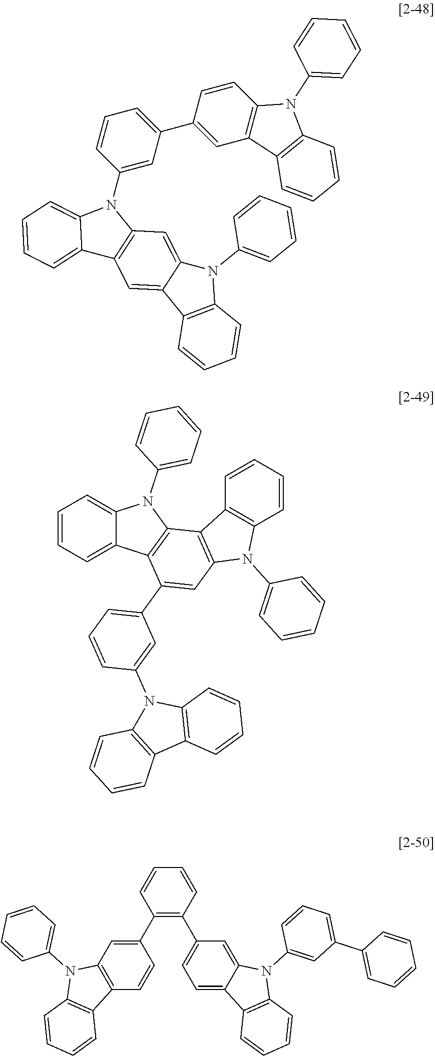

The third compound may be, for example, one selected from compounds of Group 3A and Group 3B.

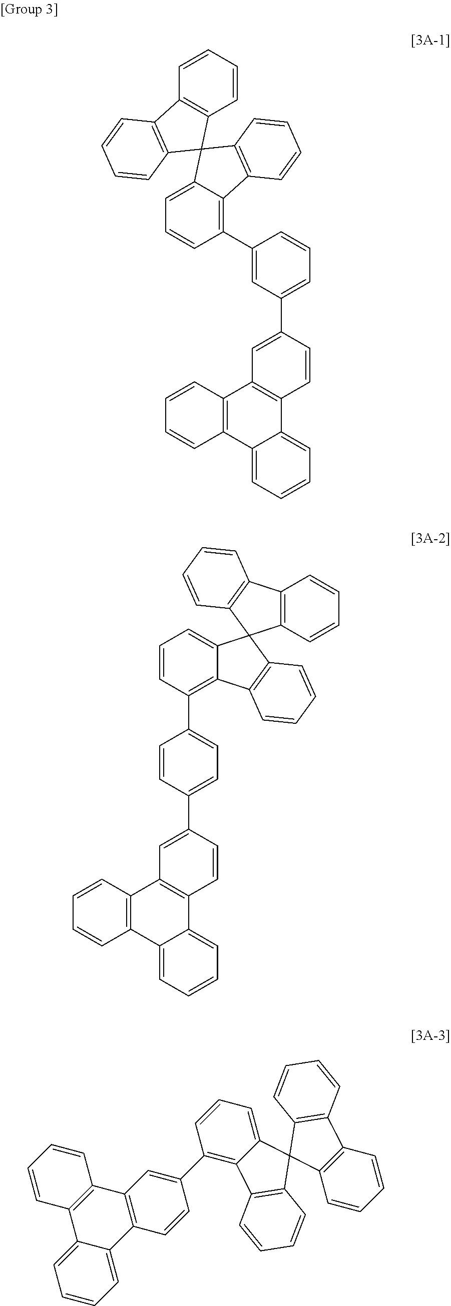

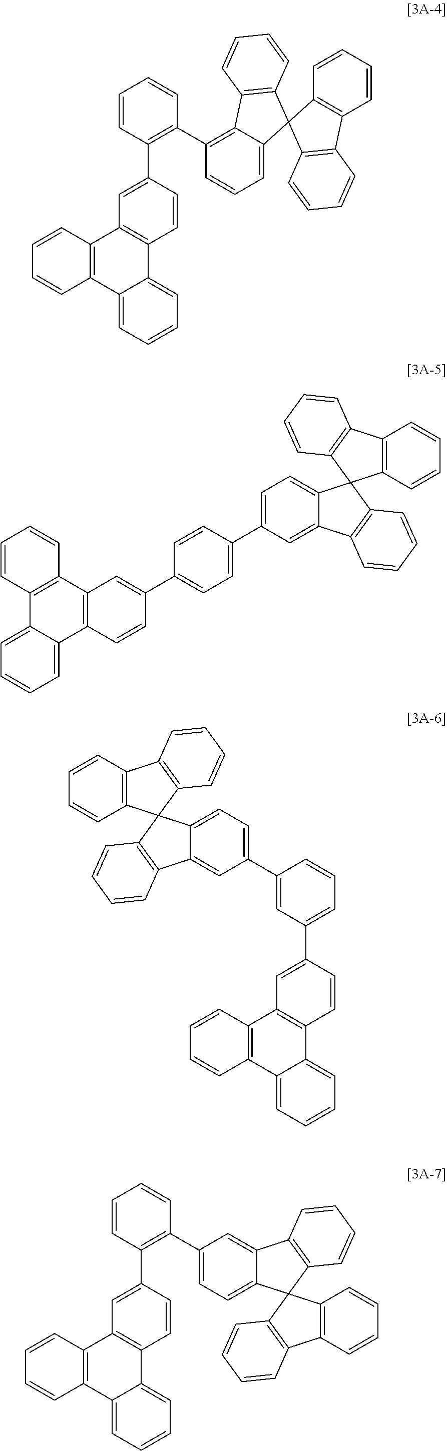

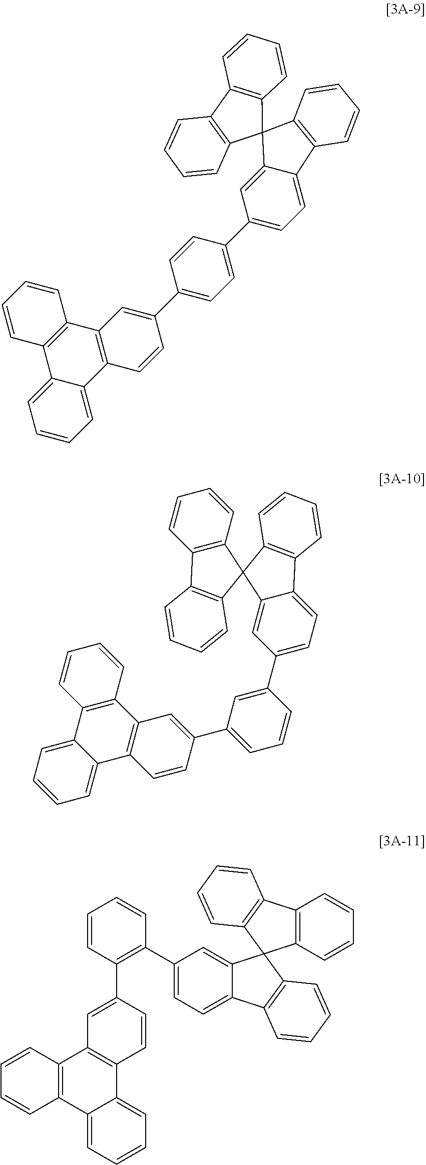

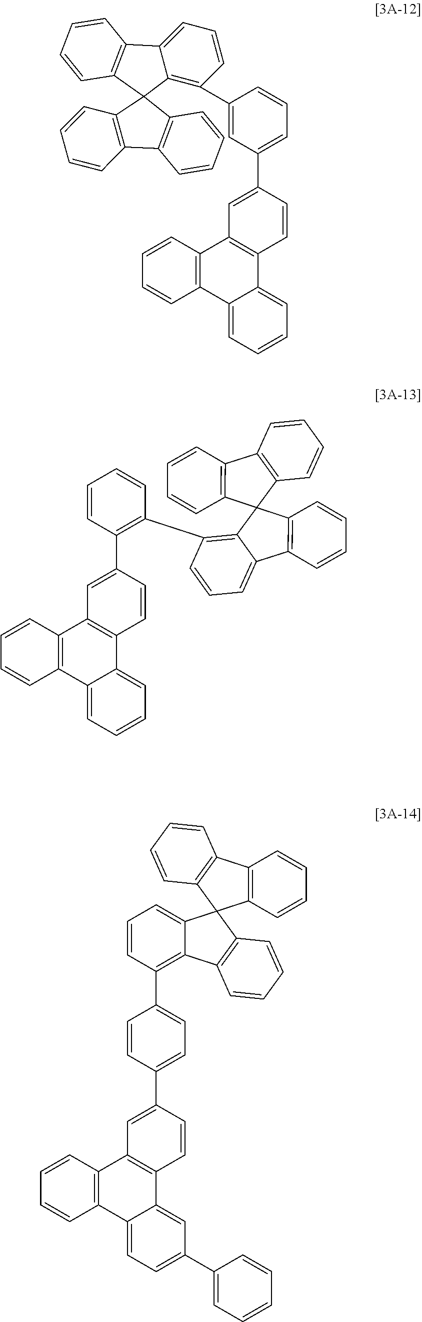

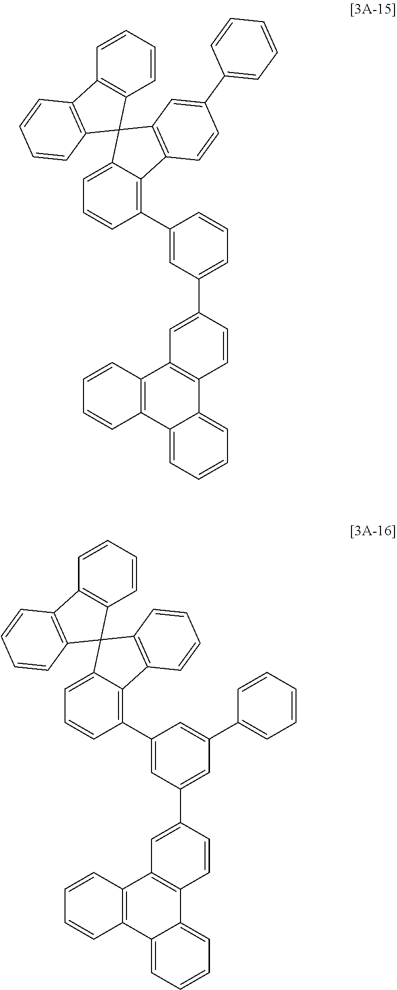

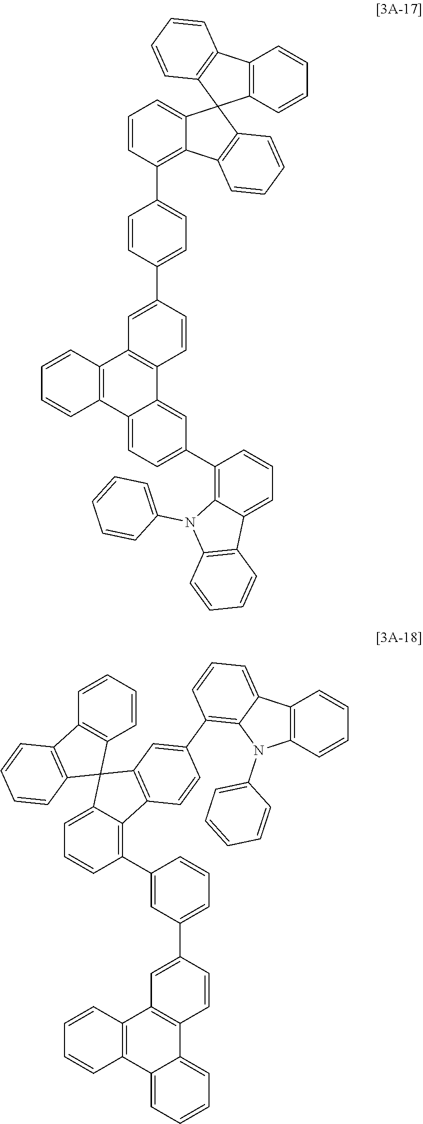 [SMILES: c1ccc(-n2c3ccccc3c3cccc(-c4ccc5c6ccccc6c6cc(-c7ccc(-c8cccc9c8-c8ccccc8C98c9ccccc9-c9ccccc98)cc7)ccc6c5c4)c32)cc1 ; c1ccc(-n2c3ccccc3c3cccc(-c4ccc5c(c4)C4(c6ccccc6-c6ccccc64)c4cccc(-c6cccc(-c7ccc8c9ccccc9c9ccccc9c8c7)c6)c4-5)c32)cc1]

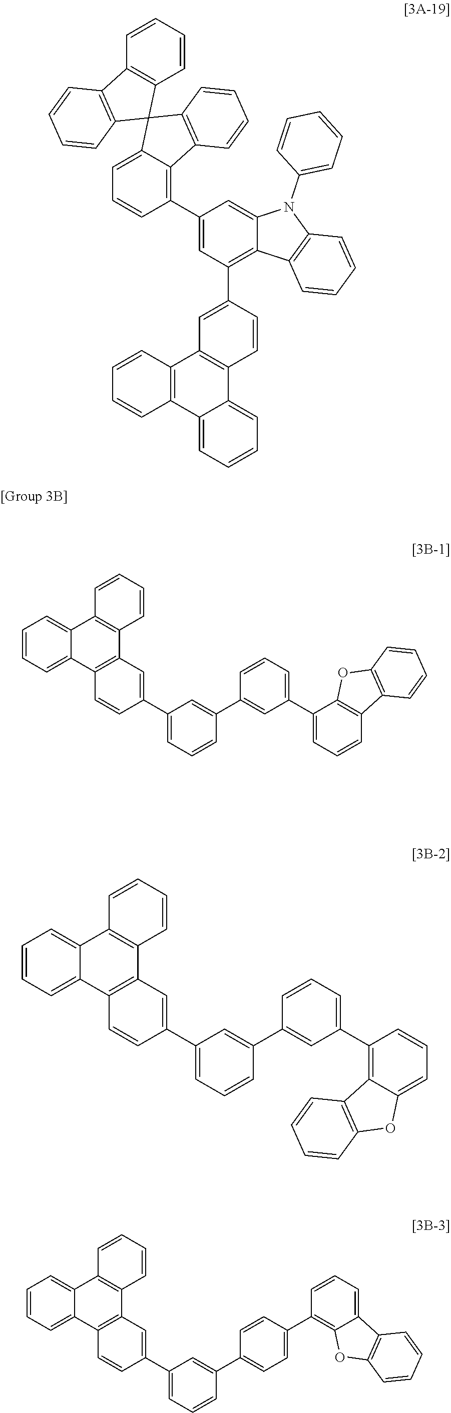 [SMILES: c1ccc(-n2c3ccccc3c3c(-c4ccc5c6ccccc6c6ccccc6c5c4)cc(-c4cccc5c4-c4ccccc4C54c5ccccc5-c5ccccc54)cc32)cc1 ; c1cc(-c2cccc(-c3cccc4c3oc3ccccc34)c2)cc(-c2ccc3c4ccccc4c4ccccc4c3c2)c1 ; c1cc(-c2cccc(-c3cccc4oc5ccccc5c34)c2)cc(-c2ccc3c4ccccc4c4ccccc4c3c2)c1 ; c1cc(-c2ccc(-c3cccc4c3oc3ccccc34)cc2)cc(-c2ccc3c4ccccc4c4ccccc4c3c2)c1]

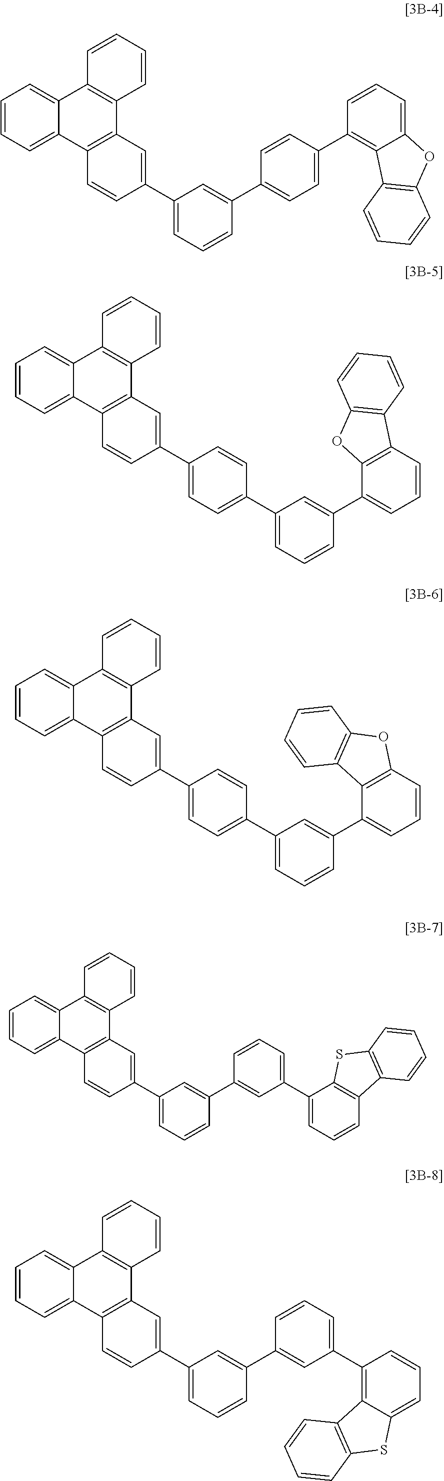 [SMILES: c1cc(-c2ccc(-c3cccc4oc5ccccc5c34)cc2)cc(-c2ccc3c4ccccc4c4ccccc4c3c2)c1 ; c1cc(-c2ccc(-c3ccc4c5ccccc5c5ccccc5c4c3)cc2)cc(-c2cccc3c2oc2ccccc23)c1 ; c1cc(-c2ccc(-c3ccc4c5ccccc5c5ccccc5c4c3)cc2)cc(-c2cccc3oc4ccccc4c23)c1 ; c1cc(-c2cccc(-c3cccc4c3sc3ccccc34)c2)cc(-c2ccc3c4ccccc4c4ccccc4c3c2)c1 ; c1cc(-c2cccc(-c3cccc4sc5ccccc5c34)c2)cc(-c2ccc3c4ccccc4c4ccccc4c3c2)c1]

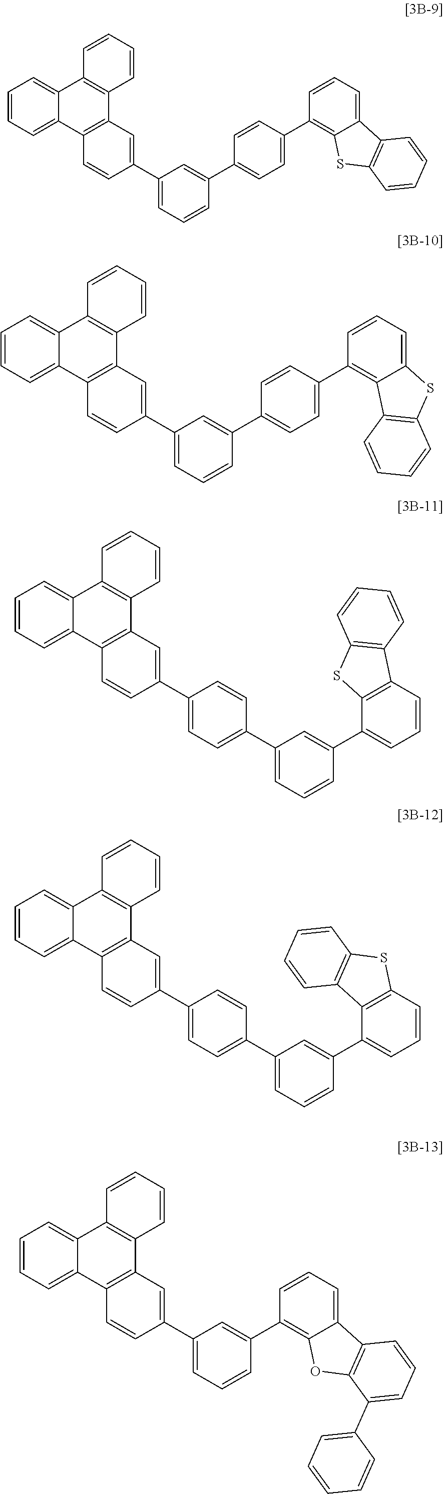 [SMILES: c1cc(-c2ccc(-c3cccc4c3sc3ccccc34)cc2)cc(-c2ccc3c4ccccc4c4ccccc4c3c2)c1 ; c1cc(-c2ccc(-c3cccc4sc5ccccc5c34)cc2)cc(-c2ccc3c4ccccc4c4ccccc4c3c2)c1 ; c1cc(-c2ccc(-c3ccc4c5ccccc5c5ccccc5c4c3)cc2)cc(-c2cccc3c2sc2ccccc23)c1 ; c1cc(-c2ccc(-c3ccc4c5ccccc5c5ccccc5c4c3)cc2)cc(-c2cccc3sc4ccccc4c23)c1 ; c1ccc(-c2cccc3c2oc2c(-c4cccc(-c5ccc6c7ccccc7c7ccccc7c6c5)c4)cccc23)cc1]

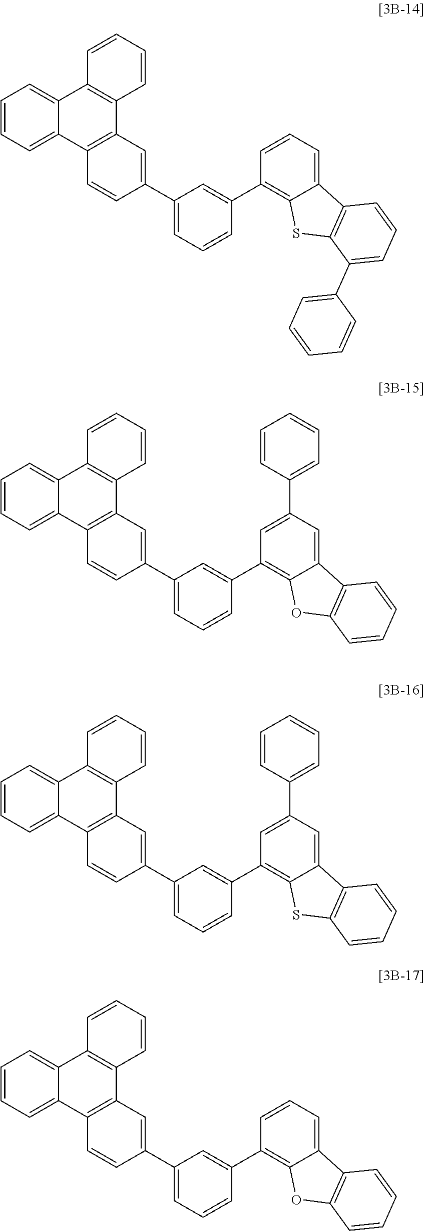 [SMILES: c1ccc(-c2cccc3c2sc2c(-c4cccc(-c5ccc6c7ccccc7c7ccccc7c6c5)c4)cccc23)cc1 ; c1ccc(-c2cc(-c3cccc(-c4ccc5c6ccccc6c6ccccc6c5c4)c3)c3oc4ccccc4c3c2)cc1 ; c1ccc(-c2cc(-c3cccc(-c4ccc5c6ccccc6c6ccccc6c5c4)c3)c3sc4ccccc4c3c2)cc1 ; c1cc(-c2ccc3c4ccccc4c4ccccc4c3c2)cc(-c2cccc3c2oc2ccccc23)c1]

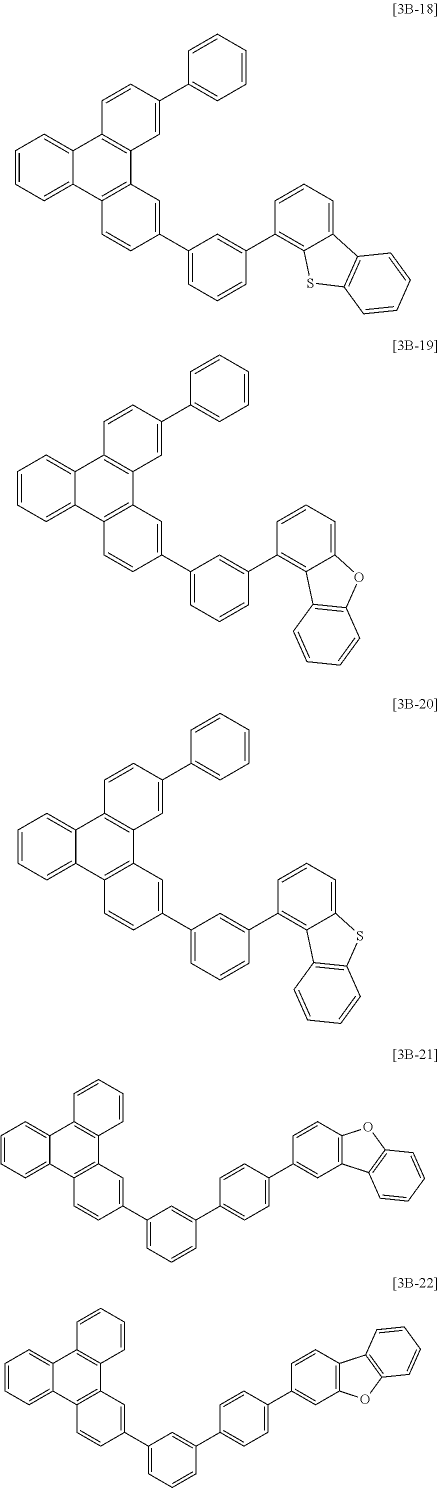 [SMILES: c1ccc(-c2ccc3c4ccccc4c4ccc(-c5cccc(-c6cccc7c6sc6ccccc67)c5)cc4c3c2)cc1 ; c1ccc(-c2ccc3c4ccccc4c4ccc(-c5cccc(-c6cccc7oc8ccccc8c67)c5)cc4c3c2)cc1 ; c1ccc(-c2ccc3c4ccccc4c4ccc(-c5cccc(-c6cccc7sc8ccccc8c67)c5)cc4c3c2)cc1 ; c1cc(-c2ccc(-c3ccc4oc5ccccc5c4c3)cc2)cc(-c2ccc3c4ccccc4c4ccccc4c3c2)c1 ; c1cc(-c2ccc(-c3ccc4c(c3)oc3ccccc34)cc2)cc(-c2ccc3c4ccccc4c4ccccc4c3c2)c1]

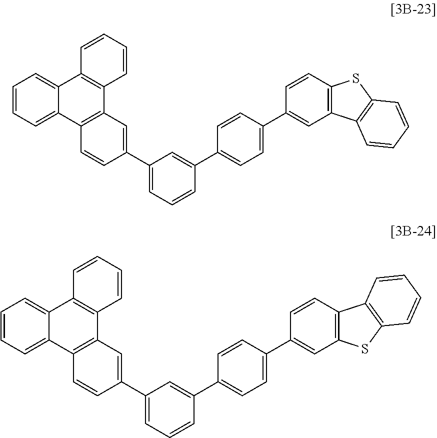 [SMILES: c1cc(-c2ccc(-c3ccc4sc5ccccc5c4c3)cc2)cc(-c2ccc3c4ccccc4c4ccccc4c3c2)c1 ; c1cc(-c2ccc(-c3ccc4c(c3)sc3ccccc34)cc2)cc(-c2ccc3c4ccccc4c4ccccc4c3c2)c1]

The first compound includes a nitrogen-containing 6-membered ring having high electron transport characteristics, and thus electrons may be stably and effectively transported to lower a driving voltage, to increase current efficiency, and to implement long life-span characteristics of a device.

The second compound has a structure including carbazole having high HOMO energy, and thus can effectively inject and transport holes, thereby contributing to improvement of device characteristics.

The third compound has a wide HOMO-LUMO band gap, thereby controlling the movement rate of holes and electrons of the first compound and the second compound, and thus hole trapping and exciton quenching may be prevented through relative movement of the light emitting layer region, which contributes to the improvement of the life-span characteristics of the device.

The three-host composition including the first compound, the second compound, and the third compound may achieve an optimum balance achieved by more finely adjusting electron/hole characteristics in the device stack compared with the composition, and may improve device characteristics greatly due to an appropriate balance of charges, compared with two-host composition such as a composition including the first compound and the second compound or a composition including the first compound and the third compound.

The composition in which the first compound, the second compound, and the third compound are mixed may be included in a light emitting layer of an organic light emitting diode to be described later, for example, as a phosphorescent host.

The composition for an organic optoelectronic element may further include one or more compounds in addition to the first compound, the second compound, and the third compound.

The composition for an organic optoelectronic element may further include a dopant.

The dopant may be, for example, a phosphorescent dopant, such as a red, green, or blue phosphorescent dopant, and may be, for example, a green phosphorescent dopant.

The dopant is a material mixed with the first compound, second compound, and third compound in a trace amount to cause light emission and may be generally a material such as a metal complex that emits light by multiple excitation into a triplet or more. The dopant may be, for example an inorganic, organic, or organic-inorganic compound, and one or more types thereof may be used.

Examples of the dopant may be a phosphorescent dopant and examples of the phosphorescent dopant may be an organic metal compound including Ir, Pt, Os, Ti, Zr, Hf, Eu, Tb, Tm, Fe, Co, Ni, Ru, Rh, Pd, or a combination thereof. The phosphorescent dopant may be for example a compound represented by Chemical Formula Z, but is not limited thereto.

L⁹MX³ [Chemical Formula Z]

In Chemical Formula Z, M is a metal, and L⁹ and X³ are the same or different, and are a ligand to form a complex compound with M.

The M may be for example Ir, Pt, Os, Ti, Zr, Hf, Eu, Tb, Tm, Fe, Co, Ni, Ru, Rh, Pd, or a combination thereof and the L⁹ and X³ may be for example a bidentate ligand.

Examples of the ligands represented by L⁹ and X³ may be selected from the chemical formulas of Group D, but are not limited thereto.

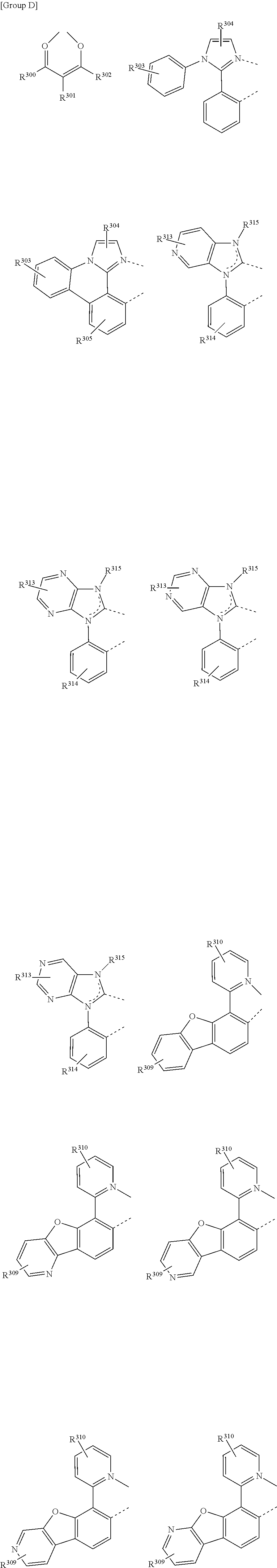

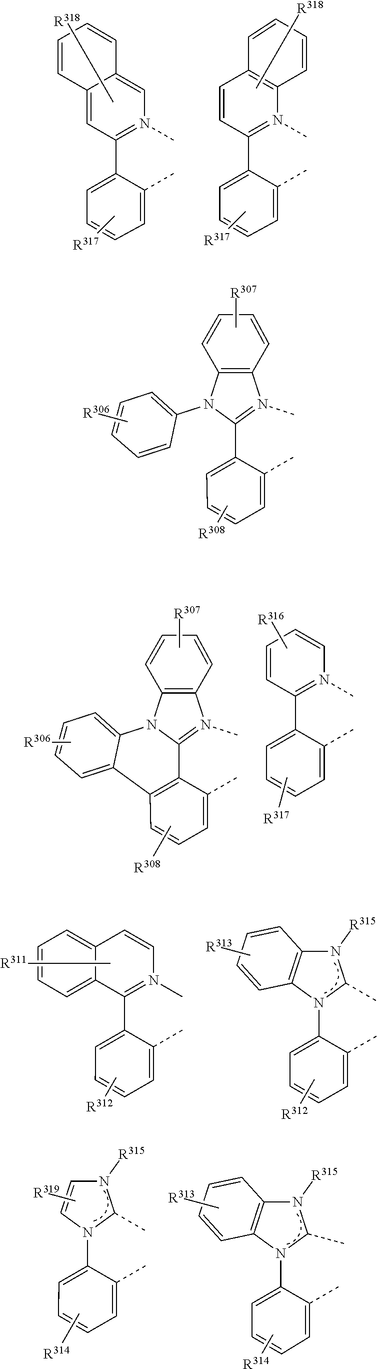

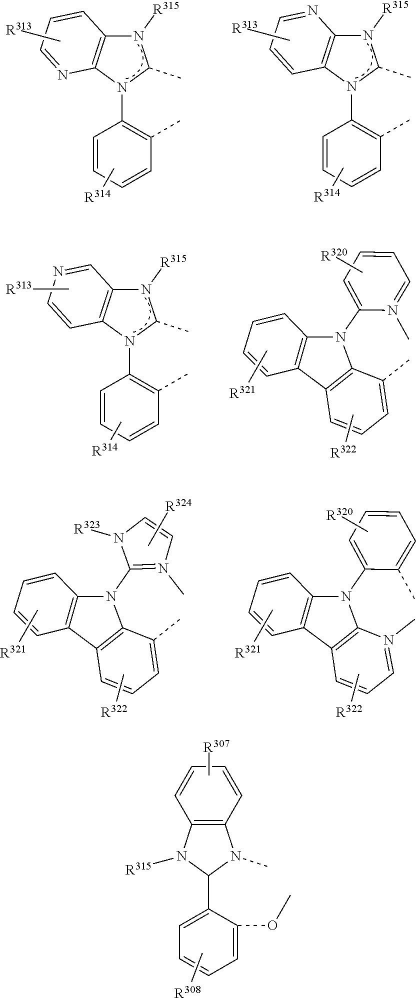

In Group D,

R³⁰⁰ to R³⁰² are each independently hydrogen, deuterium, a C1 to C30 alkyl group that is substituted or unsubstituted with a halogen, a C6 to C30 aryl group that is substituted or unsubstituted with a C1 to C30 alkyl, or a halogen, and

R³⁰³ to R³²⁴ are each independently hydrogen, deuterium, a halogen, a substituted or unsubstituted C1 to C30 alkyl group, a substituted or unsubstituted C1 to C30 alkoxy group, a substituted or unsubstituted C3 to C30 cycloalkyl group, a substituted or unsubstituted C2 to C30 alkenyl group, a substituted or unsubstituted C6 to C30 aryl group, a substituted or unsubstituted C1 to C30 heteroaryl group, a substituted or unsubstituted C1 to C30 amino group, a substituted or unsubstituted C6 to C30 arylamino group, SF₅, a trialkylsilyl group having a substituted or unsubstituted C1 to C30 alkyl group, a dialkylarylsilyl group having a substituted or unsubstituted C1 to C30 alkyl group and C6 to C30 aryl group, or a triarylsilyl group having a substituted or unsubstituted C6 to C30 aryl group.

For example, it may include a dopant represented by Chemical Formula IV.

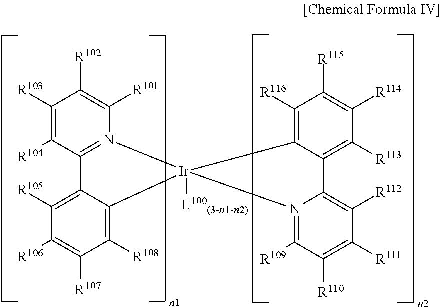

In Chemical Formula IV,

R¹⁰¹ to R¹¹⁶ are each independently hydrogen, deuterium, a substituted or unsubstituted C1 to C10 alkyl group, a substituted or unsubstituted C6 to C20 aryl group, or —SiR¹³²R¹³³R¹³⁴

R¹³² to R¹³⁴ are each independently a C1 to C6 alkyl group,

at least one of R¹⁰¹ to R¹¹⁶ is a functional group represented by Chemical Formula IV-1,

L¹⁰⁰ is a bidentate ligand of a monovalent anion, and is a ligand that coordinates to iridium through a lone pair of carbons or heteroatoms, and

n1 and n2 are each independently any one of integers of 0 to 3, n1+n2 is any one of integers of 1 to 3,

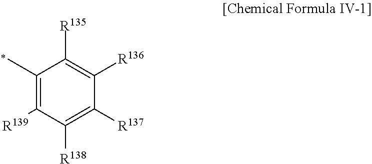

wherein in Chemical Formula IV-1,

R¹³⁵ to R¹³⁹ are each independently hydrogen, deuterium, a substituted or unsubstituted C1 to C10 alkyl group, a substituted or unsubstituted C6 to C20 aryl group, or —SiR¹³²R¹³³R¹³⁴ and

* indicates a portion linked to a carbon atom.

As an example, a dopant represented by Chemical Formula Z-1 may be included.

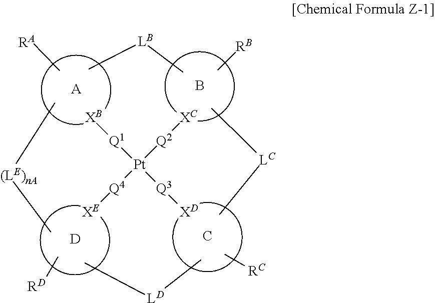

In Chemical Formula Z-1, rings A, B, C, and D are each independently 5- or 6-membered carbocyclic or heterocyclic ring;

R^{A}, R^{B}, R^{C}, and R^{D} each independently represent mono-, di-, tri-, or tetra-substitution, or unsubstitution;

L^{B}, L^{C}, and L^{D} are each independent selected from a direct bond, BR, NR, PR, O, S, Se, C═O, S═O, SO₂, CRR′, SiRR′, GeRR′, and a combination thereof,

when nA is 1, L^{E} is selected from a direct bond, BR, NR, PR, O, S, Se, C═O, S═O, SO₂, CRR′, SiRR′, GeRR′, and a combination thereof, when nA is 0, L^{E} does not exist; and

R^{A}, R^{B}, R^{C}, R^{D}, R, and R′ are each independently selected from hydrogen, deuterium, a halogen, an alkyl group, a cycloalkyl group, a heteroalkyl group, an arylalkyl group, an alkoxy group, an aryloxy group, an amino group, a silyl group, an alkenyl group, a cycloalkenyl group, a heteroalkenyl group, an alkynyl group, an aryl group, a heteroaryl group, an acyl group, a carbonyl group, a carboxylic acid group, an ester group, a nitrile group, an isonitrile group, a sulfanyl group, a sulfinyl group, a sulfonyl group, a phosphino group, and a combination thereof, any adjacent R^{A}, R^{B}, R^{C}, R^{D}, R, and R′ are optionally linked to each other to provide a ring; X^{B}, X^{C}, X^{D}, and X^{E} are each independently selected from carbon and nitrogen; and Q¹, Q², Q³, and Q⁴ each represent oxygen or a direct bond.

The dopant according to an embodiment may be a platinum complex, and may be, for example, represented by Chemical Formula V.

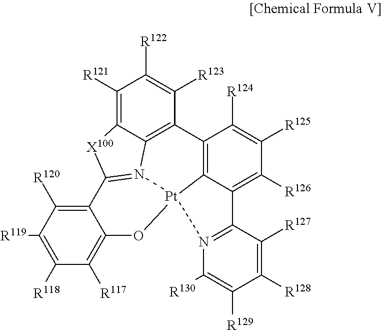

In Chemical Formula V,

X¹⁰⁰ is selected from O, S, and NR¹³¹,

R¹¹⁷ to R¹³¹ are each independently hydrogen, deuterium, a substituted or unsubstituted C1 to C10 alkyl group, a substituted or unsubstituted C6 to C20 aryl group, or —SiR¹³²R¹³³R¹³⁴

R¹³² to R¹³⁴ are each independently a C1 to C6 alkyl group, and at least one of R¹¹⁷ to R¹³¹ is —SiR¹³²R¹³³R¹³⁴ or a tert-butyl group.

The composition for an organic optoelectronic element may be formed by a dry film formation method such as chemical vapor deposition (CVD).

Hereinafter, an organic optoelectronic element including the aforementioned composition for an organic optoelectronic element is described.

The organic optoelectronic element may be any device to convert electrical energy into photoenergy and vice versa without particular limitation, and may be, for example an organic photoelectric device, an organic light emitting diode, an organic solar cell, and an organic photo conductor drum.

Herein, an organic light emitting diode as one example of an organic optoelectronic element is described referring to drawings.

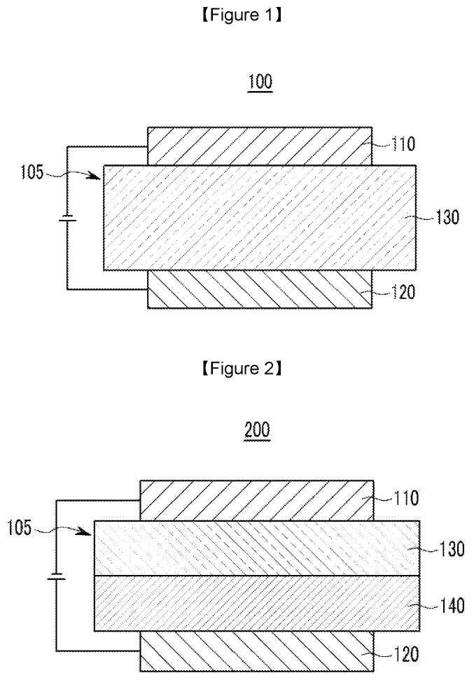

FIGS. 1 and 2 are cross-sectional views showing organic light emitting diodes according to embodiments.

Referring to FIG. 1, an organic light emitting diode 100 according to an embodiment includes an anode 120 and a cathode 110 facing each other and an organic layer 105 disposed between the anode 120 and cathode 110.

The anode 120 may be made of a conductor having a large work function to help hole injection, and may be for example a metal, a metal oxide and/or a conductive polymer. The anode 120 may be, for example a metal such as nickel, platinum, vanadium, chromium, copper, zinc, gold, and the like or an alloy thereof; a metal oxide such as zinc oxide, indium oxide, indium tin oxide (ITO), indium zinc oxide (IZO), and the like; a combination of a metal and an oxide such as ZnO and Al or SnO₂ and Sb; a conductive polymer such as poly(3-methylthiophene), poly(3,4-(ethylene-1,2-dioxy)thiophene) (PEDT), polypyrrole, and polyaniline, but is not limited thereto.

The cathode 110 may be made of a conductor having a small work function to help electron injection, and may be for example a metal, a metal oxide and/or a conductive polymer.

The cathode 110 may be for example a metal such as magnesium, calcium, sodium, potassium, titanium, indium, yttrium, lithium, gadolinium, aluminum silver, tin, lead, cesium, barium, and the like, or an alloy thereof; a multi-layer structure material such as LiF/Al, LiO₂/Al, LiF/Ca, LiF/Al, and BaF₂/Ca, but is not limited thereto.

The organic layer 105 may include the aforementioned composition for an organic optoelectronic element.

The organic layer 105 may include, for example, the light emitting layer 130, and the light emitting layer 130 may include, for example, the aforementioned composition for an organic optoelectronic element.

The aforementioned composition for an organic optoelectronic element may be, for example, a green light-emitting composition.

The light emitting layer 130 may include, for example, the aforementioned first compound, second compound, and third compound as a phosphorescent host.

Referring to FIG. 2, an organic light emitting diode 200 further includes a hole auxiliary layer 140 in addition to the light emitting layer 130. The hole auxiliary layer 140 further increases hole injection and/or hole mobility and blocks electrons between the anode 120 and the light emitting layer 130. The hole auxiliary layer 140 may be, for example, a hole transport layer, a hole injection layer, and/or an electron blocking layer and may include at least one layer.

The hole auxiliary layer 140 may include for example at least one of compounds of Group E.

Specifically, the hole auxiliary layer 140 may include a hole transport layer between the anode 120 and the light emitting layer 130 and a hole transport auxiliary layer between the light emitting layer 130 and the hole transport layer, and at least one of compounds of Group E may be included in the hole transport auxiliary layer.

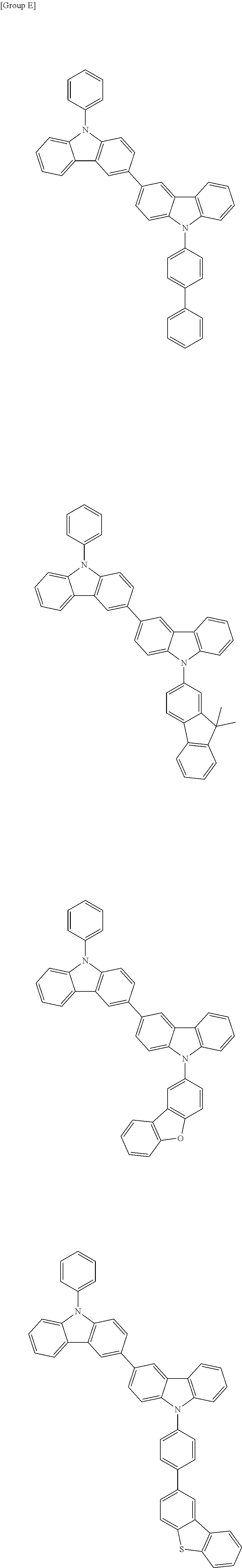 [SMILES: c1ccc(-c2ccc(-n3c4ccccc4c4cc(-c5ccc6c(c5)c5ccccc5n6-c5ccccc5)ccc43)cc2)cc1 ; CC1(C)c2ccccc2-c2ccc(-n3c4ccccc4c4cc(-c5ccc6c(c5)c5ccccc5n6-c5ccccc5)ccc43)cc21 ; c1ccc(-n2c3ccccc3c3cc(-c4ccc5c(c4)c4ccccc4n5-c4ccc5oc6ccccc6c5c4)ccc32)cc1 ; c1ccc(-n2c3ccccc3c3cc(-c4ccc5c(c4)c4ccccc4n5-c4ccc(-c5ccc6sc7ccccc7c6c5)cc4)ccc32)cc1]

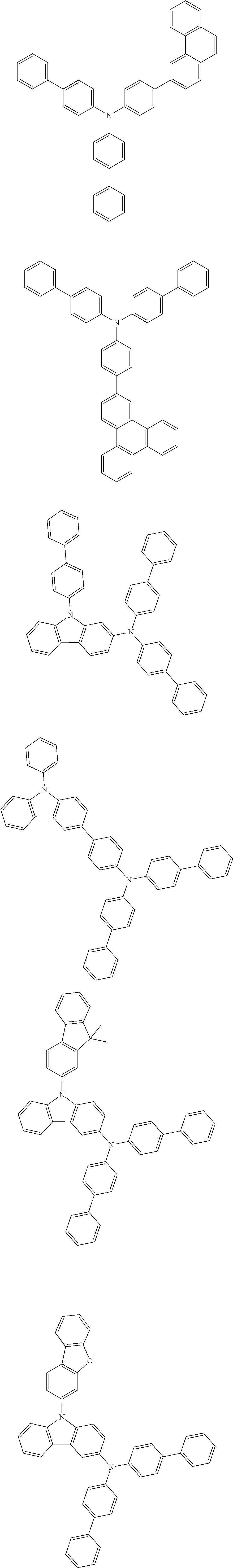

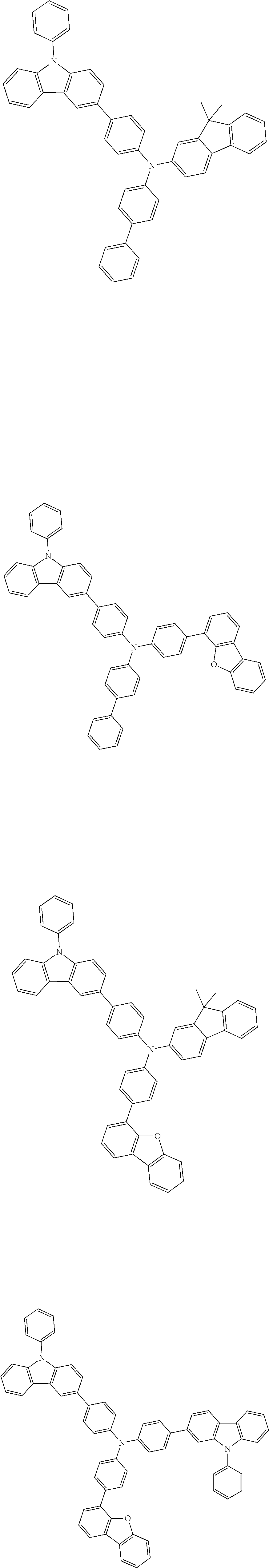 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccc(-c4ccc5c(c4)c4ccccc4n5-c4ccccc4)cc3)c3ccc(-c4cccc5c4oc4ccccc45)cc3)cc2)cc1 ; CC1(C)c2ccccc2-c2ccc(N(c3ccc(-c4ccc5c(c4)c4ccccc4n5-c4ccccc4)cc3)c3ccc(-c4cccc5c4oc4ccccc45)cc3)cc21 ; c1ccc(-n2c3ccccc3c3cc(-c4ccc(N(c5ccc(-c6ccc7c8ccccc8n(-c8ccccc8)c7c6)cc5)c5ccc(-c6cccc7c6oc6ccccc67)cc5)cc4)ccc32)cc1]

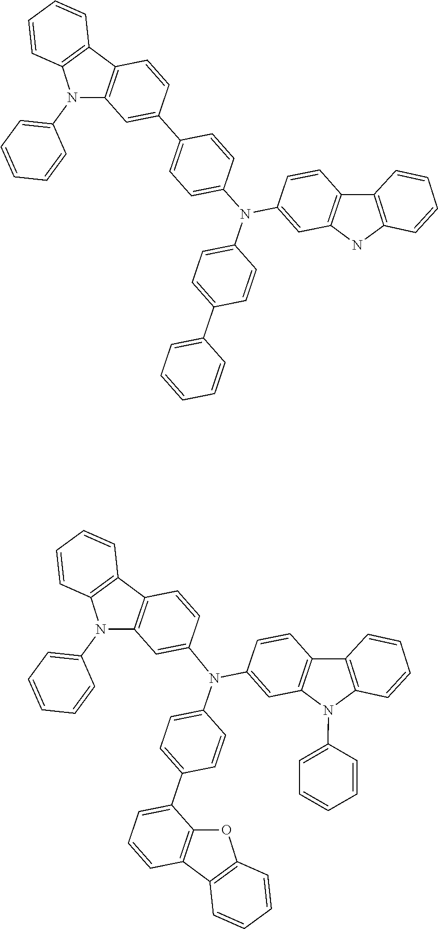 [SMILES: c1ccc(-c2ccc(N(c3ccc(-c4ccc5c6ccccc6n(-c6ccccc6)c5c4)cc3)c3ccc4c(c3)[nH]c3ccccc34)cc2)cc1 ; c1ccc(-n2c3ccccc3c3ccc(N(c4ccc(-c5cccc6c5oc5ccccc56)cc4)c4ccc5c6ccccc6n(-c6ccccc6)c5c4)cc32)cc1]

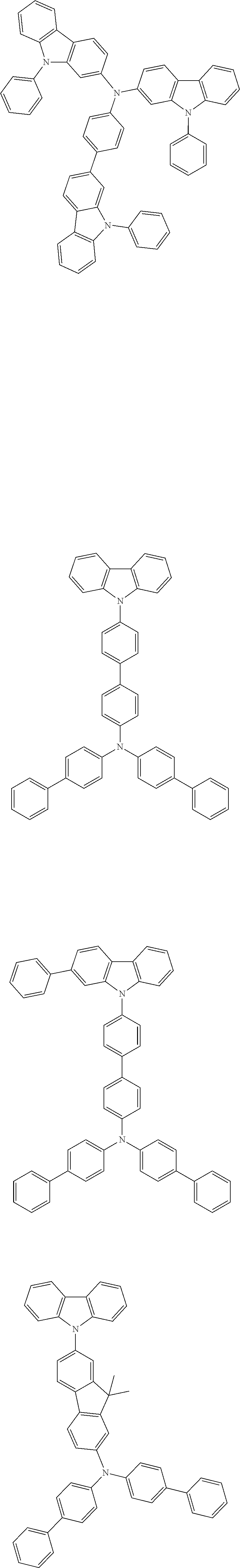 [SMILES: c1ccc(-n2c3ccccc3c3ccc(-c4ccc(N(c5ccc6c7ccccc7n(-c7ccccc7)c6c5)c5ccc6c7ccccc7n(-c7ccccc7)c6c5)cc4)cc32)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccc(-c7ccccc7)cc65)cc4)cc3)cc2)cc1 ; CC1(C)c2cc(N(c3ccc(-c4ccccc4)cc3)c3ccc(-c4ccccc4)cc3)ccc2-c2ccc(-n3c4ccccc4c4ccccc43)cc21]

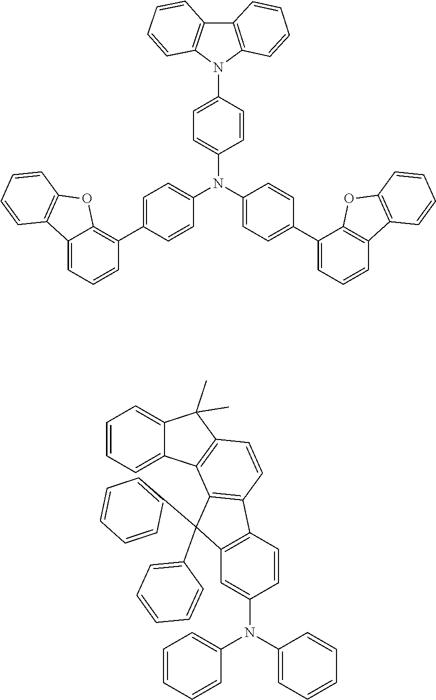 [SMILES: c1ccc2c(c1)oc1c(-c3ccc(N(c4ccc(-c5cccc6c5oc5ccccc56)cc4)c4ccc(-n5c6ccccc6c6ccccc65)cc4)cc3)cccc12 ; CC1(C)c2ccccc2-c2c1ccc1c2C(c2ccccc2)(c2ccccc2)c2cc(N(c3ccccc3)c3ccccc3)ccc2-1]

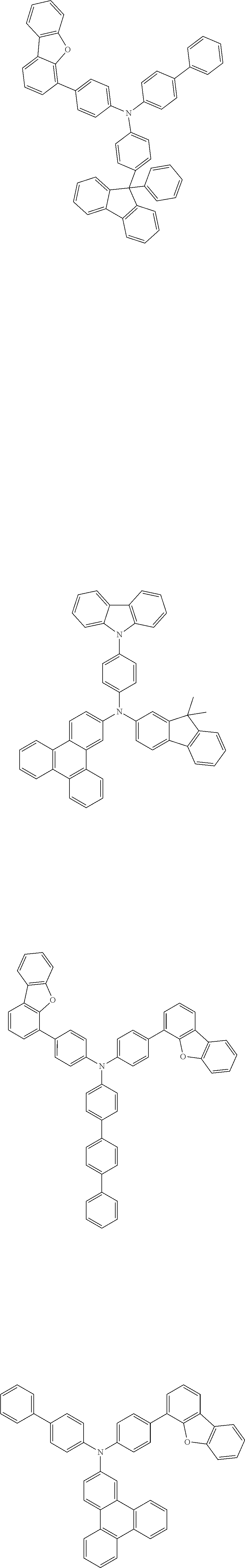 [SMILES: c1ccc(-c2ccc(N(c3ccc(-c4cccc5c4oc4ccccc45)cc3)c3ccc(C4(c5ccccc5)c5ccccc5-c5ccccc54)cc3)cc2)cc1 ; CC1(C)c2ccccc2-c2ccc(N(c3ccc(-n4c5ccccc5c5ccccc54)cc3)c3ccc4c5ccccc5c5ccccc5c4c3)cc21 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2ccc(N(c3ccc(-c4cccc5c4oc4ccccc45)cc3)c3ccc4c5ccccc5c5ccccc5c4c3)cc2)cc1]

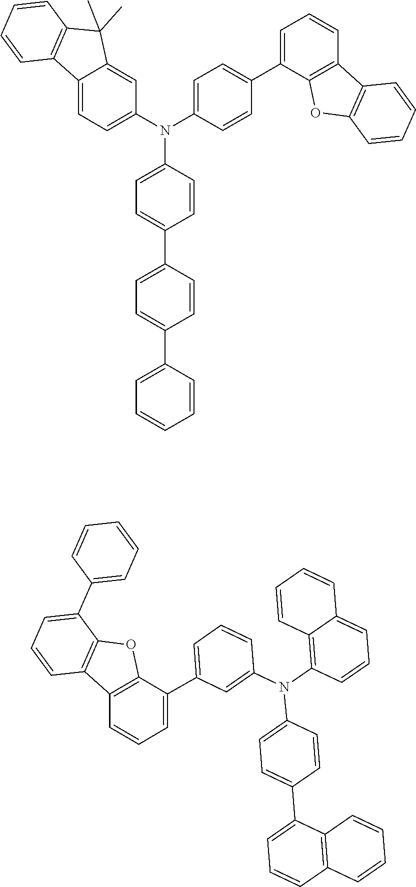 [SMILES: CC1(C)c2ccccc2-c2ccc(N(c3ccc(-c4ccc(-c5ccccc5)cc4)cc3)c3ccc(-c4cccc5c4oc4ccccc45)cc3)cc21 ; c1ccc(-c2cccc3c2oc2c(-c4cccc(N(c5ccc(-c6cccc7ccccc67)cc5)c5cccc6ccccc56)c4)cccc23)cc1]

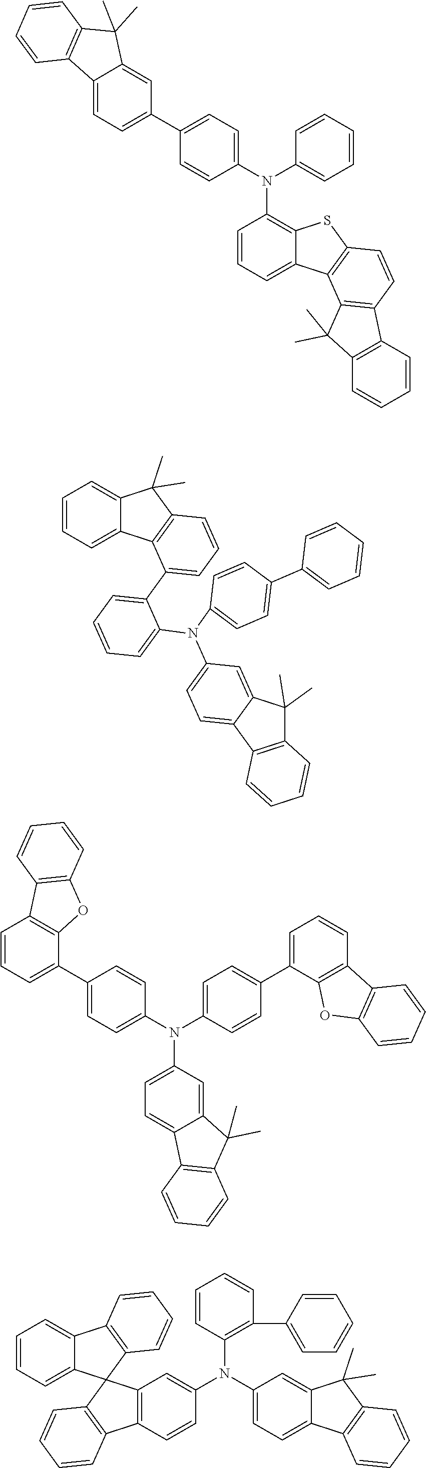 [SMILES: CC1(C)c2ccccc2-c2ccc(-c3ccc(N(c4ccccc4)c4cccc5c4sc4ccc6c(c45)C(C)(C)c4ccccc4-6)cc3)cc21 ; CC1(C)c2ccccc2-c2ccc(N(c3ccc(-c4ccccc4)cc3)c3ccccc3-c3cccc4c3-c3ccccc3C4(C)C)cc21 ; CC1(C)c2ccccc2-c2ccc(N(c3ccc(-c4cccc5c4oc4ccccc45)cc3)c3ccc(-c4cccc5c4oc4ccccc45)cc3)cc21 ; CC1(C)c2ccccc2-c2ccc(N(c3ccc4c(c3)C3(c5ccccc5-c5ccccc53)c3ccccc3-4)c3ccccc3-c3ccccc3)cc21]

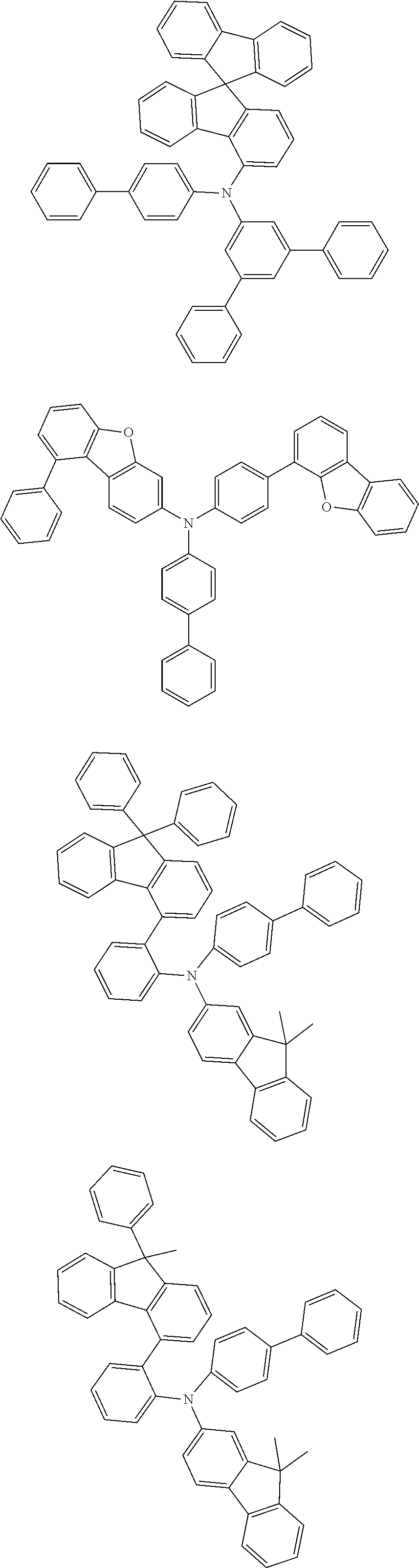 [SMILES: c1ccc(-c2ccc(N(c3cc(-c4ccccc4)cc(-c4ccccc4)c3)c3cccc4c3-c3ccccc3C43c4ccccc4-c4ccccc43)cc2)cc1 ; c1ccc(-c2ccc(N(c3ccc(-c4cccc5c4oc4ccccc45)cc3)c3ccc4c(c3)oc3cccc(-c5ccccc5)c34)cc2)cc1 ; CC1(C)c2ccccc2-c2ccc(N(c3ccc(-c4ccccc4)cc3)c3ccccc3-c3cccc4c3-c3ccccc3C4(c3ccccc3)c3ccccc3)cc21 ; CC1(C)c2ccccc2-c2ccc(N(c3ccc(-c4ccccc4)cc3)c3ccccc3-c3cccc4c3-c3ccccc3C4(C)c3ccccc3)cc21]

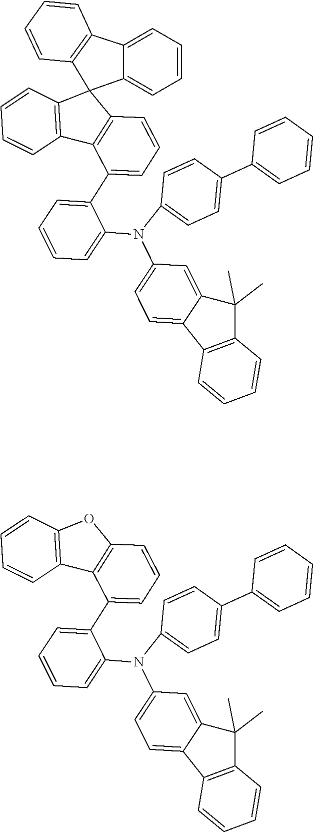 [SMILES: CC1(C)c2ccccc2-c2ccc(N(c3ccc(-c4ccccc4)cc3)c3ccccc3-c3cccc4c3-c3ccccc3C43c4ccccc4-c4ccccc43)cc21 ; CC1(C)c2ccccc2-c2ccc(N(c3ccc(-c4ccccc4)cc3)c3ccccc3-c3cccc4oc5ccccc5c34)cc21]

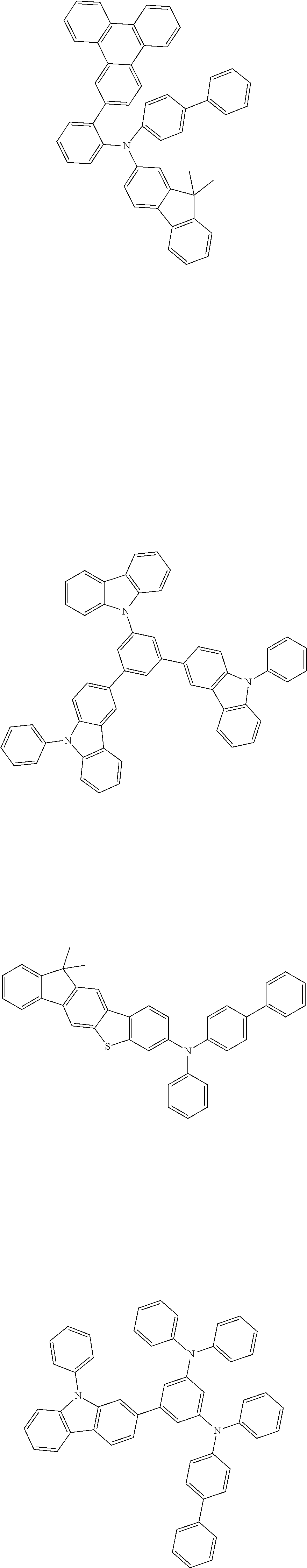 [SMILES: CC1(C)c2ccccc2-c2ccc(N(c3ccc(-c4ccccc4)cc3)c3ccccc3-c3ccc4c5ccccc5c5ccccc5c4c3)cc21 ; c1ccc(-n2c3ccccc3c3cc(-c4cc(-c5ccc6c(c5)c5ccccc5n6-c5ccccc5)cc(-n5c6ccccc6c6ccccc65)c4)ccc32)cc1 ; CC1(C)c2ccccc2-c2cc3sc4cc(N(c5ccccc5)c5ccc(-c6ccccc6)cc5)ccc4c3cc21 ; c1ccc(-c2ccc(N(c3ccccc3)c3cc(-c4ccc5c6ccccc6n(-c6ccccc6)c5c4)cc(N(c4ccccc4)c4ccccc4)c3)cc2)cc1]

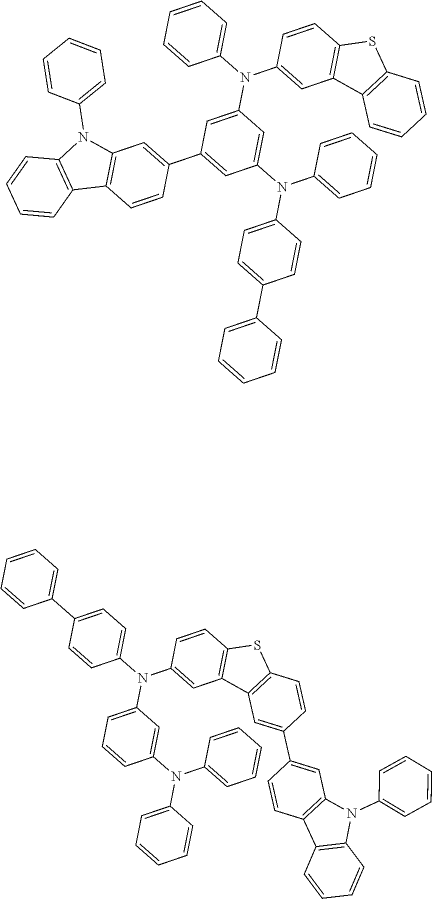 [SMILES: c1ccc(-c2ccc(N(c3ccccc3)c3cc(-c4ccc5c6ccccc6n(-c6ccccc6)c5c4)cc(N(c4ccccc4)c4ccc5sc6ccccc6c5c4)c3)cc2)cc1 ; c1ccc(-c2ccc(N(c3cccc(N(c4ccccc4)c4ccccc4)c3)c3ccc4sc5ccc(-c6ccc7c8ccccc8n(-c8ccccc8)c7c6)cc5c4c3)cc2)cc1]

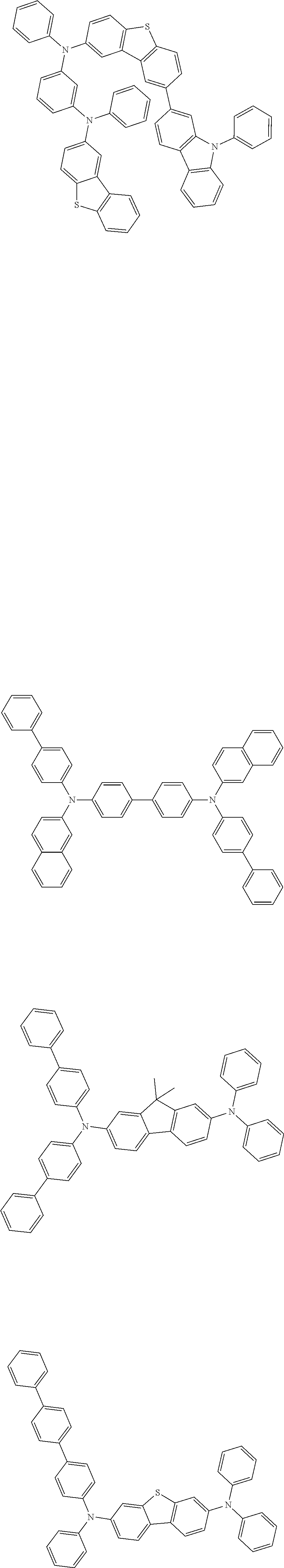 [SMILES: c1ccc(N(c2cccc(N(c3ccccc3)c3ccc4sc5ccc(-c6ccc7c8ccccc8n(-c8ccccc8)c7c6)cc5c4c3)c2)c2ccc3sc4ccccc4c3c2)cc1 ; c1ccc(-c2ccc(N(c3ccc(-c4ccc(N(c5ccc(-c6ccccc6)cc5)c5ccc6ccccc6c5)cc4)cc3)c3ccc4ccccc4c3)cc2)cc1 ; CC1(C)c2cc(N(c3ccccc3)c3ccccc3)ccc2-c2ccc(N(c3ccc(-c4ccccc4)cc3)c3ccc(-c4ccccc4)cc3)cc21 ; c1ccc(-c2ccc(-c3ccc(N(c4ccccc4)c4ccc5c(c4)sc4cc(N(c6ccccc6)c6ccccc6)ccc45)cc3)cc2)cc1]

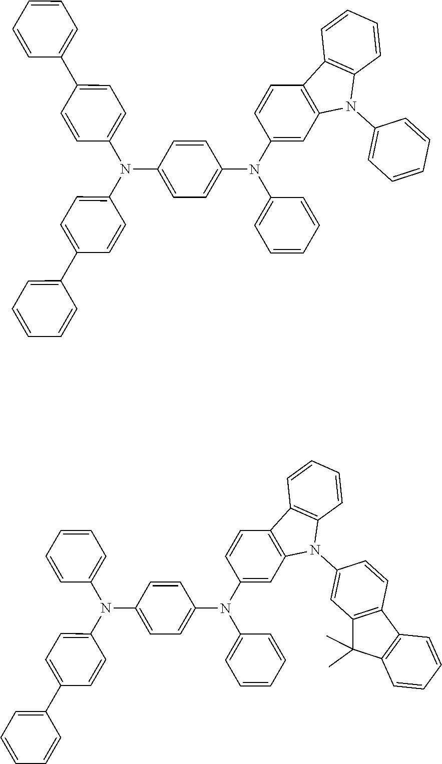 [SMILES: c1ccc(-c2ccc(N(c3ccc(-c4ccccc4)cc3)c3ccc(N(c4ccccc4)c4ccc5c6ccccc6n(-c6ccccc6)c5c4)cc3)cc2)cc1 ; CC1(C)c2ccccc2-c2ccc(-n3c4ccccc4c4ccc(N(c5ccccc5)c5ccc(N(c6ccccc6)c6ccc(-c7ccccc7)cc6)cc5)cc43)cc21]

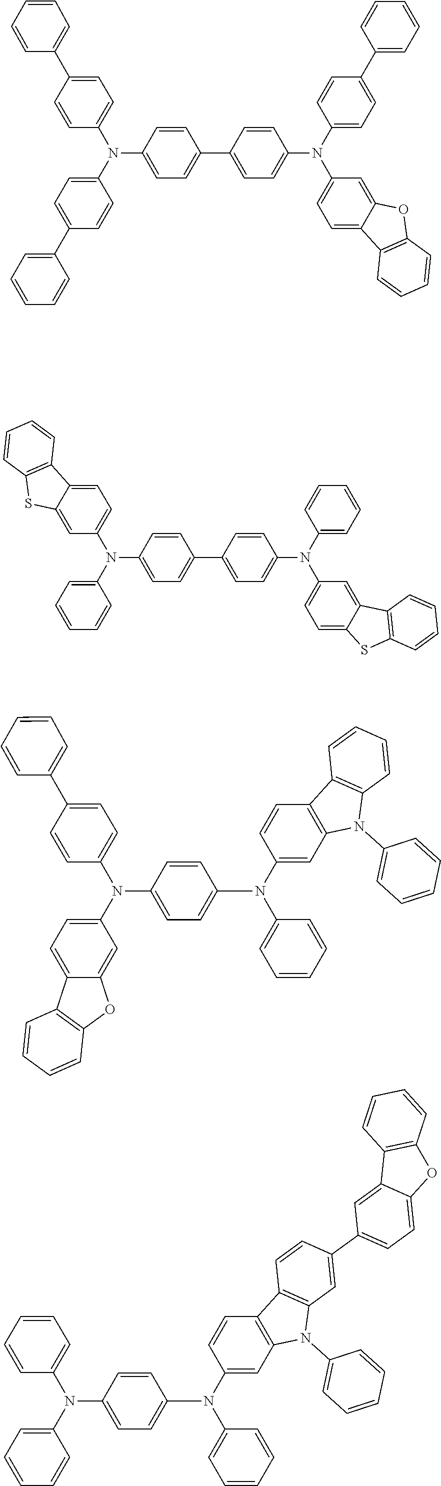 [SMILES: c1ccc(-c2ccc(N(c3ccc(-c4ccccc4)cc3)c3ccc(-c4ccc(N(c5ccc(-c6ccccc6)cc5)c5ccc6c(c5)oc5ccccc56)cc4)cc3)cc2)cc1 ; c1ccc(N(c2ccc(-c3ccc(N(c4ccccc4)c4ccc5sc6ccccc6c5c4)cc3)cc2)c2ccc3c(c2)sc2ccccc23)cc1 ; c1ccc(-c2ccc(N(c3ccc(N(c4ccccc4)c4ccc5c6ccccc6n(-c6ccccc6)c5c4)cc3)c3ccc4c(c3)oc3ccccc34)cc2)cc1 ; c1ccc(N(c2ccccc2)c2ccc(N(c3ccccc3)c3ccc4c5ccc(-c6ccc7oc8ccccc8c7c6)cc5n(-c5ccccc5)c4c3)cc2)cc1]

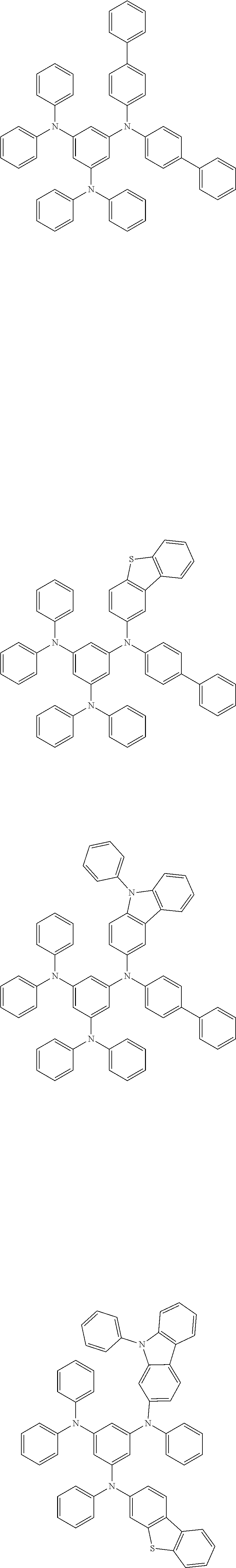 [SMILES: c1ccc(-c2ccc(N(c3ccc(-c4ccccc4)cc3)c3cc(N(c4ccccc4)c4ccccc4)cc(N(c4ccccc4)c4ccccc4)c3)cc2)cc1 ; c1ccc(-c2ccc(N(c3cc(N(c4ccccc4)c4ccccc4)cc(N(c4ccccc4)c4ccccc4)c3)c3ccc4sc5ccccc5c4c3)cc2)cc1 ; c1ccc(-c2ccc(N(c3cc(N(c4ccccc4)c4ccccc4)cc(N(c4ccccc4)c4ccccc4)c3)c3ccc4c(c3)c3ccccc3n4-c3ccccc3)cc2)cc1 ; c1ccc(N(c2ccccc2)c2cc(N(c3ccccc3)c3ccc4c(c3)sc3ccccc34)cc(N(c3ccccc3)c3ccc4c5ccccc5n(-c5ccccc5)c4c3)c2)cc1]

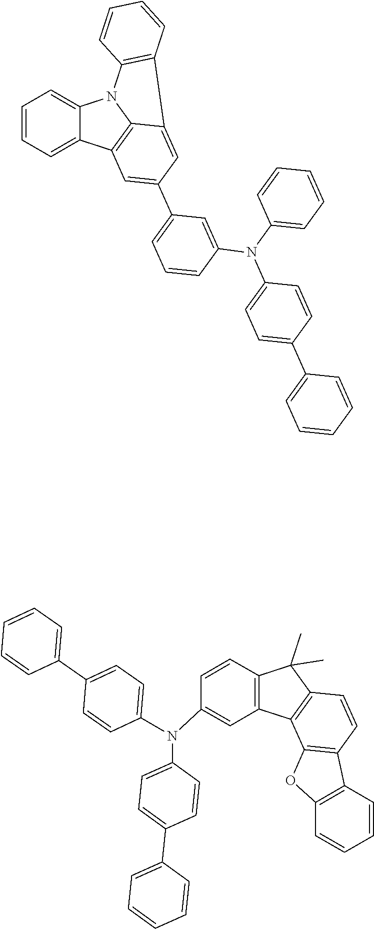 [SMILES: c1ccc(-c2ccc(N(c3ccccc3)c3cccc(-c4cc5c6ccccc6n6c7ccccc7c(c4)c56)c3)cc2)cc1 ; CC1(C)c2ccc(N(c3ccc(-c4ccccc4)cc3)c3ccc(-c4ccccc4)cc3)cc2-c2c1ccc1c2oc2ccccc21]

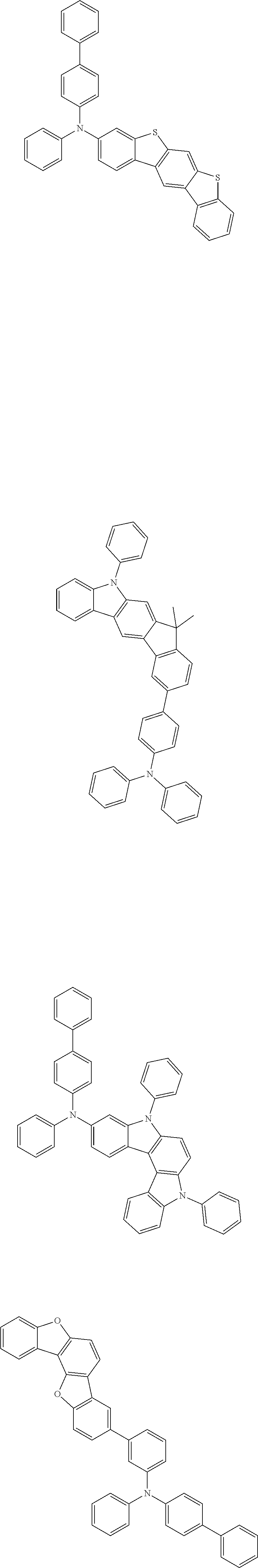 [SMILES: c1ccc(-c2ccc(N(c3ccccc3)c3ccc4c(c3)sc3cc5sc6ccccc6c5cc34)cc2)cc1 ; CC1(C)c2ccc(-c3ccc(N(c4ccccc4)c4ccccc4)cc3)cc2-c2cc3c4ccccc4n(-c4ccccc4)c3cc21 ; c1ccc(-c2ccc(N(c3ccccc3)c3ccc4c5c6c7ccccc7n(-c7ccccc7)c6ccc5n(-c5ccccc5)c4c3)cc2)cc1 ; c1ccc(-c2ccc(N(c3ccccc3)c3cccc(-c4ccc5oc6c(ccc7oc8ccccc8c76)c5c4)c3)cc2)cc1]

In the hole transport auxiliary layer, known compounds disclosed in U.S. Pat. No. 5,061,569A, JP1993-009471A, WO1995-009147A1, JP1995-126615A, JP1998-095973A and the like and compounds similar thereto may be used in addition to the compound.

In an embodiment, in FIG. 1 or 2, an organic light emitting diode may further include an electron transport layer, an electron injection layer, or a hole injection layer as the organic layer 105.

The organic light emitting diodes 100 and 200 may be manufactured by forming an anode or a cathode on a substrate, forming an organic layer using a dry film formation method such as a vacuum deposition method (evaporation), sputtering, plasma plating, and ion plating, and forming a cathode or an anode thereon.

The organic light emitting diode may be applied to an organic light emitting display device.

Hereinafter, the embodiments are illustrated in more detail with reference to examples. However, these examples are exemplary, and the scope of claims is not limited thereto.

### (Synthesis of First Compound)

### Synthesis Example 1: Synthesis of Intermediate Int-6

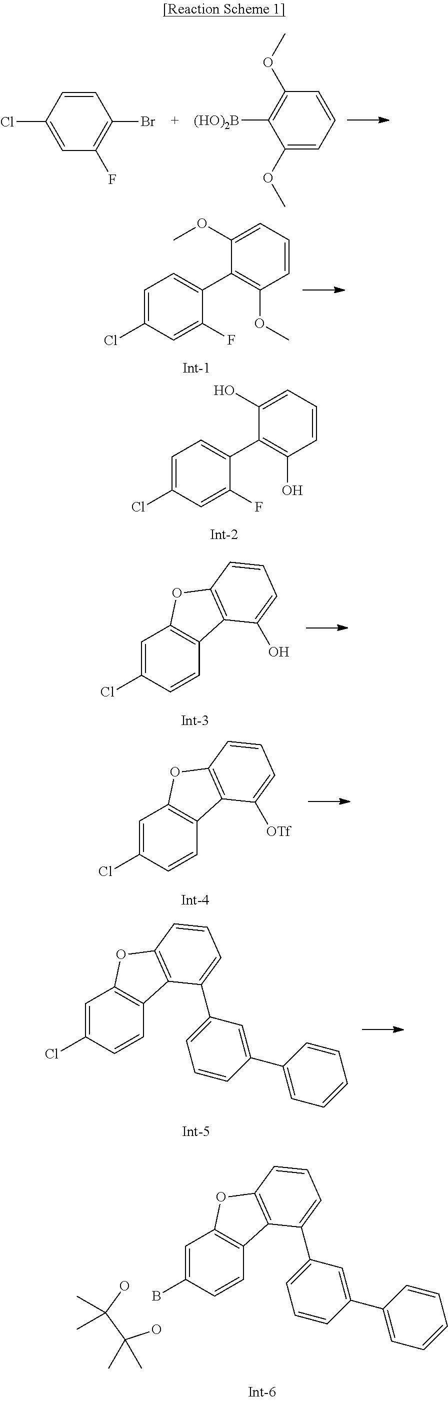

1st Step: Synthesis of Intermediate Int-1

11-bromo-4-chloro-2-fluorobenzene (61 g, 291 mmol), 2,6-dimethoxyphenylboronic acid (50.4 g, 277 mmol), K₂CO₃ (60.4 g, 437 mmol), and Pd(PPh₃)₄ (10.1 g, 8.7 mmol) were dissolved in THE (500 ml) and distilled water (200 ml) in a round-bottomed flask and then, stirred under reflux at 60° C. for 12 hours. When a reaction was completed, after removing an aqueous layer therefrom, column chromatography (hexane:DCM (20%)) was conducted, obtaining 38 g (51%) of Intermediate Int-1.

2nd Step: Synthesis of Intermediate Int-2

Intermediate Int-1 (38 g, 142 mmol) and pyridine hydrochloride (165 g, 1425 mmol) were placed in a round-bottomed flask and stirred under reflux at 200° C. for 24 hours. When a reaction was completed, the resultant was cooled to room temperature and slowly poured into distilled water and then, stirred for 1 hour. A solid was filtered therefrom, obtaining 23 g (68%) of Intermediate Int-2.

3rd Step: Synthesis of Intermediate Int-3

Intermediate Int-2 (23 g, 96 mmol) and K₂CO₃ (20 g, 144 mmol) were dissolved in NMP (100 ml) in a round bottomed flask and then, stirred under reflux at 180° C. for 12 hours. When a reaction was completed, the mixture was poured into an excessive amount of distilled water. Subsequently, a solid was filtered therefrom, dissolved in ethyl acetate, and dried with MgSO₄, and an organic layer was removed therefrom under a reduced pressure. Column chromatography (hexane:ethyl acetate 30%) was performed, obtaining 16 g (76%) of Intermediate Int-3.

4th Step: Synthesis of Intermediate Int-4

Intermediate Int-3 (16 g, 73 mmol) and pyridine (12 ml, 146 mmol) were dissolved in DCM (200 ml) in a round-bottomed flask. After lowering the temperature to 0° C., trifluoromethanesulfonic anhydride (14.7 ml, 88 mmol) was slowly added thereto in a dropwise fashion. After stirring the obtained mixture for 6 hours, when a reaction was completed, an excessive amount of distilled water was added thereto and then, stirred for 30 minutes and extracted with DCM. After removing an organic solvent under a reduced pressure, the rest was vacuum-dried, obtaining 22.5 g (88%) of Intermediate Int-4.

5th Step: Synthesis of Intermediate Int-5

21 g (83%) of Intermediate Int-5 was synthesized in the same manner as the 1st step using Intermediate Int-4 (25 g, 71.29 mmol), 3-biphenylboronic acid (16.23 g, 81.78 mmol), K₂CO₃ (14.78 g, 106.93 mmol), and Pd(PPh₃)₄ (4.12 g, 3.56 mmol).

6th Step: Synthesis of Intermediate Int-6

Intermediate Int-5 (21 g, 59.18 mmol), bis(pinacolato)diboron (19.54 g, 76.94 mmol), Pd(dppf)Cl₂ (2.42 g, 2.96 mmol), tricyclohexylphosphine (3.32 g, 11.84 mmol) and potassium acetate (11.62 g, 118.37 mmol) were dissolved in DMF (320 ml) in a round-bottomed flask. The mixture was stirred under reflux at 120° C. for 10 hours. When a reaction was completed, the mixture was poured into an excessive amount of distilled water and then, stirred for 1 hour. A solid was filtered therefrom and then, dissolved in DCM. MgSO₄ was used to remove moisture therefrom, and an organic solvent was filtered with a silica gel pad and removed under a reduced pressure. The solid was recrystallized with ethyl acetate and hexane, obtaining 18.49 g (70%) of Intermediate Int-6.

### Synthesis Example 2: Synthesis of Intermediate Int-7

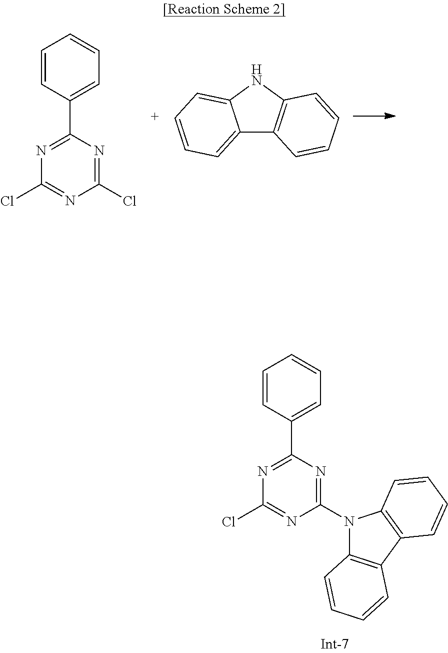 [SMILES: Clc1nc(Cl)nc(-c2ccccc2)n1 ; c1ccc2c(c1)[nH]c1ccccc12 ; Clc1nc(-c2ccccc2)nc(-n2c3ccccc3c3ccccc32)n1]

30 g (132.7 mmol) of 2,4-dichloro-6-phenyl-1,3,5-triazine, 17.75 g (106.2 mmol) of carbazole, and 14.03 g (146.0 mmol) of NaOtBu were placed in a round-bottomed flask and dissolved in 650 ml of THF and then, stirred at room temperature for 12 hours. A solid produced therein was filtered and stirred in an aqueous layer for 30 minutes. The solid was filtered and then, dried to obtain 20 g (42%) of Intermediate Int-7.

### Synthesis Example 3: Synthesis of Compound 1-27

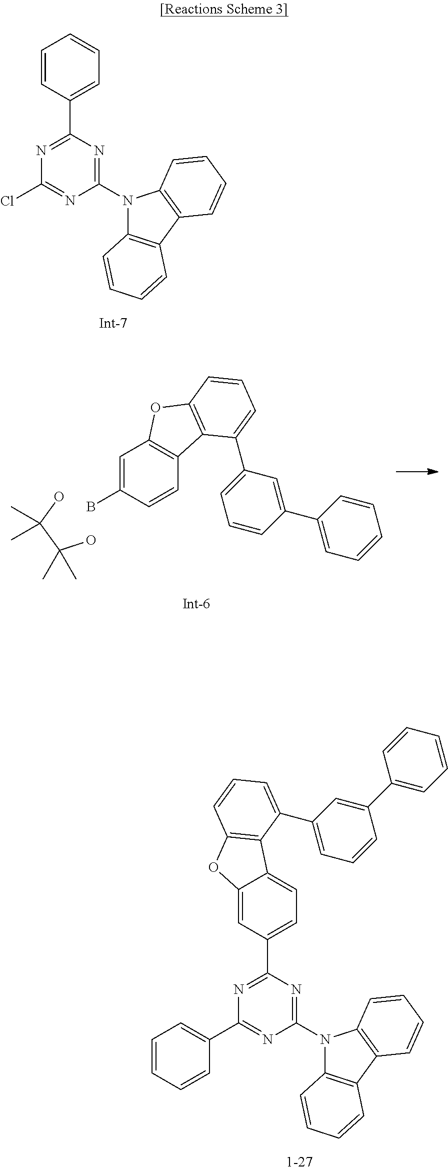

9.5 g (26.6 mmol) of Intermediate Int-7, 14.25 g (31.9 mmol) of Intermediate Int-6, 9.2 g (66.6 mmol) of K₂CO₃, and 1.5 g (1.3 mmol) of Pd (PPh₃)₄ were placed in a round-bottomed flask and dissolved in 100 ml of THF and 40 ml of distilled water and then, stirred under reflux at 70° C. for 12 hours. When a reaction was completed, the mixture was added to 500 mL of methanol, and a solid crystallized therein was filtered, dissolved in monochlorobenznen (MCB), filtered with silica gel, and after removing an appropriate amount of an organic solvent, recrystallized with methanol to obtain 13.1 g (77%) of Compound 1-27.

(LC/MS theoretical value: 640.23 g/mol, measured value: M+=641.39 g/mol)

### Synthesis Example 3: Synthesis of Intermediate Int-14

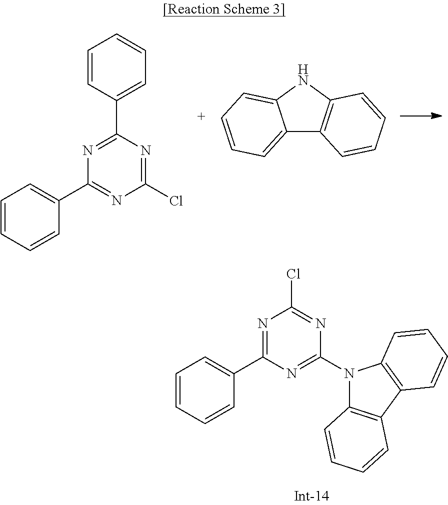 [SMILES: Clc1nc(-c2ccccc2)nc(-c2ccccc2)n1 ; c1ccc2c(c1)[nH]c1ccccc12 ; Clc1nc(-c2ccccc2)nc(-n2c3ccccc3c3ccccc32)n1]

2,4-dichloro-6-phenyl-1,3,5-triazine (30 g, 132.71 mmol), carbazole (17.75 g, 106.17 mmol), and sodium tert-butoxide (14.03 g, 145.98 mmol) were placed in a round-bottomed flask and stirred with THE (650 ml) at room temperature for 12 hours. A solid produced therein was filtered and stirred in an aqueous layer for 30 minutes. After the filtering, a product therefrom was dried, obtaining 20 g (42%) of Intermediate Int-14.

### Synthesis Example 4: Synthesis of Compound 1-27

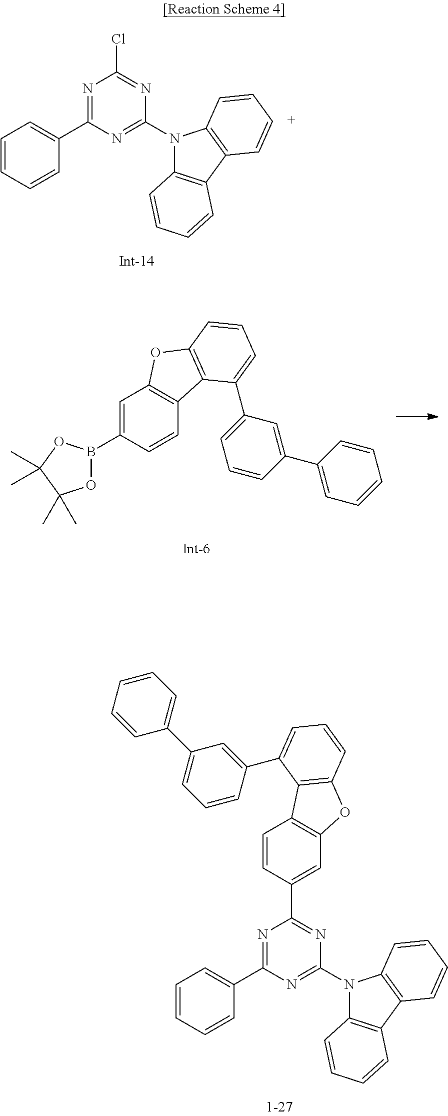 [SMILES: Clc1nc(-c2ccccc2)nc(-n2c3ccccc3c3ccccc32)n1 ; CC1(C)OB(c2ccc3c(c2)oc2cccc(-c4cccc(-c5ccccc5)c4)c23)OC1(C)C ; c1ccc(-c2cccc(-c3cccc4oc5cc(-c6nc(-c7ccccc7)nc(-n7c8ccccc8c8ccccc87)n6)ccc5c34)c2)cc1]

Intermediate Int-14 (9.5 g, 26.62 mmol), Intermediate Int-6 (14.26 g, 31.95 mmol), K₂CO₃ (9.20 g, 66.56 mmol), and Pd(PPh₃)₄ (1.54 g, 1.33 mmol) were placed in a round-bottomed flask and dissolved in THE (100 ml) and distilled water (40 ml) and then, stirred under reflux at 70° C. for 12 hours. When a reaction was completed, the mixture was added to 500 mL of methanol to crystallize a solid, and the solid was filtered, dissolved in monochlorobenzene, filtered with silica gel/Celite, and after removing an appropriate amount of an organic solvent, recrystallized with methanol, obtaining 13.14 g (77%) of Compound 1-27.

(LC/MS theoretical value: 640.23 g/mol, measured value: M+=641.39 g/mol)

### Synthesis Example 5: Synthesis of Compound 1-24

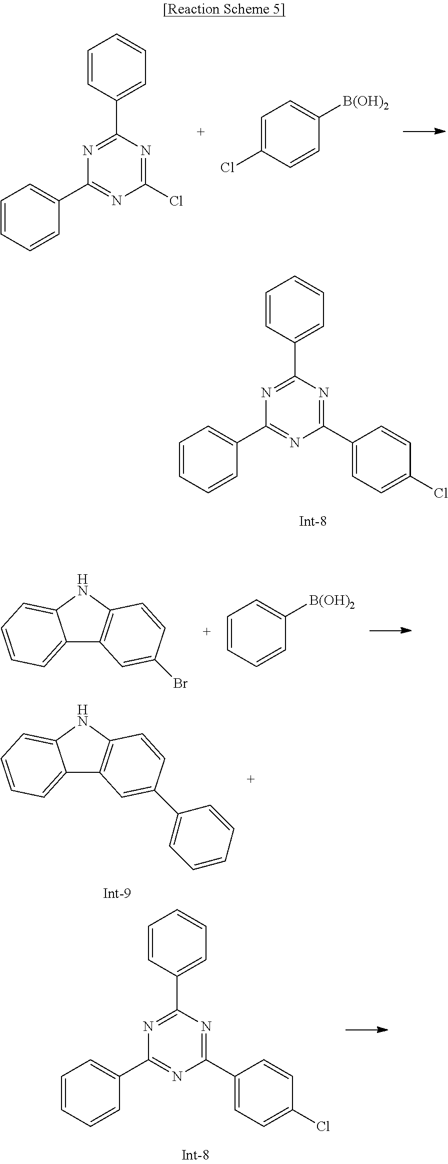

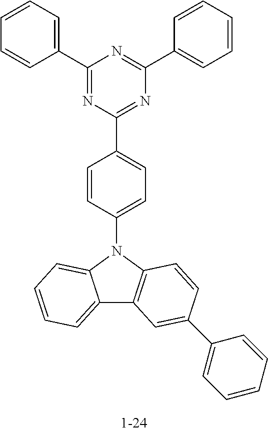 [SMILES: c1ccc(-c2ccc3c(c2)c2ccccc2n3-c2ccc(-c3nc(-c4ccccc4)nc(-c4ccccc4)n3)cc2)cc1]

1st Step: Synthesis of Intermediate Int-8

23.4 g (87.3 mmol) of 2-chloro-4,6-diphenyl-1,3,5-triazine was added to 100 mL of THF, 100 mL of toluene, and 100 mL of distilled water, and 0.9 equivalent of 4-chlorophenylboronic acid, 0.03 equivalent of Pd(PPh₃)₄, and 2 equivalent of K₂CO₃ were added thereto and then, stirred under reflux under a nitrogen atmosphere for 6 hours. After removing an aqueous layer, an organic layer therefrom was dried under a reduced pressure. A solid obtained therefrom was washed with water and hexane and then, recrystallized with 200 mL of toluene to obtain 20 g (67%) of Intermediate Int-8.

2nd Step: Synthesis of Intermediate Int-9

35 g (142 mmol) of 3-bromo-9H-carbazole was dissolved in 500 mL of THF, and 17.3 g (142 mmol) of phenylboronic acid and 8.2 g (7.1 mmol) of Pd(PPh₃)₄ were added thereto and then, stirred. 49.1 g (356 mmol) of K₂CO₃ saturated in water was added thereto and then, stirred under reflux at 80° C. for 12 hours. When a reaction was completed, water was added to the reaction solution, and the mixture was extracted with DCM, treated with MgSO₄ to removed moisture, filtered, and concentrated under a reduced pressure. The obtained residue was separated and purified through column chromatography (hexane:DCM (20%)) to obtain 22.0 g (64%) of Intermediate Int-9.

3rd Step: Synthesis of Compound 1-24

22.0 g (90.4 mmol) of Intermediate Int-9, 31.1 g (90.4 mmol) of Intermediate Int-8, 13.1 g (135.6 mmol) of NaOtBu, 2.5 g (2.7 mmol) of Pd₂(dba)₃, and 5.5 g (50% in toluene) of P(t-Bu)₃ were added to 300 mL of xylene and then, stirred under reflux under a nitrogen flow for 12 hours. After removing the xylene, 200 mL of methanol was added to the obtained mixture, and a solid crystallized therein was filtered, dissolved in MCB, and filtered with silica gel, and an appropriate amount of an organic solvent was concentrated to obtain 32 g (64%) of Compound 1-24.

(LC/MS theoretical value: 550.22 g/mol, measured value: M+=551.23 g/mol)

### Synthesis Example 6: Synthesis of Compound 1-41

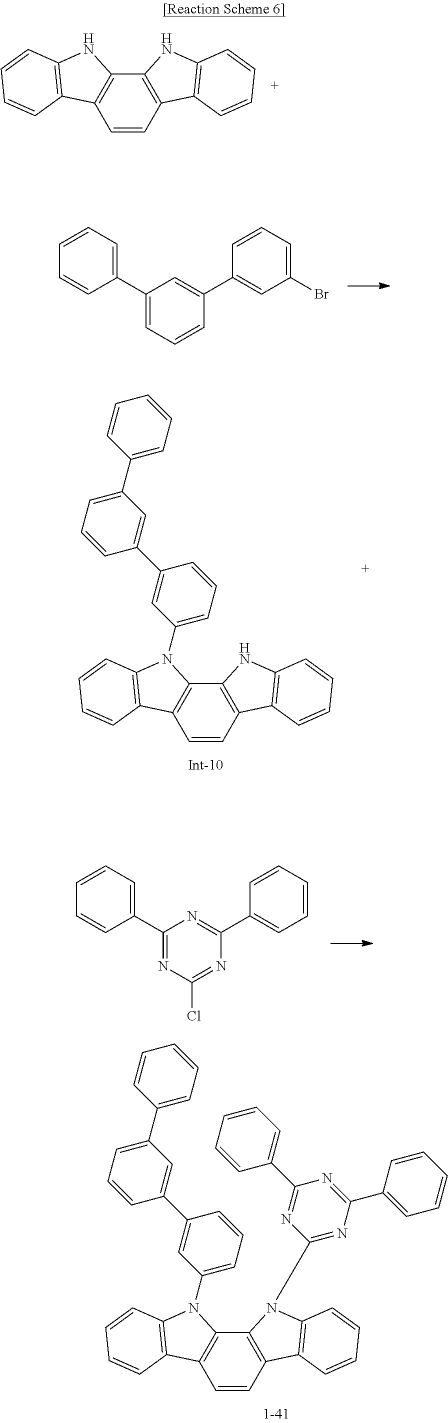

1st Step: Synthesis of Intermediate Int-10

15 g (58.5 mmol) of indolo[2,3B-a]carbazole, 18.1 g (58.5 mmol) of 3-bromo-m-terphenyl, 1.6 g (1.8 mmol) of Pd₂(dba)₃, 2.8 ml (5.8 mmol) of P(t-Bu)₃, and 8.4 g (87.8 mmol) of NaOtBu were suspended in 300 ml of xylene and then, stirred under reflux at 120° C. for 12 hours. When a reaction was completed, distilled water was added thereto and then, stirred for 30 minutes and extracted, and an organic layer therefrom alone was purified through silica gel column (hexane:DCM (30%)) to obtain 16.2 g (57%) of Intermediate Int-10.

2nd Step: Synthesis of Compound 1-41

16.1 g (33.2 mmol) of Intermediate Int-10 and 8.9 g (33.2 mmol) of 2-chloro-4,6-diphenyl-1,3,5-triazine were used in the same method as the 3rd step of Synthesis Example 4 to obtain 11.4 g (48%) of Compound 1-41.

(LC/MS theoretical value: 715.27 g/mol, measured value: M+=716.29 g/mol)

### Synthesis Example 7: Synthesis of Compound 1-25

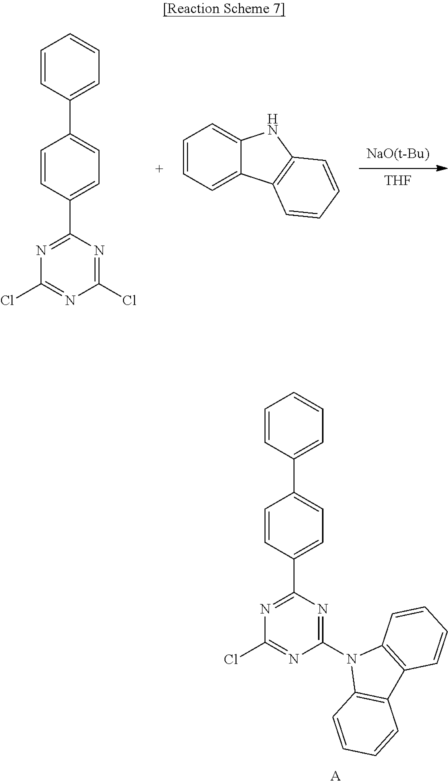

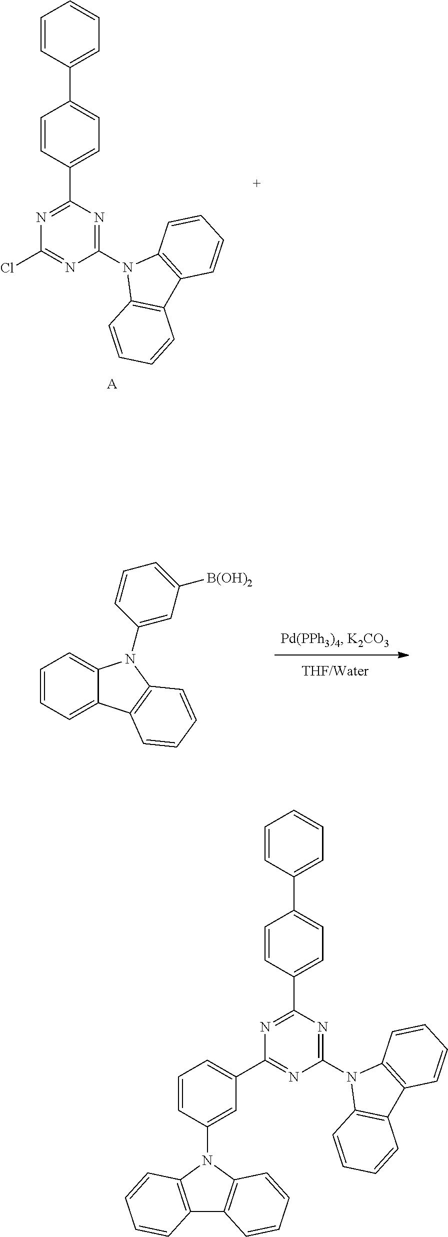

1st Step: Synthesis of Intermediate A

65.5 g (216.79 mmol) of 2-[1,1′-biphenyl]-4-yl-4,6-dichloro-1,3,5-triazine and 25 g (149.51 mmol) of carbazole were suspended in 800 ml of THF, and 15.09 g (156.99 mmol) of NaO(t-Bu) was slowly added thereto. After stirring the mixture for 12 hours at room temperature, a solid produced therein was filtered, washed with distilled water, acetone, and hexane in order to obtain 40.15 g (yield of 62%) of Intermediate A.

2nd Step: Synthesis of Compound 1-25

10 g (23.10 mmol) of Intermediate A, 8.70 g (23.56 mmol) of 3-(9H-carbazol-9-yl)phenyl boronic acid, 0.8 g (0.69 mmol) of Pd(PPh₃)₄, 6.39 g (46.2 mmol) of K₂CO₃ were suspended in 100 ml of THE and 50 ml of distilled water and then, stirred under reflux for 12 hours. When a reaction was completed, after cooling to room temperature, the generated solid was filtered and washed with distilled water and acetone. The resulting solid was heated and dissolved in 200 ml of dichlorobenzene, silica gel-filtered, and recrystallized in 150 ml of dichlorobenzene to obtain 11 g (yield of 74%) of Compound 1-25.

(LC/MS: theoretical value: 639.75 g/mol, measured value: 640.40 g/mol)

### Synthesis Example 8: Synthesis of Compound 1-46

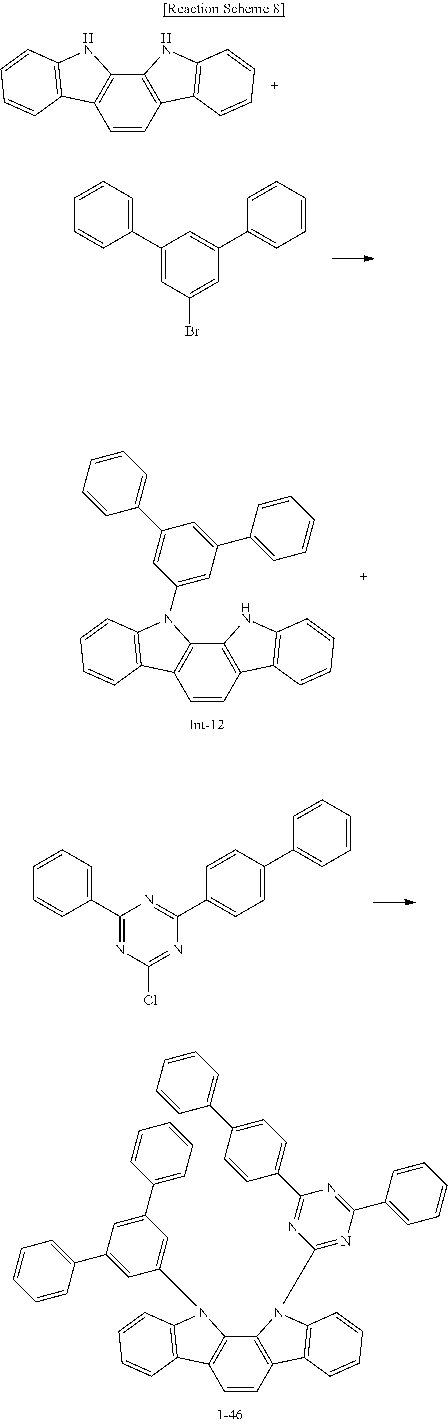 [SMILES: c1ccc2c(c1)[nH]c1c2ccc2c3ccccc3[nH]c21 ; Brc1cc(-c2ccccc2)cc(-c2ccccc2)c1 ; c1ccc(-c2cc(-c3ccccc3)cc(-n3c4ccccc4c4ccc5c6ccccc6[nH]c5c43)c2)cc1 ; Clc1nc(-c2ccccc2)nc(-c2ccc(-c3ccccc3)cc2)n1 ; c1ccc(-c2ccc(-c3nc(-c4ccccc4)nc(-n4c5ccccc5c5ccc6c7ccccc7n(-c7cc(-c8ccccc8)cc(-c8ccccc8)c7)c6c54)n3)cc2)cc1]

1st Step: Synthesis of Intermediate Int-12

12 g (46.8 mmol) of indolo[2,3B-a]carbazole, 14.5 g (46.8 mmol) of 1-bromo-3,5-diphenylbenzene, 1.3 g (1.4 mmol) of Pd₂(dba)₃, 2.3 ml (4.7 mmol) of P(t-Bu)₃, and 6.8 g (70.2 mmol) of NaOtBu were suspended in 220 ml of xylene and then, stirred under reflux at 120° C. for 12 hours. When a reaction was completed, distilled water was added thereto and then, stirred for 30 minutes and extracted, and an organic layer therefrom alone was purified through silica gel column (hexane:DCM (30%)) to obtain 13.6 g (60%) of Intermediate Int-12.

2nd Step: Synthesis of Compound 1-46

13 g (26.8 mmol) of Intermediate Int-12 and 1.3 g (53.7 mmol) of NaH were suspended in 150 ml of dry N,N-dimethylformamide (DMF) and then, stirred under a nitrogen flow. Subsequently, 11.1 g (32.2 mmol) of 2-chloro-4-phenyl-6-(4-biphenyl)-1,3,5-triazine were suspended in 70 ml of dry DMF and then, slowly added to the mixture in a dropwise fashion. After completing the addition in a dropwise fashion, the obtained mixture was stirred for 6 hours. When a reaction was completed, distilled water was added thereto, and crystals precipitated therein were filtered and dried. The crystals were recrystallized in 150 ml of DCB to obtain 8.3 g (39%) of Compound 1-46.

(LC/MS: theoretical value: 791.30 g/mol, measured value: 792.11 g/mol)

### Synthesis Example 9: Synthesis of Compound 1-73

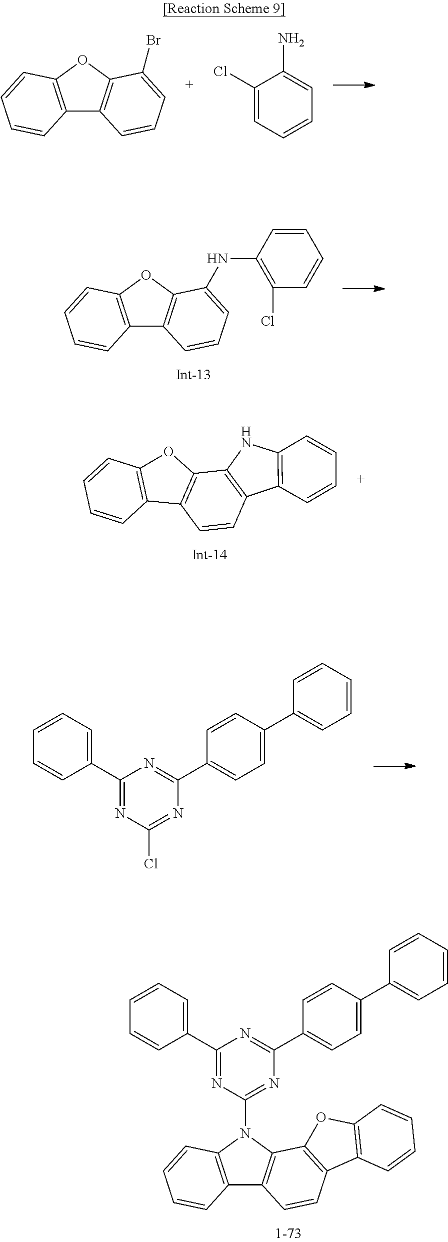 [SMILES: Brc1cccc2c1oc1ccccc12 ; Nc1ccccc1Cl ; Clc1ccccc1Nc1cccc2c1oc1ccccc12 ; c1ccc2c(c1)[nH]c1c2ccc2c3ccccc3oc21 ; Clc1nc(-c2ccccc2)nc(-c2ccc(-c3ccccc3)cc2)n1 ; c1ccc(-c2ccc(-c3nc(-c4ccccc4)nc(-n4c5ccccc5c5ccc6c7ccccc7oc6c54)n3)cc2)cc1]

1st Step: Synthesis of Intermediate Int-13

50 g (202.4 mmol) of 4-bromodibenzofuran, 38.7 g (303.53 mmol) of 2-chloroaniline, 9.3 g (10.2 mmol) of Pd₂(dba)₃, 7.4 ml (30.4 mmol) of P(t-bu)₃, and 29.2 g (303.5 mmol) of NaOtBu were placed in a round-bottomed flask and dissolved in 650 ml of toluene and then, stirred under reflux at 130° C. for 12 hours. When a reaction was completed, after removing an aqueous layer therefrom, the residue was treated through column chromatography (hexane:DCM (20%)) to obtain 38 g (64%) of Intermediate Int-13.

2nd Step: Synthesis of Intermediate Int-14

50 g (170.2 mmol) of Intermediate Int-13, 7.8 g (8.5 mmol) of Pd₂(dba)₃, 110.9 g (340.4 mmol) of CS₂CO₃, and 6.3 g (17.0 mmol) of PCy₃.HBF₄ (tricyclohexylphosphine tetrafluorobarate) were placed in a round-bottomed flask and dissolved in 550 ml of DMAc and then, stirred under reflux at 160° C. for 12 hours. When a reaction was completed, an excessive amount of distilled water was poured thereinto and then, stirred for 1 hour. A solid therein was filtered and dissolved in MCB at a high temperature. Subsequently, MgSO₄ was used to remove moisture, a silica gel pad was used to filter an organic solvent, and a filtrate therefrom was stirred. A solid obtained therefrom was filtered and vacuum-dried to obtain 26.9 g (62%) of Intermediate Int-14.

3rd Step: Synthesis of Compound 1-73

11.5 g (44.7 mmol) of Intermediate Int-14, 18.4 g (53.7 mmol) of 2-chloro-4-phenyl-6-(4-biphenyl)-1,3,5-triazine, and 2.2 g (89.5 mmol) of NaH were placed in a round bottomed flask and dissolved in 180 ml of dry DMF and then, stirred under reflux at room temperature for 12 hours. When a reaction was completed, an excessive amount of distilled water was poured thereinto and then, stirred for 1 hour. A solid therein was filtered and dissolved in MCB of a high temperature. After removing moisture with MgSO₄ and filtering an organic solvent by using a silica gel pad, a filtrate therefrom was stirred. A solid produced therein was filtered and vacuum-dried, obtaining 22.1 g (88%) of Compound 1-73.

(LC/MS: theoretical value: 561.21 g/mol, measured value: 562.62 g/mol)

(Synthesis of Second Compound)

### Synthesis Example 10: Synthesis of Compound 2-1

It was synthesized in the same manner as described in KR10-2017-0068927A.

### Synthesis Example 11: Synthesis of Compound 2-2

It was synthesized in the same manner as described in KR10-2017-0037277A.

### Synthesis Example 12: Synthesis of Compound 2-15

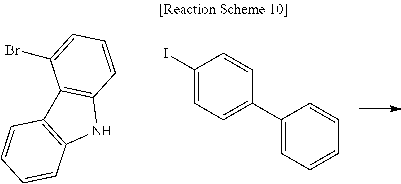 [SMILES: Brc1cccc2[nH]c3ccccc3c12 ; Ic1ccc(-c2ccccc2)cc1]

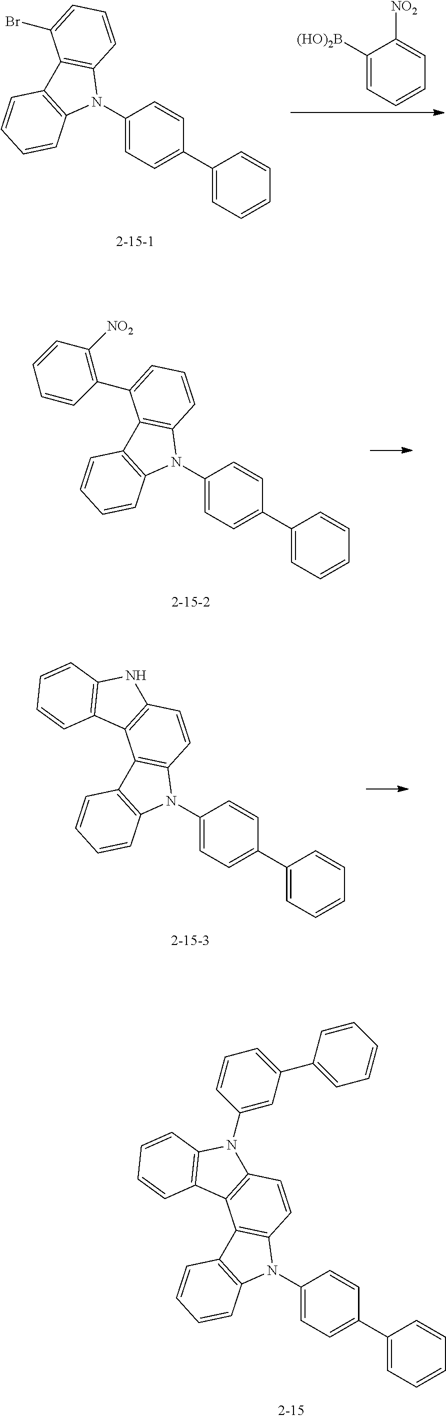 [SMILES: Brc1cccc2c1c1ccccc1n2-c1ccc(-c2ccccc2)cc1 ; O=[N+]([O-])c1ccccc1B(O)O ; O=[N+]([O-])c1ccccc1-c1cccc2c1c1ccccc1n2-c1ccc(-c2ccccc2)cc1 ; c1ccc(-c2ccc(-n3c4ccccc4c4c5c(ccc43)[nH]c3ccccc35)cc2)cc1 ; c1ccc(-c2ccc(-n3c4ccccc4c4c5c6ccccc6n(-c6cccc(-c7ccccc7)c6)c5ccc43)cc2)cc1]

1st Step: Synthesis of Intermediate 2-15-1

In a round-bottomed flask, 10.44 g (42.41 mmol) of 4-bromo-9H-carbazole, 11.88 g (42.41 mmol) of 4-iodo-1,1′-biphenyl (Aldrich), 0.388 g (0.424 mmol) of Pd₂(dba)₃, 0.206 g (0.848 mmol) of P(t-Bu)3, and 6.11 g (63.61 mmol) of NaO(t-Bu) were suspended in 420 ml of toluene and stirred at 60° C. for 12 hours. After completion of the reaction, distilled water was added thereto, stirred for 30 minutes, and extracted and only the organic layer was columned with a silica gel column (hexane/dichloromethane=9:1 (v/v)) to obtain 14.70 g (yield of 87%) of Intermediate 2-15-1.

2nd Step: Synthesis of Intermediate 2-15-2

In a round-bottom flask, 15.50 g (38.92 mmol) of the synthesized Intermediate 2-15-1, 7.15 g (42.81 mmol) of (2-nitrophenyl)-boronic acid, and 16.14 g (116.75 mmol) of potassium carbonate, 1.35 g (1.17 mmol) of tetrakis-(triphenylphosphine)palladium(0) (Pd(PPh₃)₄) was suspended in 150 ml of toluene and 70 ml of distilled water and then stirred under reflux for 12 hours. Then, extraction was performed with dichloromethane and distilled water, and the organic layer was filtered through silica gel. Then, the organic solution was removed, and the product solid was recrystallized from dichloromethane and n-hexane to obtain 13.72 g (yield of 80%) of Intermediate 2-15-2.

3rd Step: Synthesis of Intermediate 2-15-3

22.46 g (51.00 mmol) of Intermediate 2-15-2 and 52.8 ml of triethyl phosphite were placed in a round-bottomed flask and then, substituted with nitrogen and stirred for 12 hours at 160° C. When a reaction was completed, 3 L of MeOH was added thereto and then, filtered, and a filtrate therefrom was volatilized. A product therefrom was purified (hexane) through column chromatography, obtaining 10.42 g (yield: 50%) of Intermediate 2-15-3.

4th Step: Synthesis of Compound 2-15

Compound 2-15 was synthesized in the same manner as in the 1st step of Synthesis Example 12 by using Intermediate 2-15-3 and 1-iodo-3-phenylbenzene (yield: 60%).

(LC/MS: theoretical value: 560.23 g/mol, measured value: 561.57 g/mol)

### Synthesis Example 13: Synthesis of Compound 2-33

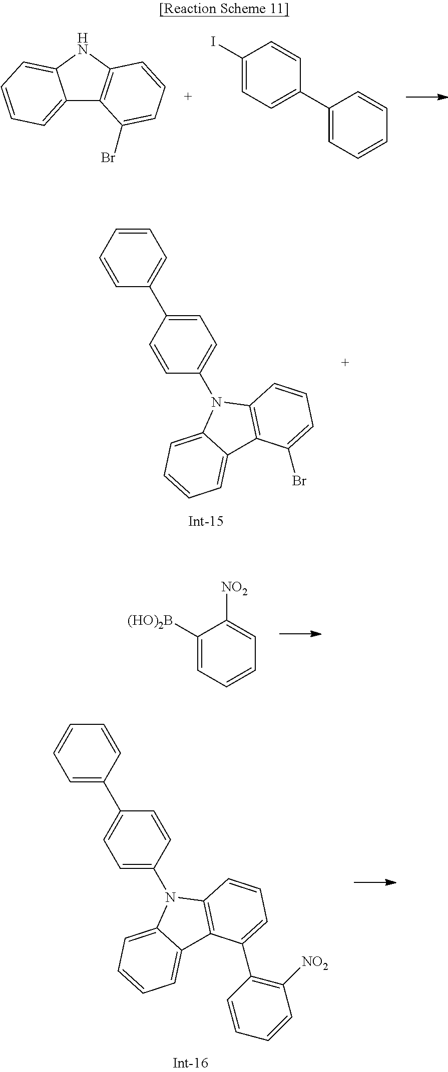 [SMILES: Brc1cccc2[nH]c3ccccc3c12 ; Ic1ccc(-c2ccccc2)cc1 ; Brc1cccc2c1c1ccccc1n2-c1ccc(-c2ccccc2)cc1 ; O=[N+]([O-])c1ccccc1B(O)O ; O=[N+]([O-])c1ccccc1-c1cccc2c1c1ccccc1n2-c1ccc(-c2ccccc2)cc1]

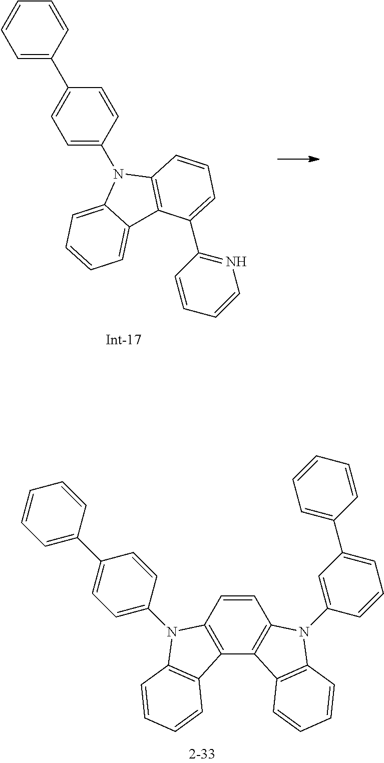 [SMILES: c1ccc(-c2ccc(-n3c4ccccc4c4c(-c5ccccn5)cccc43)cc2)cc1 ; c1ccc(-c2ccc(-n3c4ccccc4c4c5c6ccccc6n(-c6cccc(-c7ccccc7)c6)c5ccc43)cc2)cc1]

1st Step: Synthesis of Intermediate Int-15

10.4 g (42.4 mmol) of 4-bromo-9H-carbazole, 11.9 g (42.4 mmol) of 4-iodo-1,1′-biphenyl, 0.39 g (0.42 mmol) of Pd₂(dba)₃, 0.21 g (0.85 mmol) of P(t-Bu)₃, and 6.1 g (63.6 mmol) of NaO^{t}—Bu were suspended in 420 ml of toluene and then, stirred at 60° C. for 12 hours. When a reaction was completed, distilled water was added thereto and then, stirred for 30 minutes, extracted, and treated through column chromatography (hexane:DCM (10%)) to obtain 14.7 g (87%) of Intermediate Int-15.

2nd Step: Synthesis of Intermediate Int-16

15.5 g (38.9 mmol) of Intermediate Int-15, 7.2 g (42.8 mmol) of 2-nitrophenylboronic acid, 16.1 g (116.7 mmol) of K₂CO₃, and 1.4 g (1.2 mmol) of Pd(PPh₃)₄ were suspended in 150 ml of toluene and 70 ml of distilled water and then, stirred under reflux for 12 hours. The resultant was treated with DCM and distilled water, and an organic layer therefrom was silica gel-filtered. Subsequently, after removing an organic solution, a solid produced therein was recrystallized with DCM and hexane to obtain 13.7 g (80%) of Intermediate Int-16.

3rd Step: Synthesis of Intermediate Int-17

22.5 g (51.0 mmol) of Intermediate Int-16 and 52.8 ml of triethyl phosphite were added thereto, and after substituted with nitrogen, the mixture was stirred under reflux for 12 hours at 160° C. When a reaction was completed, 3 L of methanol was added thereto and then, stirred and filtered, and a filtrate therefrom was distilled under a reduced pressure. The obtained product was treated through column chromatography (hexane:DCM (10%)) to obtain 10.4 g (50%) of Intermediate Int-17.

4th Step: Synthesis of Compound 2-33

The synthesized Intermediate Int-17 and 3B-iodo-biphenyl were used in the same method as the 1st step of Synthesis Example 13 to synthesize Compound 2-33.

(LC/MS: theoretical value: 560.23 g/mol, measured value: 561.57 g/mol)

### Synthesis Example 14: Synthesis of Compound 2-13

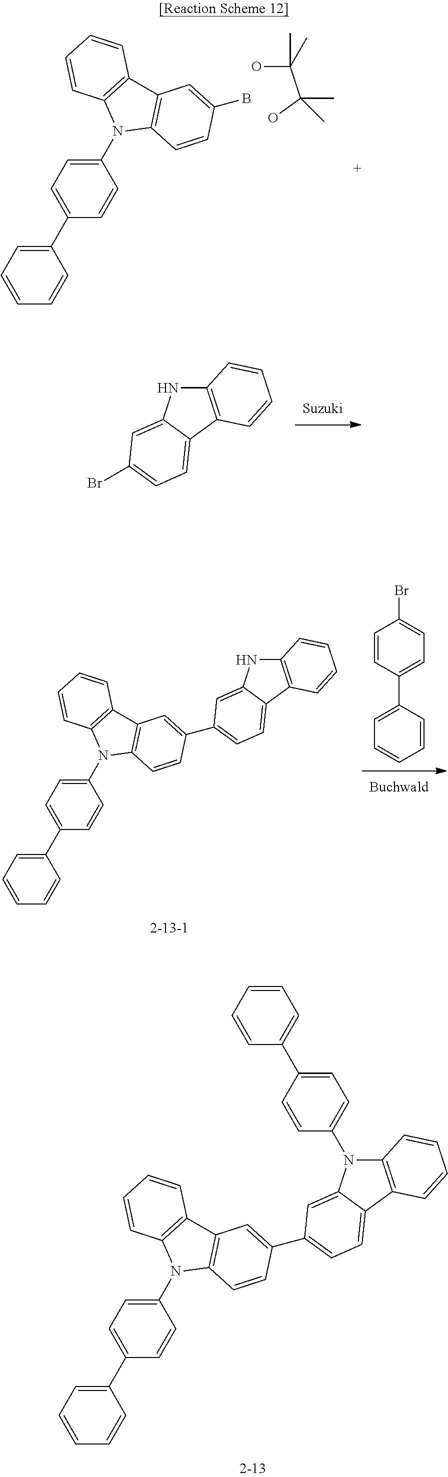

1st Step: Synthesis of Intermediate 2-13-1

In a round-bottomed flask, 18.23 g (40.94 mmol) of 2-[9-([1,1′-biphenyl]-4-yl)-9H-carbazole-3-yl]-4,4,5,5-tetramethyl-1,3,2-dioxaborolane, 11.08 g (45.03 mmol) of 2-bromo-9H-carbazole, 11.32 g (81.88 mmol) of potassium carbonate, and 1.42 g (1.23 mmol) of tetrakis-(triphenylphosphine)palladium (0) (Pd(PPh₃)₄) were suspended in 180 ml of tetrahydrofuran (THF) and 75 ml of distilled water and then, stirred under reflux for 12 hours. After extracting with dichloromethane and distilled water, an organic layer was silica gel-filtered. Subsequently, after removing an organic solution, a product solid therefrom was recrystallized with dichloromethane and n-hexane, obtaining 18.05 g (yield: 91%) of Intermediate 2-13-1.

2nd Step: Synthesis of Compound 2-13

In a round-bottomed flask, 13.29 g (27.42 mmol) of Intermediate 2-13-1, 6.39 g (27.42 mmol) of 1-bromo-4-phenylbenzene, 0.25 g (0.274 mmol) of Pd₂(dba)₃, 0.133 g (0.274 mmol) of P(t-Bu)₃, and 3.95 g (41.13 mmol) of NaO(t-Bu) were suspended in 300 ml of toluene and then, stirred at 60° C. for 12 hours. When a reaction was completed, distilled water was added thereto and then, stirred for 30 minutes and extracted, and an organic layer therefrom alone was columned through silica gel column (hexane/dichloromethane=9:1 (v/v)), obtaining 15.37 g (yield: 88%) of Compound 2-13.

LC-Mass (theoretical value: 636.26 g/mol, measured value: M+=637.40 g/mol)

### Synthesis Example 15: Synthesis of Compound 2-8

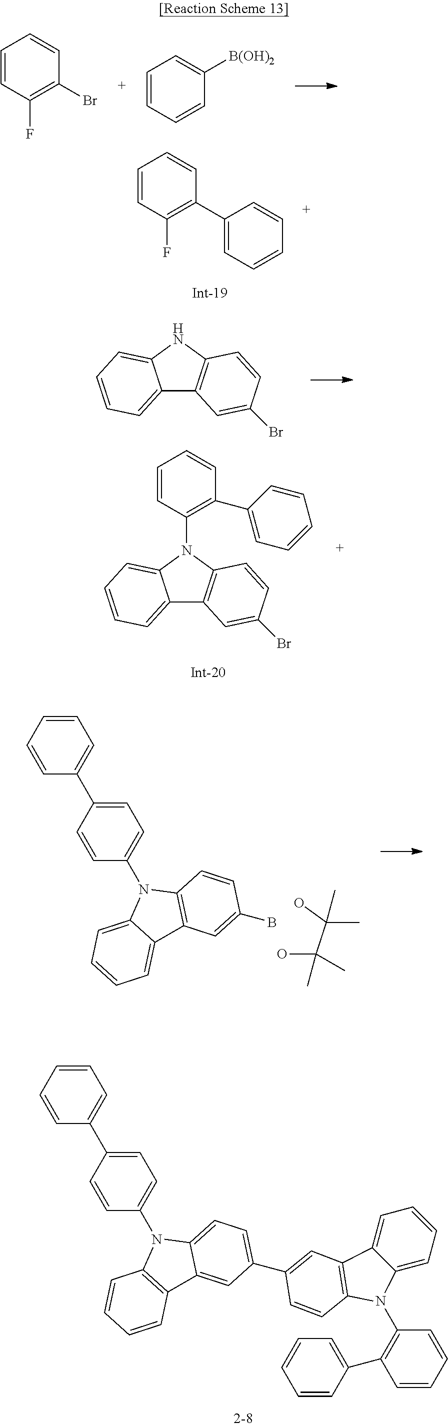

1st Step: Synthesis of Intermediate Int-19

105 g (600 mmol) of 2-bromo-1-fluorobenzene, 87.8 g (720 mmol) of phenylboronic acid, 124.4 g (900 mmol) of K₂CO₃, and 20.8 g (18 mmol) of Pd(PPh₃)₄ were suspended in 1,200 ml of THE and 450 ml of distilled water under a nitrogen flow and then, stirred under reflux for 12 hours. When a reaction was completed, the resultant was extracted with DCM and treated through column chromatography (hexane:DCM (10%)) to obtain 77.5 g (75%) of Intermediate Int-19.

2nd Step: Synthesis of Intermediate Int-20

30 g (174.2 mmol) of Intermediate Int-19, 55.7 g (226.5 mmol) of 3B-bromo-9H-carbazole, and 8.4 g (348.5 mmol) of NaH were suspended in 290 ml of N-methyl-2-pyrrolidone (NMP) under a nitrogen flow and then, stirred under reflux for 18 hours. The reactant was slowly poured into an excessive amount of water and then, stirred, and a solid therein was filtered to obtain 41.6 g (60%) of Intermediate Int-20.

3rd Step: Synthesis of Compound 2-8

25.0 g (62.8 mmol) of Intermediate Int-20, 27.9 g (62.8 mmol) of 9-(4-biphenyl)-3-(tetramethyl-1,3,2-dioxaborolane-2-yl)-9H-carbazole, 17.4 g (125.5 mmol) of K₂CO₃, and 2.2 g (1.9 mmol) of Pd(PPh₃)₄ were suspended in 120 ml of THF and 60 ml of distilled water under a nitrogen flow and then, stirred under reflux for 12 hours. When a reaction was completed, the resultant was extracted with DCM and treated through column chromatography (hexane:DCM (30%)), and a solid obtained therefrom was recrystallized with 250 ml of toluene to obtain 31.9 g (80%) of Compound 2-8.

LC-Mass (theoretical value: 636.78 g/mol, measured value: M+=637.87 g/mol)

### (Third Compound)

### Synthesis Example 16: Synthesis of Compound 3A-1

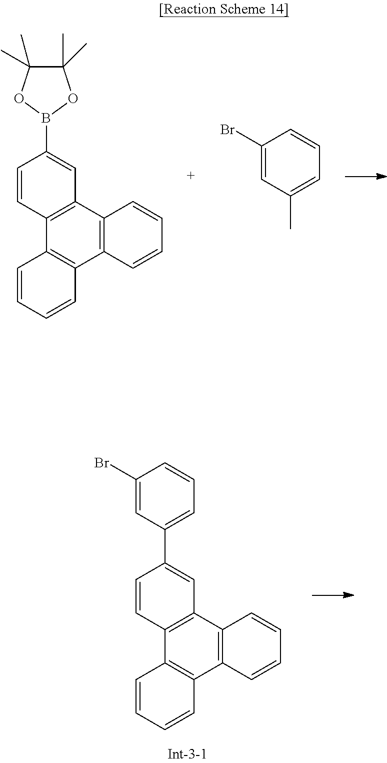

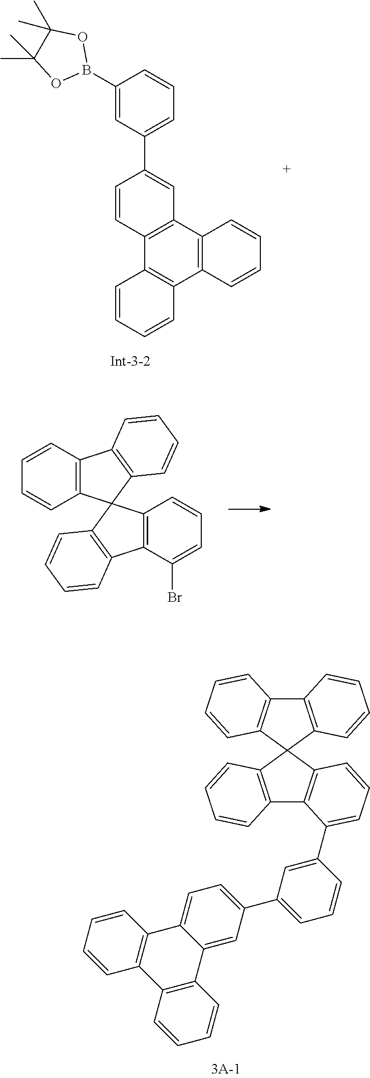

1st Step: Synthesis of Intermediate Int 3-1

50.3 g (142.1 mmol) of 4,4,5,5-tetramethyl-2-(triphenylen-2-yl)-1,3,2-dioxaborolane, 40.2 g (142.1 mmol) of 1-bromo-3-iodobenzene, 29.5 g (213.2 mmol) of K₂CO₃, and 4.9 g (4.3 mmol) of Pd(PPh₃)₄ were suspended in 280 ml of THF and 110 ml of distilled water under a nitrogen flow and then, stirred under reflux for 8 hours. When a reaction was completed, the resultant was extracted with DCM and treated through column chromatography (hexane:DCM (20%)), obtaining 39.3 g (78%) of Intermediate Int 3-1 as a solid.

2nd Step: Synthesis of Intermediate Int 3-2

77 g (203.3 mmol) of Intermediate Int 3-1, 59.4 g (233.8 mmol) of bis(pinacolato)diboron, 4.8 g (5.9 mmol) of Pd(dppf)Cl₂, and 28.9 g (294.8 mmol) of potassium acetate were placed in a round-bottomed flask and dissolved in 400 ml of DMF. The mixture was stirred under reflux at 120° C. for 12 hours. When a reaction was completed, the mixture was poured into an excessive amount of distilled water and then, stirred for 1 hour. A solid therein was filtered and dissolved in DCM. After removing moisture with MgSO₄, an organic solvent was filtered with silica gel pad and removed therefrom under a reduced pressure. A solid therefrom was recrystallized with ethyl acetate and hexane, obtaining 41.8 g (70%) of Intermediate Int 3-2.

3rd Step: Synthesis of Compound 3A-1

61.2 g (142.1 mmol) of Intermediate Int-3-2, 56.2 g (142.1 mmol) of 4-bromo-9,9′-spirobi[9H-fluorene], 29.5 g (213.2 mmol) of K₂CO₃, and 4.9 g (4.3 mmol) of Pd(PPh₃)₄ were suspended in 280 ml of THE and 110 ml of distilled water and then, stirred under reflux for 8 hours under a nitrogen flow. When a reaction was completed, the resultant was extracted with DCM and then, treated with column chromatography (hexane:DCM (20%)), obtaining 39.3 g (78%) of Compound 3A-1.

LC-Mass (theoretical value: 618.23 g/mol, measured value: M+=619.40 g/mol)

### Synthesis Example 17: Synthesis of Compound 3A-2

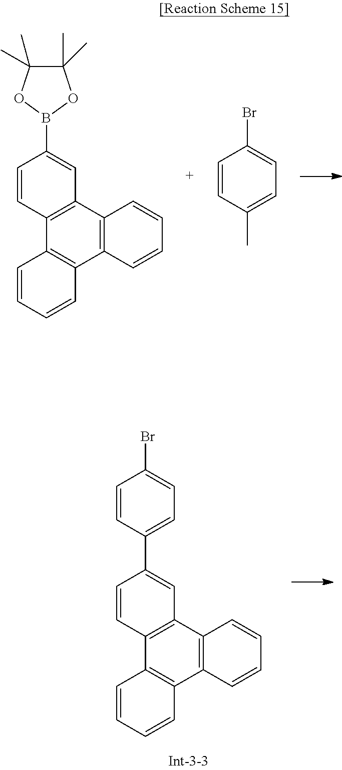

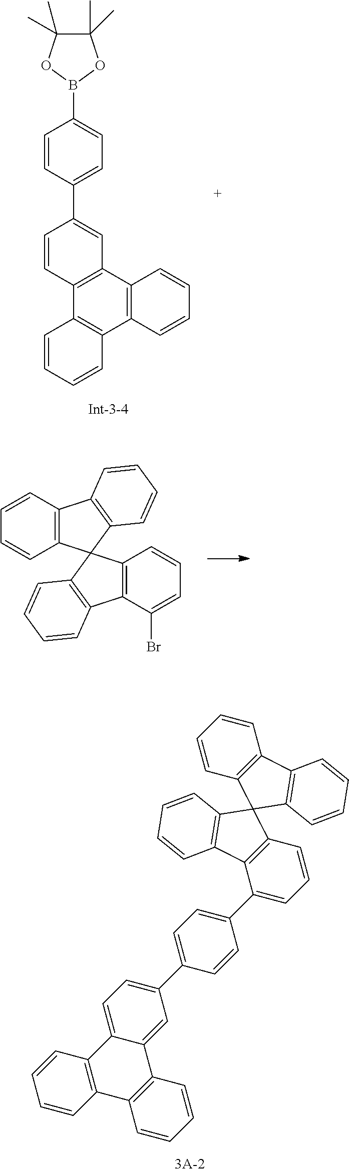

1st Step: Synthesis of Intermediate Int 3-3

50.3 g (142.1 mmol) of 4,4,5,5-tetramethyl-2-(triphenylen-2-yl)-1,3,2-dioxaborolane, 40.2 g (142.1 mmol) of 1-bromo-4-iodobenzene, 29.5 g (213.2 mmol) of K₂CO₃, and 4.9 g (4.3 mmol) of Pd(PPh₃)₄ were suspended in 280 ml of THF and 110 ml of distilled water under a nitrogen flow and then, stirred under reflux for 8 hours. When a reaction was completed, the resultant was extracted with DCM and treated through column chromatography (hexane:DCM (20%)), obtaining 43.6 g (80%) of intermediate Int 3-3 as a solid.

2nd Step: Synthesis of Intermediate Int 3-4

77 g (203.3 mmol) of Intermediate Int 3-3, 59.4 g (233.8 mmol) of bis(pinacolato)diboron, 4.8 g (5.9 mmol) of Pd(dppf)Cl₂, and 28.9 g (294.8 mmol) of potassium acetate were placed in a round-bottomed flask and dissolved in 400 ml of DMF. The mixture was stirred under reflux at 120° C. for 12 hours. When a reaction was completed, the mixture was poured into an excessive amount of distilled water and then, stirred for 1 hour. A solid was filtered therefrom and dissolved in DCM. After removing moisture with MgSO₄, an organic solvent was filtered therefrom with a silica gel pad and removed under a reduced pressure. A solid therefrom was recrystallized with ethyl acetate and hexane, obtaining 65.6 g (75%) of Intermediate Int 3-4.

3rd Step: Synthesis of Compound 3A-2

61.2 g (142.1 mmol) of Intermediate Int 3-4, 56.2 g (142.1 mmol) of 4-bromo-9,9′-spirobi[9H-fluorene], 29.5 g (213.2 mmol) of K₂CO₃, and 4.9 g (4.3 mmol) of Pd(PPh₃)₄ were suspended in 280 ml of THF and 110 ml of distilled water under a nitrogen flow and stirred under reflux for 8 hours. When a reaction was completed, the resultant was extracted with DCM and treated with column chromatography (hexane:DCM (20%)), obtaining 39.3 g (78%) of Compound 3A-2 as a solid.

LC-Mass (theoretical value: 618.23 g/mol, measured value: M+=619.39 g/mol)

### Synthesis Example 18: Synthesis of Compound 3B-4

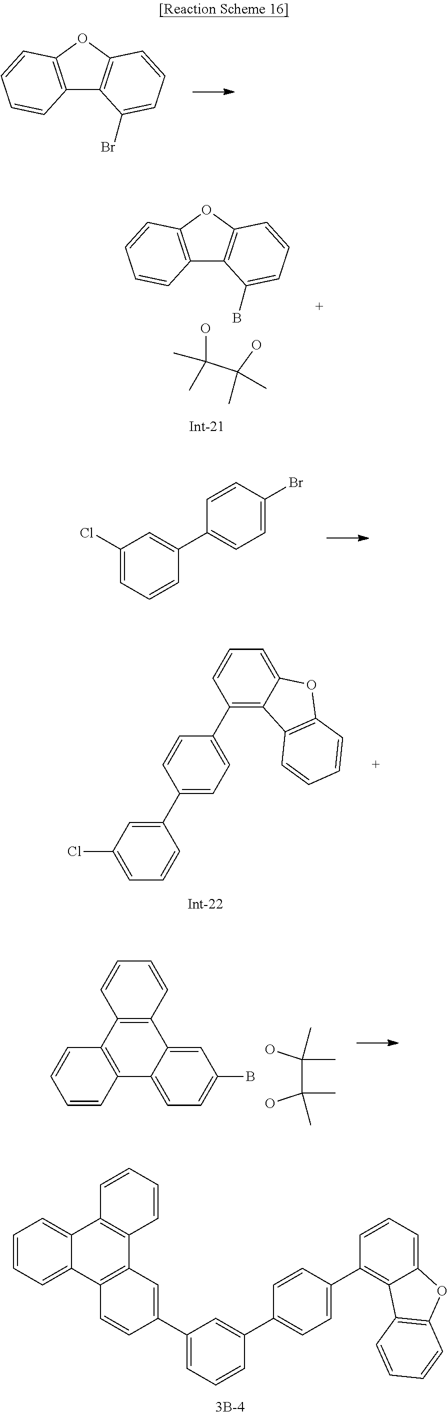

1st Step: Synthesis of Intermediate Int-21

50 g (203.3 mmol) of 1-bromodibenzofuran, 59.4 g (233.8 mmol) of bis(pinacolato)diboron, 4.8 g (5.9 mmol) of Pd(dppf)Cl₂, and 28.9 g (294.8 mmol) of potassium acetate were placed in a round-bottomed flask and dissolved in 400 ml of DMF. The mixture was stirred under reflux at 120° C. for 12 hours. When a reaction was completed, the mixture was poured into an excessive amount of distilled water and then, stirred for 1 hour. A solid therein was filtered and dissolved in DCM. After removing moisture with MgSO₄, an organic solvent was filtered with a silica gel pad and removed under a reduced pressure. A solid therefrom was recrystallized with ethyl acetate and hexane, obtaining 41.8 g (70%) of Intermediate Int-21.

2nd Step: Synthesis of Intermediate Int-22

37.9 g (142.1 mmol) of 4-bromo-3′-chloro-1,1′-biphenyl, 41.8 g (142.1 mmol) of Intermediate Int-21, 29.5 g (213.2 mmol) of K₂CO₃, and 4.9 g (4.3 mmol) of Pd(PPh₃)₄ were suspended in 280 ml of THF and 110 ml of distilled water under a nitrogen flow and stirred under reflux for 8 hours. When a reaction was completed, the resultant was extracted with DCM and treated through column chromatography (hexane:DCM (20%)), obtaining 39.3 g (78%) of Intermediate Int-22 as a solid.

3rd Step: Synthesis of Compound 3B-4

39.3 g (110.8 mmol) of Intermediate Int-22, 39.2 g (110.8 mmol) of 4,4,5,5-tetramethyl-2-(triphenylen-2-yl)-1,3,2-dioxaborolane, 65.0 g (199.4 mmol) of Cs₂CO₃, 5.1 g (5.5 mmol) of Pd₂(dba)₃, and 8.9 g (22.2 mmol) of P(t-Bu)₃ were suspended in 440 ml of 1,4-dioxane under a nitrogen flow and stirred under reflux for 8 hours. When a reaction was completed, after cooling to room temperature, an excessive amount of methanol was poured thereinto to form a solid, and the solid was filtered. The filtered solid was washed subsequently with distilled water, methanol, and acetone and then, recrystallized with 400 ml of MCB, obtaining 29.1 g (48%) of Compound 3B-4.

LC-Mass (theoretical value: 546.66 g/mol, measured value: M+=547.51 g/mol)

### Synthesis Example 19: Synthesis of Compound 3B-7

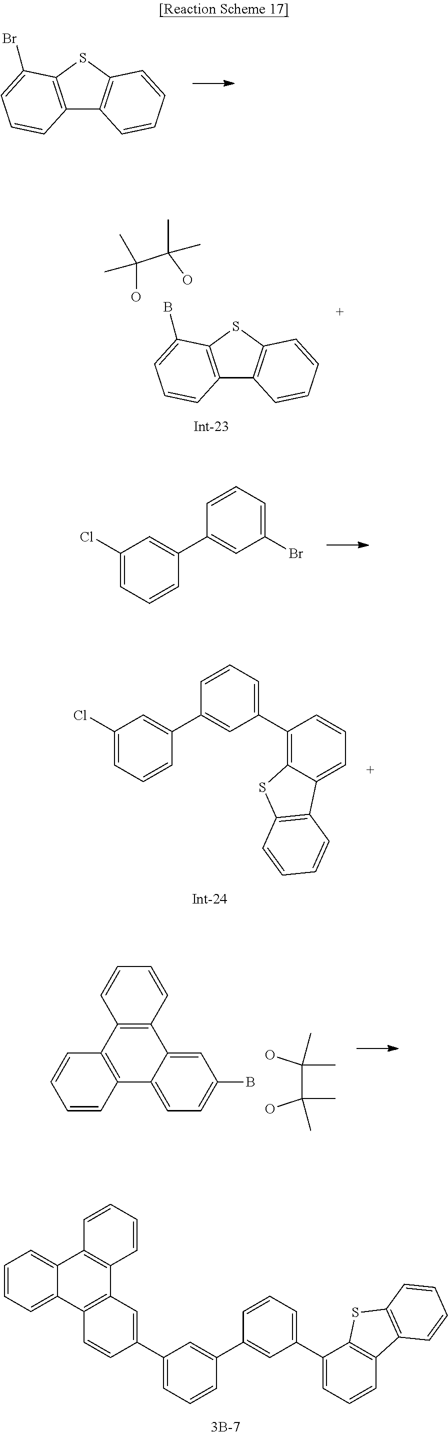

1st Step: Synthesis of Intermediate Int-23

28 g (55%) of Intermediate Int-23 was synthesized and purified in the same manner as in the 1^{st} step of Synthesis Example 18 except that 4-bromodibenzothiophene was used instead of the 1-bromodibenzofuran.

2nd Step: Synthesis of Intermediate Int-24

22 g (65%) of Intermediate Int-24 was synthesized and purified in the same manner as in the 2nd step of Synthesis Example 18 except that 3B-bromo-3′-chloro-1,1′-biphenyl was used instead of the 4-bromo-3′-chloro-1,1′-biphenyl.

3rd Step: Synthesis of Compound 3B-7

11.1 g (39%) of Compound 3B-7 was synthesized and purified in the same manner as in the 3rd step of Synthesis Example 18 except that Intermediate Int-24 was used.

LC-Mass (theoretical value: 562.72 g/mol, measured value: M+=563.57 g/mol)

### Synthesis Example 20: Synthesis of Compound 3B-2

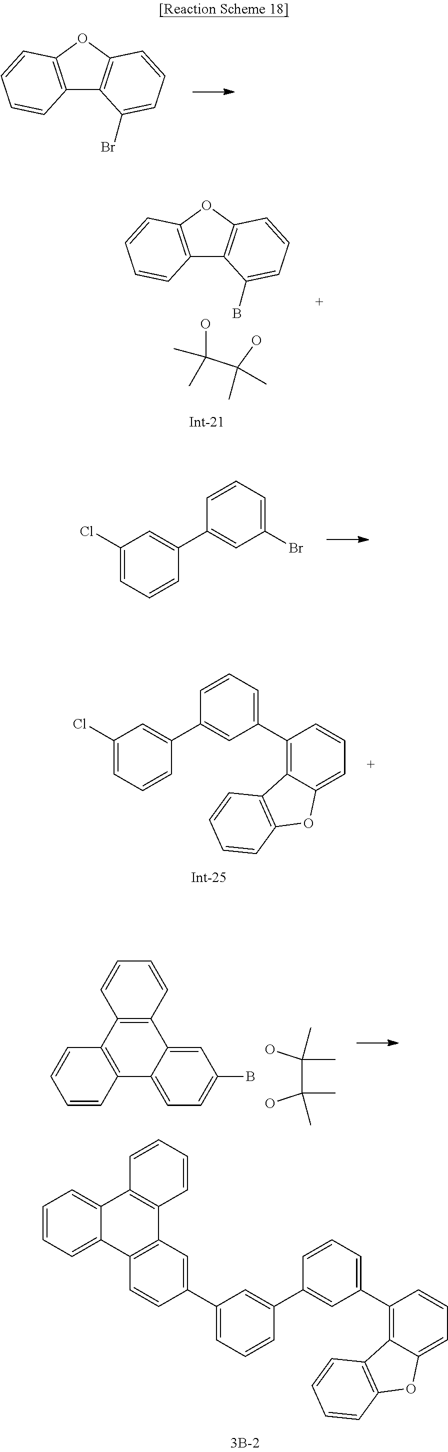

1st Step: Synthesis of Intermediate Int-21

19.1 g (45%) of Compound 3B-7 was synthesized and purified in the same manner as in the 1st step of Synthesis Example 18 except that Intermediate Int-21 was used.

2nd Step: Synthesis of Intermediate Int-25

26.2 g (65%) of Intermediate Int-25 was synthesized and purified in the same manner as in the 2nd step of Synthesis Example 18 except that 3B-bromo-3′-chloro-1,1′-biphenyl was used instead of the 4-bromo-3′-chloro-1,1′-biphenyl.

3rd Step: Synthesis of Compound 3B-2

9.5 g (48%) of Compound 3B-2 was synthesized and purified in the same manner as in the 3rd step of Synthesis Example 18 except that Intermediate Int-25 was used.

LC-Mass (theoretical value: 546.20 g/mol, measured value: M+=547.88 g/mol)

### Synthesis Example 21: Synthesis of Compound 3B-13

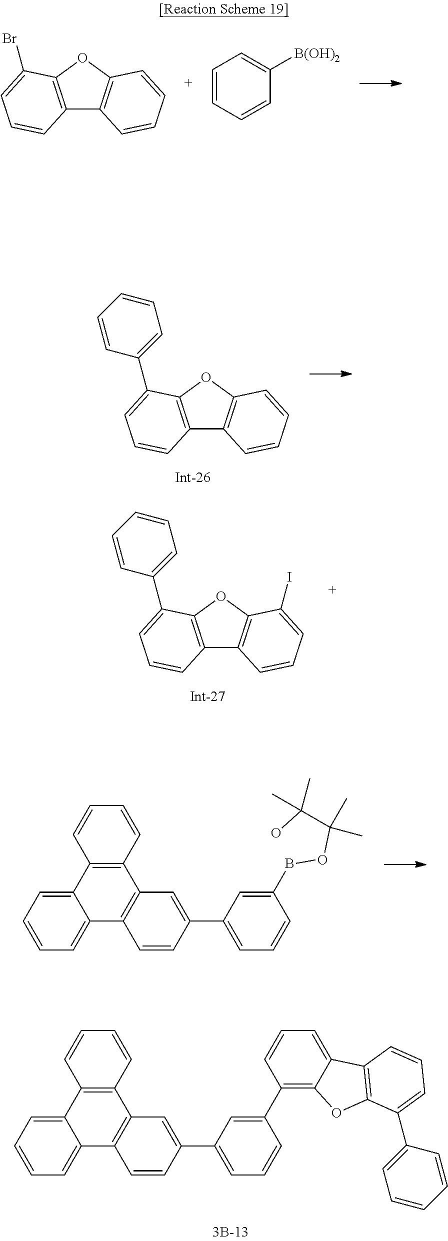

1st Step: Synthesis of Intermediate Int-26

41.8 g (169.2 mmol) of 4-bromodibenzofuran, 24.8 g (203.3 mmol) of phenylboronic acid, 46.8 g (338.3 mmol) of K₂CO₃, and 5.9 g (5.1 mmol) of Pd(PPh₃)₄ were suspended in 340 ml of THE and 170 ml of distilled water under a nitrogen flow and then, stirred under reflux for 8 hours. When a reaction was completed, the resultant was extracted with DCM and treated through column chromatography (hexane:DCM (20%)), obtaining 28.5 g (69%) of Intermediate Int-26 as a solid.

2nd Step: Synthesis of Intermediate Int-27

28.5 g (116.7 mmol) of Intermediate Int-26 was dissolved in 250 ml of THF in a round-bottomed flask under a nitrogen flow and then, stirred at −78° C. for 30 minutes. Subsequently, 51.3 ml (128.3 mmol) of n-butyllithium (2.5 M solution) was slowly added thereto in a dropwise fashion for 1 hour and then, additionally stirred for 4 hours. At −78° C., a solution obtained by diluting 29.6 g (116.7 mmol) of iodine with THE was slowly added thereto in a dropwise fashion and then, stirred at room temperature for 4 hours. When a reaction was completed, a saturated sodium bicarbonate aqueous solution and DCM were added thereto and then, stirred for 1 hour, and an organic layer was separated therefrom and filtered with a silica gel pad to remove a solvent under a reduced pressure, obtaining 34.6 g (80%) of Intermediate Int-27.

3rd Step: Synthesis of Compound 3B-13

29.2 g (81%) of Compound 3B-13 was synthesized and purified in the same manner as in the 3rd step of Synthesis Example 18 except that Intermediate Int-27 was used.

LC-Mass (theoretical value: 546.66 g/mol, measured value: M+=547.64 g/mol)

### Synthesis Example 22: Synthesis of Compound 3B-3

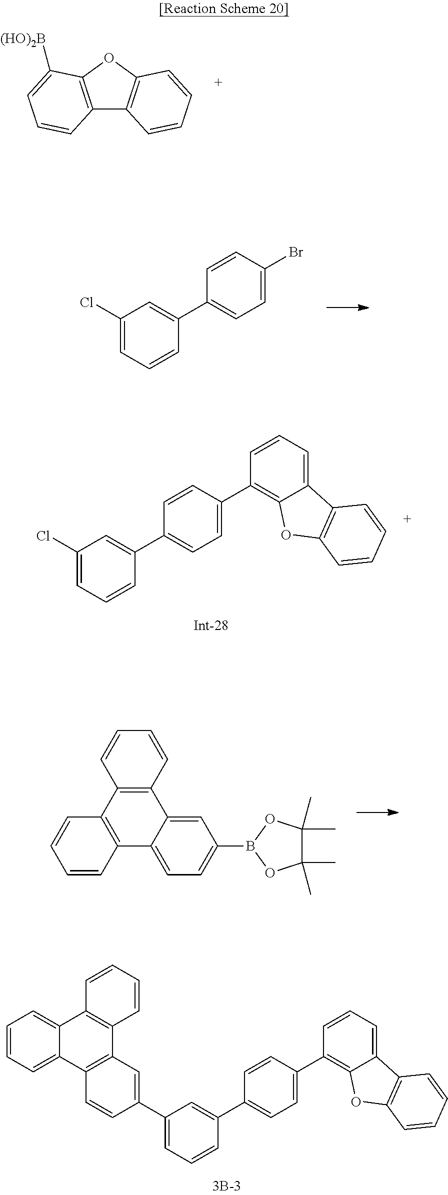 [SMILES: OB(O)c1cccc2c1oc1ccccc12 ; Clc1cccc(-c2ccc(Br)cc2)c1 ; Clc1cccc(-c2ccc(-c3cccc4c3oc3ccccc34)cc2)c1 ; CC1(C)OB(c2ccc3c4ccccc4c4ccccc4c3c2)OC1(C)C ; c1cc(-c2ccc(-c3cccc4c3oc3ccccc34)cc2)cc(-c2ccc3c4ccccc4c4ccccc4c3c2)c1]

1st Step: Synthesis of Intermediate Int-28

12.2 g (68%) of Intermediate Int-28 was synthesized and purified in the same manner as in the 1^{st} step and 2nd step of Synthesis Example 18 except that 4-bromodibenzofuran was used instead of the 1-bromodibenzofuran.

2nd Step: Synthesis of Compound 3B-3

9.1 g (56%) of Compound 3B-3 was synthesized and purified in the same manner as in the 3rd step of Synthesis Example 18 except that Intermediate Int-28 was used.

LC-Mass (theoretical value: 546.20 g/mol, measured value: M+=547.82 g/mol)

### (Synthesis of Dopant)

### Synthesis Example 23: Dopant Compound PtGD

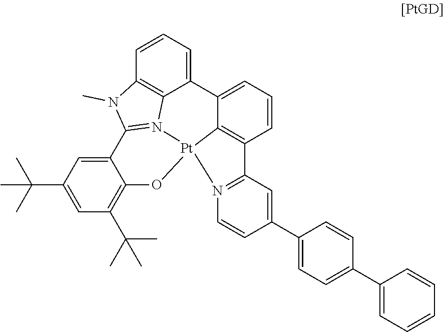

It was synthesized in the same manner as described in KR1999337.

### (Manufacture of Organic Light Emitting Diode)

### Example 1

The glass substrate coated with ITO (indium tin oxide) was washed with distilled water. After washing with the distilled water, the glass substrate was washed with a solvent such as isopropyl alcohol, acetone, methanol, and the like ultrasonically and dried and then, moved to a plasma cleaner, cleaned by using oxygen plasma for 10 minutes, and moved to a vacuum depositor. This obtained ITO transparent electrode was used as an anode, Compound A doped with 3% NDP-9 (available from Novaled) was vacuum-deposited on the ITO substrate to form a 1,400 Å-thick hole transport layer, and Compound B was deposited on the hole transport layer to form a 350 Å-thick hole transport auxiliary layer. On the hole transport auxiliary layer, a 400 Å-thick light emitting layer was formed by vacuum-depositing Compound 1-27, Compound 2-2, and Compound 3A-2 as a host simultaneously and doping 15 wt % of PtGD as a dopant. Herein, Compound 1-27, Compound 2-2, and Compound 3A-2 were used in a weight ratio of 35:55:10, and the ratios were separately described for the following examples and comparative examples. Subsequently, Compound C was deposited on the light emitting layer to form a 50 Å-thick electron transport auxiliary layer, and Compound D and Liq were simultaneously vacuum deposited at a weight ratio of 1:1 to form a 300 Å-thick electron transport layer. On the electron transport layer, LiQ and Al were sequentially vacuum-deposited to be 15 Å thick and 1,200 Å thick, manufacturing an organic light emitting diode having the following structure.

ITO/Compound A (3% NDP-9 doping, 1,400 Å)/Compound B (350 Å)/EML {[85 wt % of host (1-27:2-2:3A-2=35:55:10):15 wt % of [PtGD]} (400 Å)/Compound C (50 Å)/Compound D: LiQ (300 Å)/LiQ (15 Å)/Al (1,200 Å).
Compound A: N-(biphenyl-4-yl)-9,9-dimethyl-N-(4-(9-phenyl-9H-carbazol-3-yl)phenyl)-9H-fluoren-2-amine
Compound B: N,N-bis(9,9-dimethyl-9H-fluoren-4-yl)-9,9-spirobi(fluorene)-2-amine
Compound C: 2-(3-(3-(9,9-dimethyl-9H-fluoren-2-yl)phenyl)phenyl)-4,6-diphenyl-1,3,5-triazine
Compound D: 8-(4-(4,6-di(naphthalen-2-yl)-1,3,5-triazin-2-yl)phenyl)quinolone

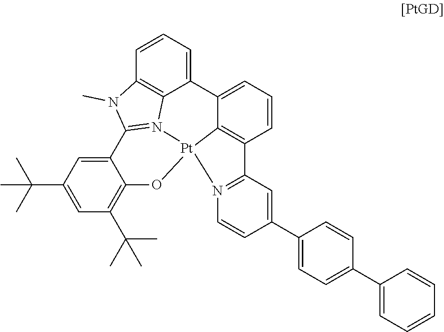

### Examples 2 to 9 and Comparative Examples 1 to 13

Organic light emitting diodes were manufactured in the same manner as in Example 1, except that the composition was changed to the host shown in Tables 1 to 6.

### Evaluation I

The efficiency and life-span of the organic light emitting diodes according to Examples 1 to 3 and Comparative Examples 1 to 6 were measured.

Specific measurement methods are as follows, and the results are shown in Tables 1 to 3.

(1) Measurement of Current Density Change Depending on Voltage Change

The obtained organic light emitting diodes were measured regarding a current value flowing in the unit device, while increasing the voltage from 0 V to 10 V using a current-voltage meter (Keithley 2400), and the measured current value was divided by area to provide the results.

(2) Measurement of Luminance Change Depending on Voltage Change

Luminance was measured by using a luminance meter (Minolta Cs-1000A), while the voltage of the organic light emitting diodes was increased from 0 V to 10 V.

(3-1) Measurement of Luminous Efficiency I

The current efficiency (cd/A) of the required luminance of 9000 nits was calculated using the luminance, current density, and voltage measured from (1) and (2). Relative efficiency ratios are shown based on the luminous efficiency values of Comparative Examples 1, 3, and 5, respectively.

(4-1) Measurement of Life-Span I

The results were obtained by measuring a time when current efficiency (cd/A) was decreased down to 95%, while luminance (cd/m²) was maintained to be 24,000 cd/m². Relative life-span ratios are shown based on the life-span values of Comparative Examples 1, 3, and 5, respectively.

TABLE 1

| | | | | Ratio of | Luminous | |
|---|---|---|---|---|---|---|
| | | | | First host:Second | efficiency | Life-span |
| | First | Second | Third | host:Third host | ratio | ratio (T95) |
| | host | host | host | (wt:wt) | (%) | (%) |
| Example 1 | 1-27 | 2-2 | 3A-2 | 35:55:10 | 100 | 116 |
| Comparative | 1-27 | 2-2 | — | 35:65:0 | 100 | 100 |
| Example 1 | | | | | | |
| Comparative | 1-27 | — | 3A-2 | 35:0:65 | 80 | 60 |
| Example 2 | | | | | | |

TABLE 2

| | | | | Ratio of | Luminous | |
|---|---|---|---|---|---|---|
| | | | | First host:Second | efficiency | Life-span |
| | First | Second | Third | host:Third host | ratio | ratio (T95) |
| | host | host | host | (wt:wt) | (%) | (%) |
| Example 2 | 1-24 | 2-15 | 3A-1 | 35:55:10 | 100 | 116 |
| Comparative | 1-24 | 2-15 | — | 35:65:0 | 100 | 100 |
| Example 3 | | | | | | |
| Comparative | 1-24 | — | 3A-1 | 35:0:65 | 80 | 70 |
| Example 4 | | | | | | |

TABLE 3

| | | | | Ratio of | Luminous | |
|---|---|---|---|---|---|---|
| | | | | First host:Second | efficiency | Life-span |
| | First | Second | Third | host:Third host | ratio | ratio (T95) |
| | host | host | host | (wt:wt) | (%) | (%) |
| Example 3 | 1-25 | 2-13 | 3A-2 | 32:48:20 | 100 | 117 |
| Comparative | 1-25 | 2-13 | — | 35:65:0 | 100 | 100 |
| Example 5 | | | | | | |
| Comparative | 1-25 | — | 3A-2 | 35:0:65 | 80 | 65 |
| Example 6 | | | | | | |

Referring to Tables 1 to 3, the organic light emitting diodes according to Examples 1 to 3 have significantly improved life-span while maintaining the same or higher efficiency compared to the organic light emitting diodes according to Comparative Examples 1 to 6.

### Evaluation II

The efficiency and life-span of organic light emitting diodes according to Examples 4 to 9 and Comparative Examples 7 to 13 were measured.

Specific measurement methods are as follows, and the results are shown in Tables 4 to 6.

(1) Measurement of Current Density Change Depending on Voltage Change

The obtained organic light emitting diodes were measured regarding a current value flowing in the unit device, while increasing the voltage from 0 V to 10 V using a current-voltage meter (Keithley 2400), and the measured current value was divided by area to provide the results.

(2) Measurement of Luminance Change Depending on Voltage Change Luminance was measured by using a luminance meter (Minolta Cs-1000A), while the voltage of the organic light emitting diodes was increased from 0 V to 10 V.

(3-2) Measurement of Luminous Efficiency II

The current efficiency (cd/A) of the same current density (10 mA/cm²) was calculated using the luminance, current density, and voltage measured from (1) and (2). Relative efficiency ratios are shown based on the luminous efficiency values of Comparative Examples 7, 10, and 12, respectively.

(4-2) Measurement of Life-Span II

The organic light emitting diodes of Example 4 to Example 9, and Comparative Example 7 to Comparative Example 13 were measured with respect to T90 life-spans by emitting light at initial luminance (cd/m²) of 9,000 cd/m² and measuring luminance decreases over time to obtain when the luminance decreased down to 97% of the initial luminance as T97 life-span. Relative efficiency ratios are shown based on the luminous efficiency values of Comparative Examples 7, 10, and 12, respectively.

TABLE 4

| | | | | Ratio of | Luminous | |
|---|---|---|---|---|---|---|
| | | | | First host:Second | efficiency | Life-span |
| | First | Second | Third | host:Third host | ratio | ratio (T97) |
| | host | host | host | (wt:wt) | (%) | (%) |
| Example 4 | 1-46 | 2-8 | 3B-7 | 35:55:10 | 99 | 121 |
| Example 5 | 1-46 | 2-8 | 3B-4 | 35:55:10 | 100 | 117 |
| Example 6 | 1-46 | 2-8 | 3B-3 | 40:50:10 | 99 | 132 |
| Example 7 | 1-25 | 2-8 | 3B-3 | 35:55:10 | 105 | 137 |
| Comparative | 1-46 | 2-8 | — | 35:65 | 100 | 100 |
| Example 7 | | | | | | |
| Comparative | 1-25 | 2-8 | — | 35:65 | 91 | 67 |
| Example 8 | | | | | | |
| Comparative | 1-25 | — | 3B-3 | 50:50 | 43 | 31 |
| Example 9 | | | | | | |

TABLE 5

| | | | | Ratio of | | |
|---|---|---|---|---|---|---|
| | | | | First host:Second | Efficiency | life-span |
| | First | Second | Third | host:Third host | ratio | ratio T97 |
| | host | host | host | (wt:wt) | (%) | (%) |
| Example 8 | 1-73 | 2-2 | 3B-2 | 40:50:10 | 102 | 128 |
| Comparative | 1-73 | 2-2 | — | 40:60 | 100 | 100 |
| Example 10 | | | | | | |
| Comparative | 1-73 | — | 3B-2 | 50:50 | 39 | 27 |
| Example 11 | | | | | | |

TABLE 6

| | | | | Ratio of | | |
|---|---|---|---|---|---|---|
| | | | | First host:Second | Efficiency | life-span |
| | First | Second | Third | host:Third host | ratio | ratio T97 |
| | host | host | host | (wt:wt) | (%) | (%) |
| Example 9 | 1-41 | 2-1 | 3B-2 | 40:50:10 | 102 | 113 |
| Comparative | 1-41 | 2-1 | — | 40:60 | 100 | 100 |
| Example 12 | | | | | | |
| Comparative | 1-41 | — | 3B-2 | 50:50 | 65 | 71 |
| Example 13 | | | | | | |

Referring to Tables 4 to 6, the organic light emitting diodes according to Examples 4 to 9 exhibited significantly improved life-span while maintaining a similar level of efficiency as compared to the organic light emitting diodes according to Comparative Examples 7 to 13.

While this invention has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

1. A composition for an organic optoelectronic element, comprising:
a first compound represented by Chemical Formula I;
a second compound represented by Chemical Formula II; and
a third compound represented by Chemical Formula IIIA or Chemical Formula IIIB, 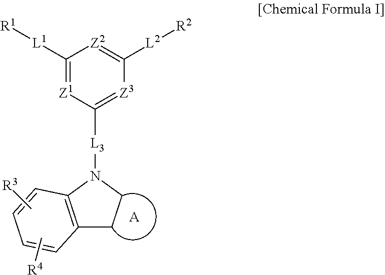
wherein, in Chemical Formula I,
Z¹ to Z³ are N or C-L^{a}-R^{a}, provided that at least two of Z¹ to Z³ are N,
L^{a} and L¹ to L³ are each independently a single bond, a substituted or unsubstituted C6 to C20 arylene group, a substituted or unsubstituted C2 to C20 heterocyclic group, or a combination thereof,
R¹ and R² are each independently a substituted or unsubstituted C6 to C30 aryl group, a substituted or unsubstituted C2 to C30 heterocyclic group, or a combination thereof,
R^{a}, R³, and R⁴ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and
ring A is represented by any one of Chemical Formula I-1 to Chemical Formula I-7: 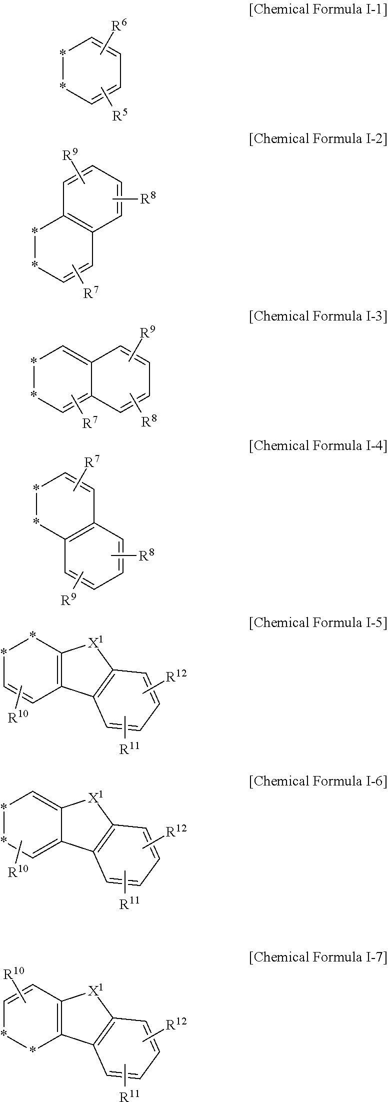
wherein, in Chemical Formula I-1 to Chemical Formula I-7,
X¹ is O, S, or NR,
R^{b} and R⁵ to R¹² are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and
* is a linking point; 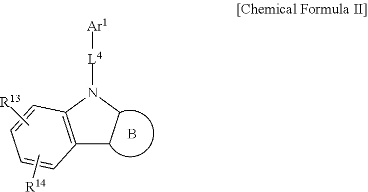
wherein, in Chemical Formula II,
L⁴ is a single bond, a substituted or unsubstituted C6 to C20 arylene group, a substituted or unsubstituted C2 to C20 heterocyclic group, or a combination thereof,
Ar¹ is a substituted or unsubstituted C6 to C30 aryl group, a substituted or unsubstituted dibenzofuranyl group, a substituted or unsubstituted dibenzothiophenyl group, or a combination thereof,
R¹³ and R¹⁴ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and
ring B is represented by any one of Chemical Formula II-1 to Chemical Formula II-4: 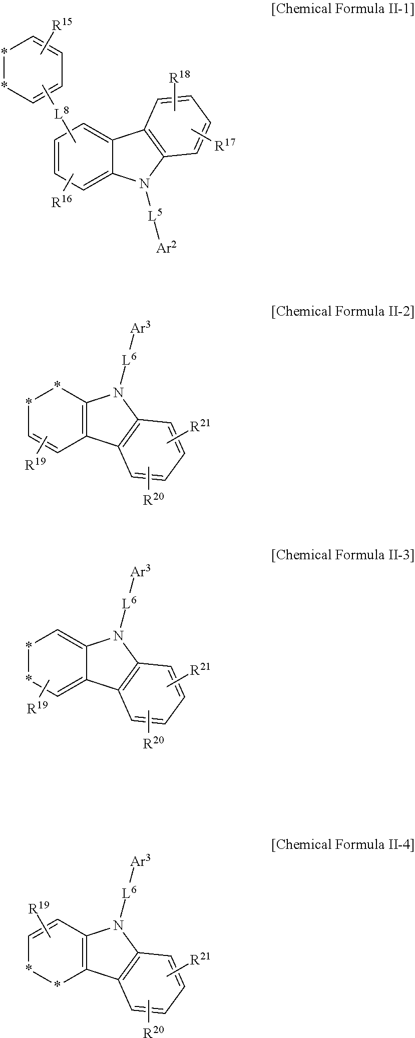
wherein, in Chemical Formula II-1 to Chemical Formula II-4,
L⁵ and L⁶ are each independently a single bond, a substituted or unsubstituted C6 to C20 arylene group, a substituted or unsubstituted C2 to C20 heterocyclic group, or a combination thereof,
L⁸ is a single bond, or a substituted or unsubstituted C6 to C20 arylene group,
Ar² and Ar³ are a substituted or unsubstituted C6 to C30 aryl group, a substituted or unsubstituted dibenzofuranyl group, a substituted or unsubstituted dibenzothiophenyl group, or a combination thereof,
R¹⁵ to R²¹ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and
* is a linking point; 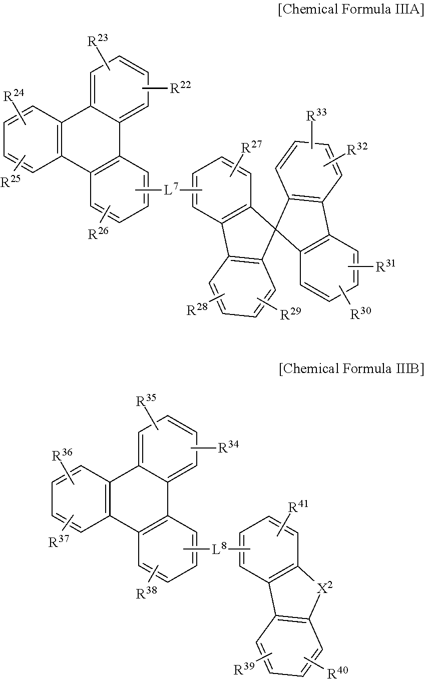
wherein, in Chemical Formula IIIA and Chemical Formula IIIB,
L⁷ and L⁸ are each independently a single bond, a substituted or unsubstituted C6 to C20 arylene group, a substituted or unsubstituted C2 to C20 heterocyclic group, or a combination thereof,
R²² to R⁴¹ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and
X² is O or S.

2. The composition for an organic optoelectronic element of claim 1, wherein the first compound is represented by Chemical Formula IA or Chemical Formula IE: 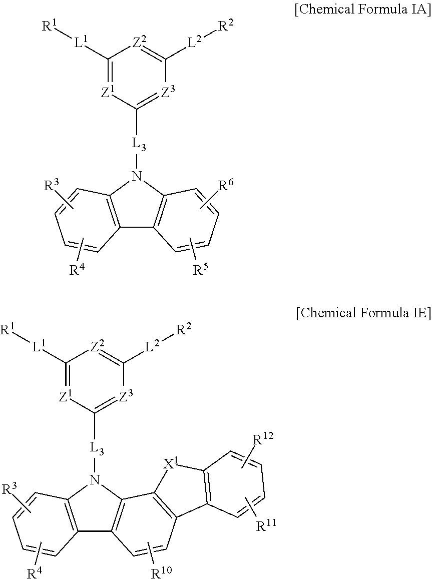
wherein, in Chemical Formula IA and Chemical Formula IE, definitions of Z¹ to Z³, L¹ to L³, R¹ to R¹², and X¹ are the same as for Chemical Formula I.

3. The composition for an organic optoelectronic element of claim 1, wherein the second compound is represented by Chemical Formula IIA or Chemical Formula IIF: 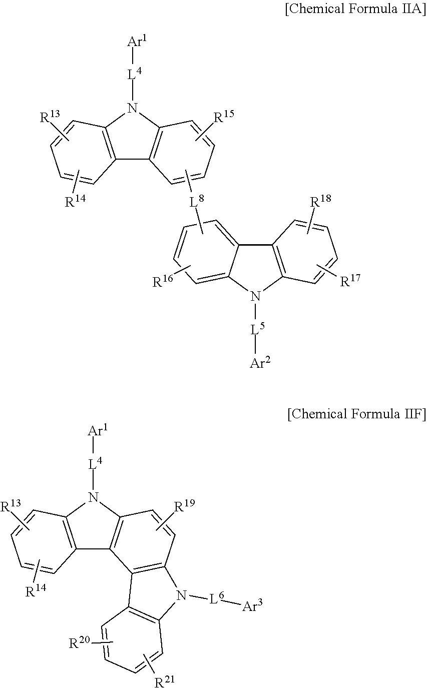
wherein, in Chemical Formula IIA and Chemical Formula IIF, definitions of L⁴ to
L⁶, L⁸, Ar¹ to Ar³, and R¹³ to R²¹ are the same as for Chemical Formula II.

4. The composition for an organic optoelectronic element of claim 1, wherein the third compound is represented by Chemical Formula IIIA.

5. The composition for an organic optoelectronic element of claim 2, wherein:
the first compound is represented by Chemical Formula IA, and
the third compound is represented by Chemical Formula IIIA.

6. The composition for an organic optoelectronic element of claim 4, wherein the second compound is represented by Chemical Formula IIA-1 or Chemical Formula IIA-2: 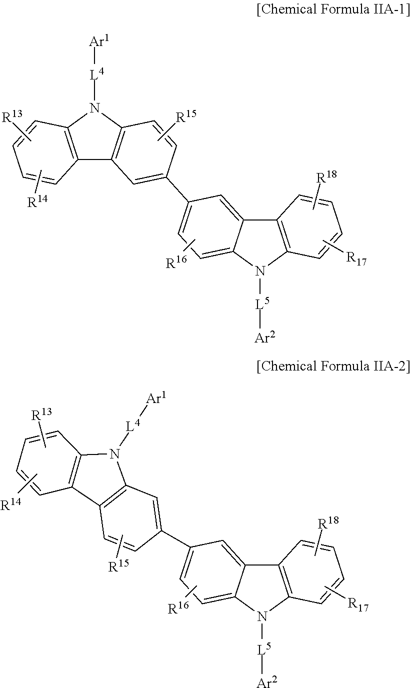
wherein, in Chemical Formula IIA-1 and Chemical Formula IIA-2, definitions of L⁴, L⁵, Ar¹, Ar², and R¹³ to R¹⁸ are the same as for Chemical Formula II.

7. The composition for an organic optoelectronic element of claim 4, wherein the third compound is represented by any one of Chemical Formula IIIA-1 to Chemical Formula IIIA-4: 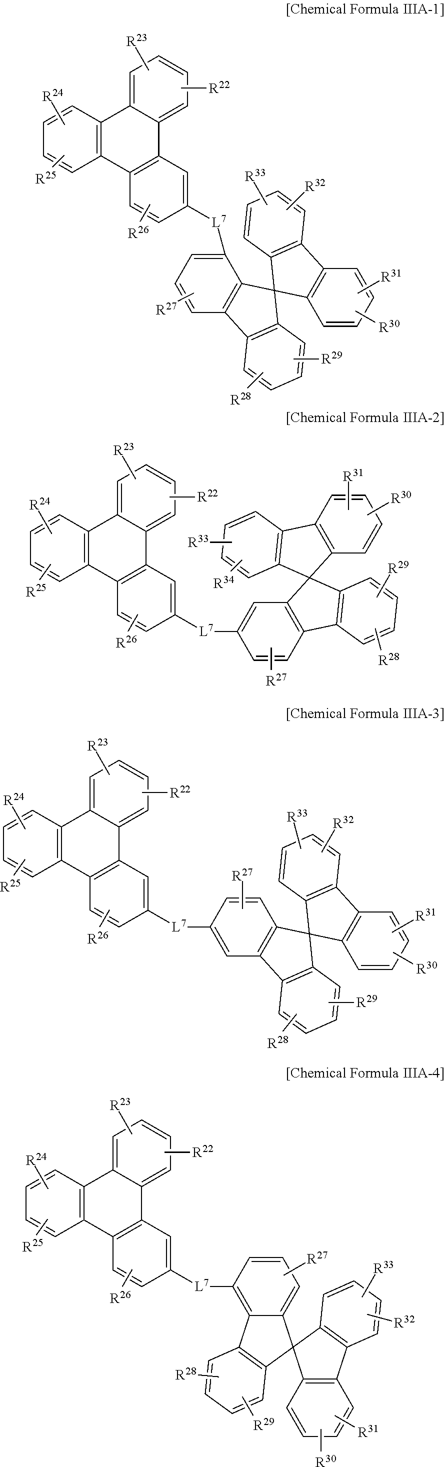
wherein, in Chemical Formula IIIA-1 to Chemical Formula IIIA-4, definitions of L⁷ and R²² to R³³ are the same as for Chemical Formula III.

8. The composition for an organic optoelectronic element of claim 7, wherein:
the third compound is represented by Chemical Formula IIIA-4,
L⁷ is a single bond or a substituted or unsubstituted phenylene group, and
R²² to R³³ are hydrogen, a substituted or unsubstituted phenyl group, or a substituted or unsubstituted carbazolyl group.

9. The composition for an organic optoelectronic element of claim 4, wherein:
the first compound is represented by Chemical Formula IA-1 or Chemical Formula IA-4,
the second compound is represented by any one of Chemical Formula IIA-1, Chemical Formula IIA-2, and Chemical Formula IIF, and
the third compound is represented by Chemical Formula IIIA-4, 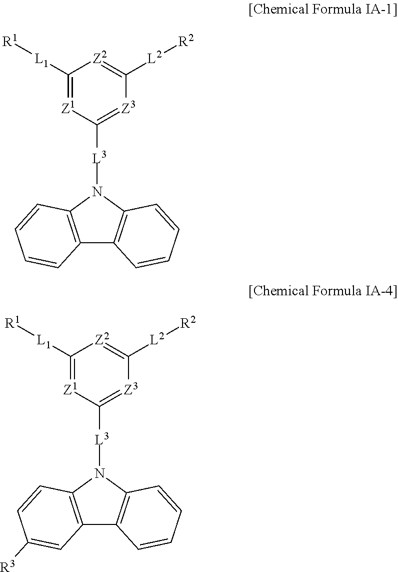
wherein, in Chemical Formula IA-1 and Chemical Formula IA-4, definitions of Z¹ to Z³, L¹ to L³, R¹, and R² are the same as for Chemical Formula I, and R³ is a substituted or unsubstituted phenyl group, a substituted or unsubstituted biphenyl group, a substituted or unsubstituted terphenyl group, a substituted or unsubstituted carbazolyl group, a substituted or unsubstituted indolocarbazolyl group, a substituted or unsubstituted dibenzofuranyl group, or a substituted or unsubstituted dibenzothiophenyl group; 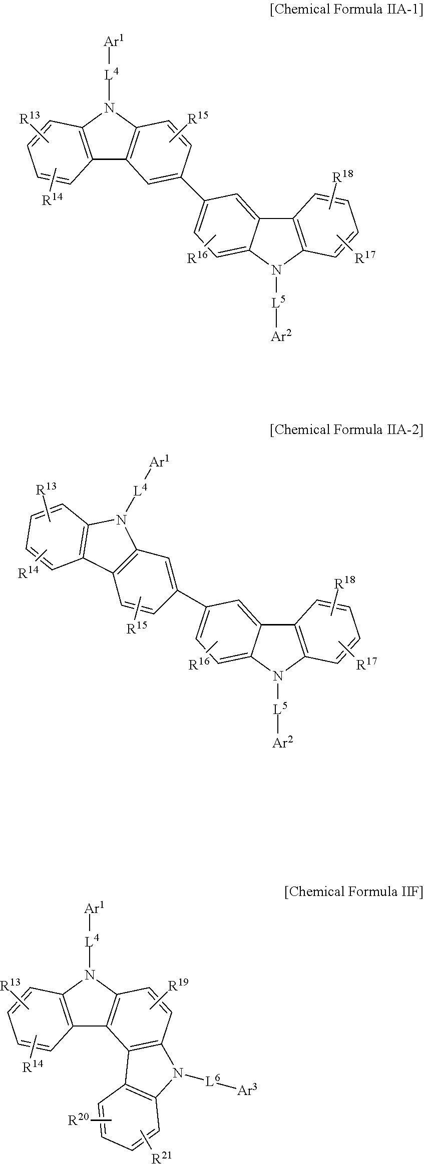 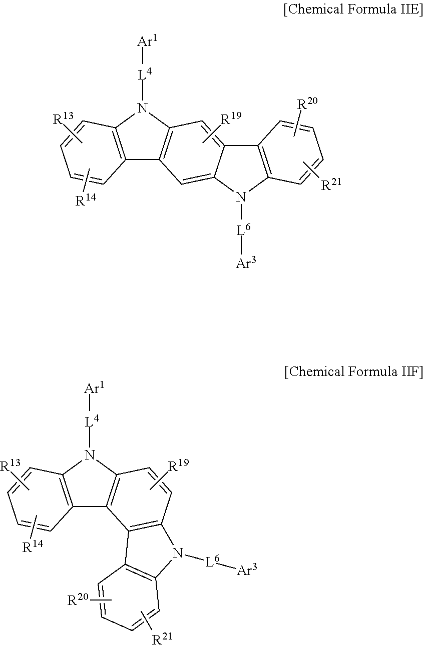
wherein, in Chemical Formula IIA-1, Chemical Formula IIA-2, and Chemical Formula IIF, definitions of L⁴ to L⁶, L⁸, Ar¹ to Ar³, and R¹³ to R²¹ are the same as for Chemical Formula II; 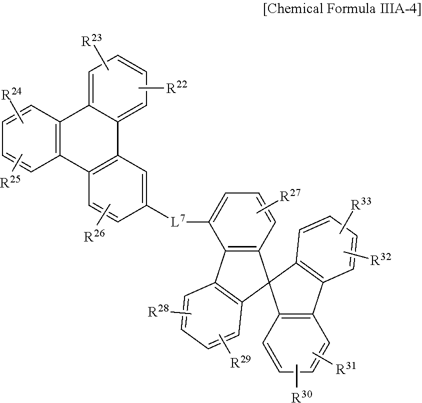
wherein, in Chemical Formula IIIA-4, definitions of L⁷ and R²² to R³³ are the same as for Chemical Formula III.

10. The composition for an organic optoelectronic element of claim 1, wherein the third compound is represented by Chemical Formula IIIB.

11. The composition for an organic optoelectronic element of claim 10, wherein the first compound is represented by any one of Chemical Formula IA, Chemical Formula ID, Chemical Formula IE, Chemical Formula IF, Chemical Formula IG, Chemical Formula IH, Chemical Formula II, and Chemical Formula IJ: 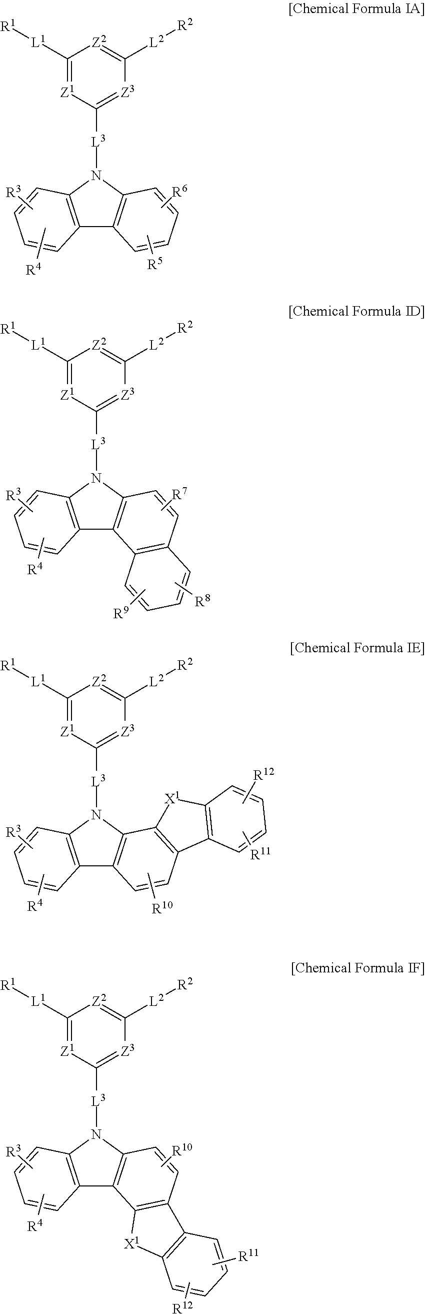 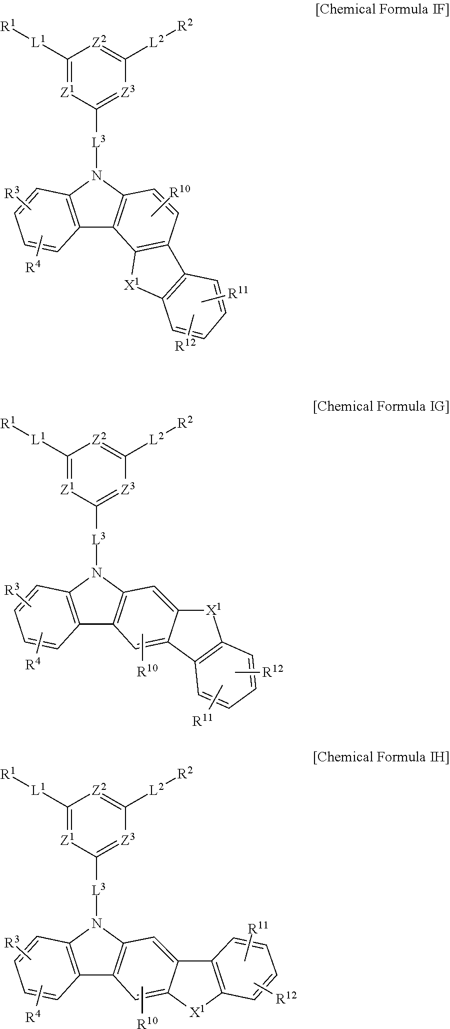 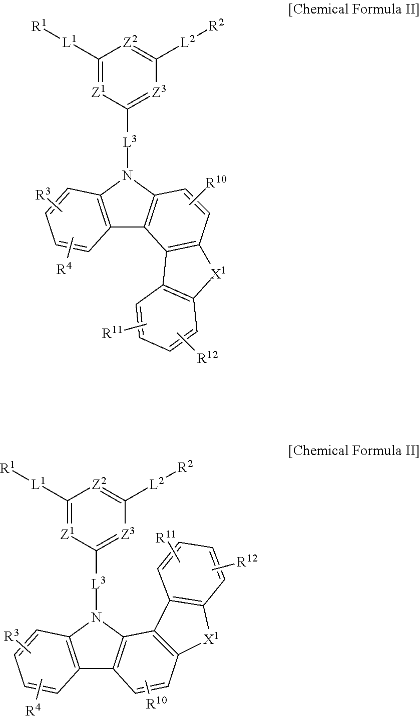
wherein, in Chemical Formula IA, Chemical Formula ID, Chemical Formula IE, Chemical Formula IF, Chemical Formula IG, Chemical Formula IH, Chemical Formula II, and Chemical Formula IJ, definitions of Z¹ to Z³, L¹ to L³, R¹ to R¹², and X¹ are the same as for Chemical Formula I.

12. The composition for an organic optoelectronic element of claim 10, wherein the second compound is represented by any one of Chemical Formula IIA-1 to Chemical Formula IIA-3: 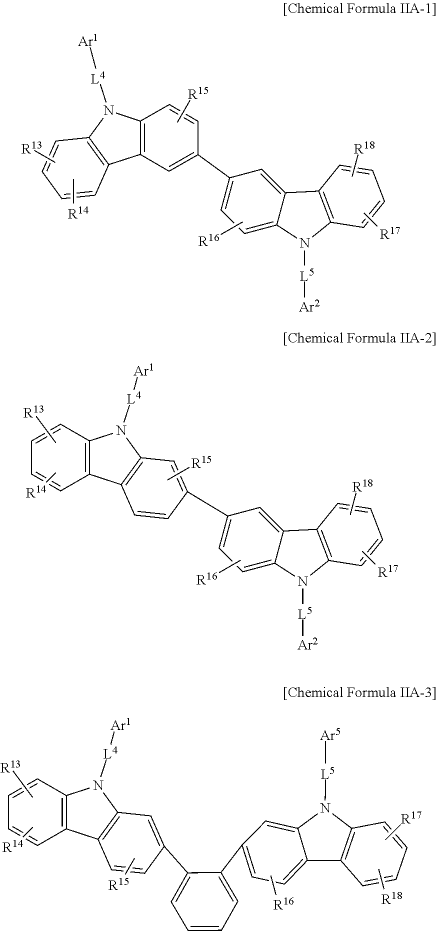
wherein, in Chemical Formula IIA-1 to Chemical Formula IIA-3, definitions of L⁴, L⁵, Ar¹, Ar², and R¹³ to R¹⁸ are the same as for Chemical Formula II.

13. The composition for an organic optoelectronic element of claim 10, wherein the second compound is represented by any one of Chemical Formula IIA-1, Chemical Formula IIA-2, and Chemical Formula IIF: 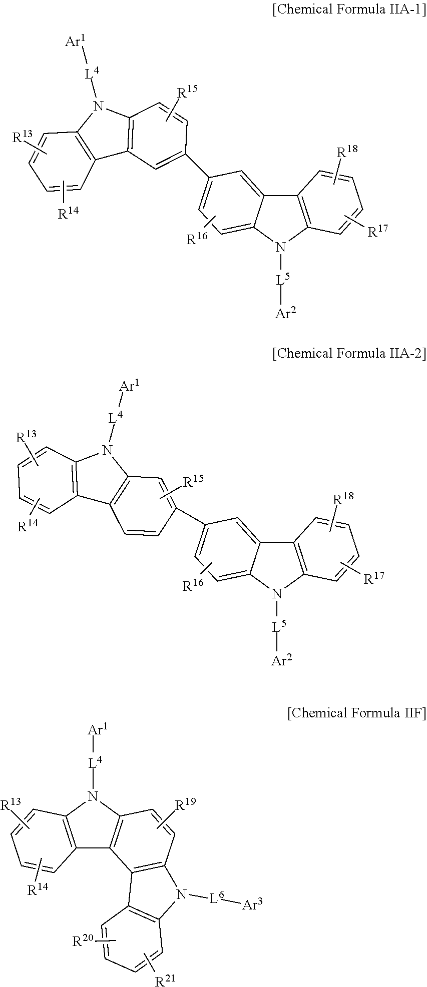
wherein, in Chemical Formula IIA-1, Chemical Formula IIA-2, and Chemical Formula IIF,
R¹³ to R²¹ are each hydrogen,
L⁴ to L⁶ are each independently a single bond or a substituted or unsubstituted phenylene group, and
Ar¹ to Ar³ are each independently a substituted or unsubstituted phenyl group, or a substituted or unsubstituted biphenyl group.

14. The composition for an organic optoelectronic element of claim 10, wherein the third compound is represented by any one of Chemical Formula IIIB-1 to Chemical Formula IIIB-4: 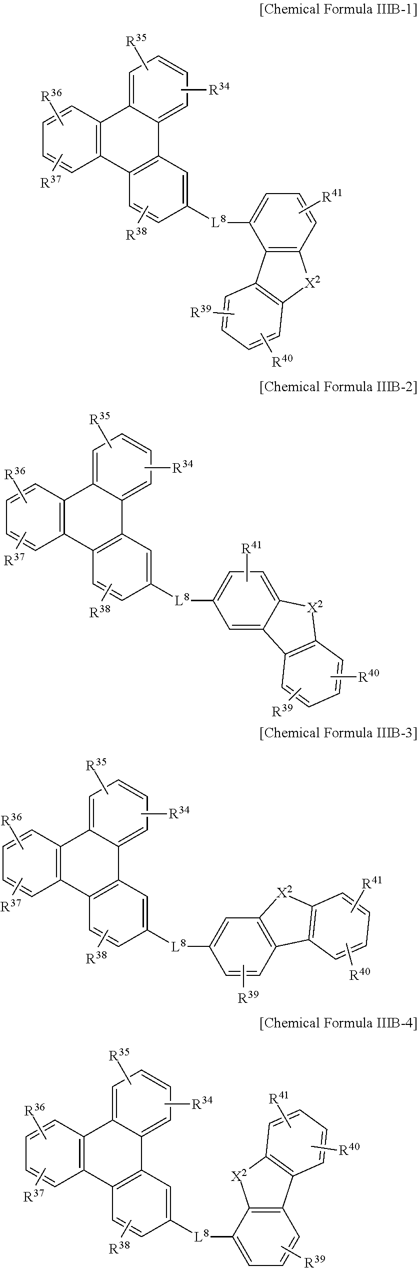
wherein, in Chemical Formula IIIB-1 to Chemical Formula IIIB-4, definitions of X², L⁸, and R³⁴ to R⁴¹ are the same as for Chemical Formula III.

15. The composition for an organic optoelectronic element of claim 14, wherein the third compound is represented by Chemical Formula IIIB-1 or Chemical Formula IIIB-4.

16. The composition for an organic optoelectronic element of claim 10, wherein:
the first compound is represented by Chemical Formula IA-1,
the second compound is represented by Chemical Formula IIA-1, and
the third compound is represented by Chemical Formula IIIB-4, 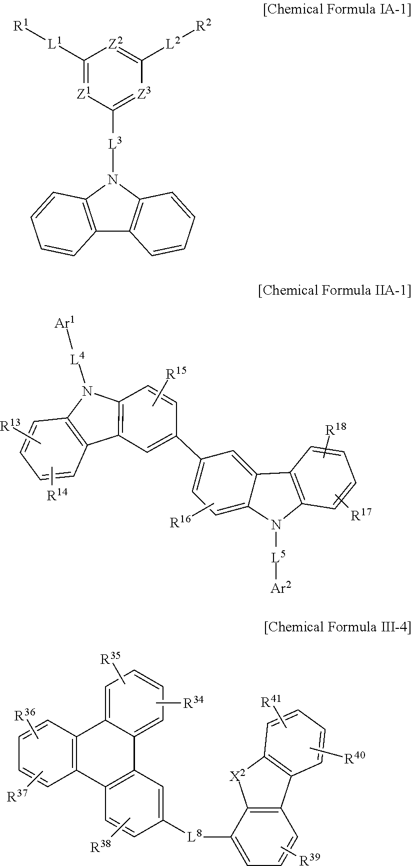
wherein, in Chemical Formula IA-I,
Z¹ to Z³ are each N,
L¹ to L³ are each independently a single bond or an unsubstituted phenylene group, and
R¹ and R² are each independently a substituted or unsubstituted phenyl group, a substituted or unsubstituted biphenyl group, a substituted or unsubstituted carbazolyl group, a substituted or unsubstituted dibenzofuranyl group, or a substituted or unsubstituted dibenzothiophenyl group;
wherein, in Chemical Formula IIA-1,
R¹³ to R¹⁸ are each independently hydrogen, a substituted or unsubstituted phenyl group, a substituted or unsubstituted carbazolyl group, a substituted or unsubstituted dibenzofuranyl group, or a substituted or unsubstituted dibenzothiophenyl group,
L⁴ and L⁵ are each independently a single bond, or a substituted or unsubstituted phenylene group, a substituted or unsubstituted biphenylene group, a substituted or unsubstituted naphthylene group, a substituted or unsubstituted dibenzofuranylene group, or a substituted or unsubstituted dibenzothiophenylene group, and
Ar¹ and Ar² are each independently a substituted or unsubstituted phenyl group, a substituted or unsubstituted biphenyl group, a substituted or unsubstituted terphenyl group, a substituted or unsubstituted naphthyl group, a substituted or unsubstituted phenanthrene group, a substituted or unsubstituted triphenylene group, a substituted or unsubstituted fluorenyl group, a substituted or unsubstituted dibenzofuranyl group, or a substituted or unsubstituted dibenzothiophenyl group;
wherein, in Chemical Formula IIIB-4,
X² is O or S, and
L⁸ is selected from linking groups of Group I, 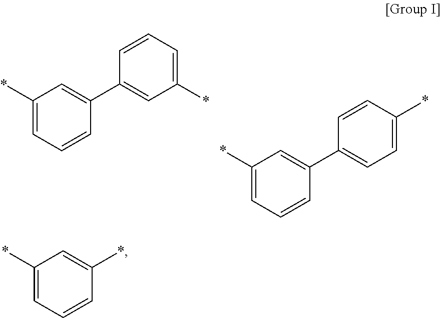
R³⁴ to R⁴¹ are each independently hydrogen or a substituted or unsubstituted phenyl group.

17. The composition for an organic optoelectronic element of claim 10, wherein:
the first compound is represented by Chemical Formula IE-1,
the second compound is represented by Chemical Formula IIA-1, and
the third compound is represented by Chemical Formula IIIB-1 or Chemical Formula IIIB-4: 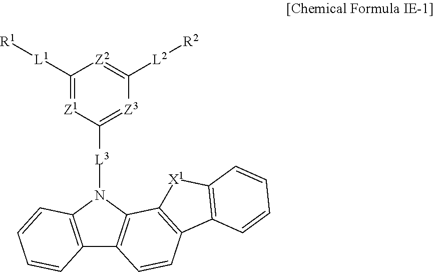
wherein, in Chemical Formula IE-1,
X¹ is NR^{b} or O,
R^{b} is a substituted or unsubstituted phenyl group, a substituted or unsubstituted biphenyl group, or a substituted or unsubstituted terphenyl group,
Z¹ to Z³ are each N,
L¹ to L³ are each independently a single bond, or a substituted or unsubstituted phenylene group, and
R¹ and R² are each independently a substituted or unsubstituted phenyl group, or a substituted or unsubstituted biphenyl group;
wherein, in Chemical Formula IIA-1,
R¹³ to R¹⁸ are each independently hydrogen, a substituted or unsubstituted phenyl group, a substituted or unsubstituted carbazolyl group, a substituted or unsubstituted dibenzofuranyl group, or a substituted or unsubstituted dibenzothiophenyl group,
L⁴ and L⁵ are each independently a single bond, or a substituted or unsubstituted phenylene group, a substituted or unsubstituted biphenylene group, a substituted or unsubstituted naphthylene group, a substituted or unsubstituted dibenzofuranylene group, or a substituted or unsubstituted dibenzothiophenylene group, and
Ar¹ and Ar² are each independently a substituted or unsubstituted phenyl group, a substituted or unsubstituted biphenyl group, a substituted or unsubstituted terphenyl group, a substituted or unsubstituted naphthyl group, a substituted or unsubstituted phenanthrene group, a substituted or unsubstituted triphenylene group, a substituted or unsubstituted fluorenyl group, a substituted or unsubstituted dibenzofuranyl group, or a substituted or unsubstituted dibenzothiophenyl group; 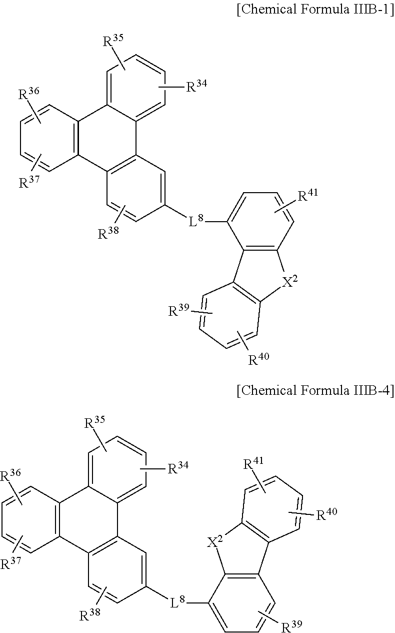
wherein, in Chemical Formula IIIB-1 and Chemical Formula IIIB-4,
X² is O or S, and
L⁸ is selected from linking groups of Group I, 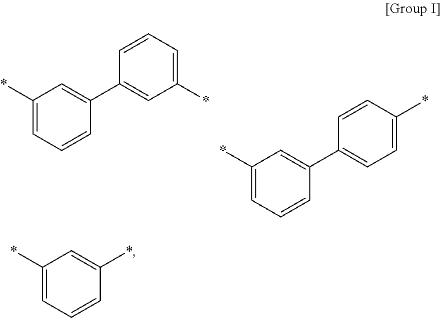
R³⁴ to R⁴¹ are each independently hydrogen or a substituted or unsubstituted phenyl group.

18. The composition for an organic optoelectronic element of claim 1, wherein:
the first compound is included in an amount of 20 wt % to 50 wt % based on the total weight of the first compound, the second compound, and the third compound,
the second compound is included in an amount of 40 wt % to 60 wt % based on the total weight of the first compound, the second compound, and the third compound, and
the third compound is included in an amount of 10 wt % to 30 wt % of based on the total weight of the first compound, the second compound, and the third compound.

19. An organic optoelectronic element, comprising:
an anode and a cathode facing each other, and
an organic layer between the anode and the cathode, the organic layer including the composition for an organic optoelectronic element of claim 1.

20. A display device comprising the organic optoelectronic element of claim 19.
